(19) United States
(12) Patent Application Publication
(10) Pub. No.: US 2015/0236267 A1
(43) Pub. Date: Aug. 20, 2015

(54) ORGANIC ELECTROLUMINESCENCE DEVICE

(71) Applicant: SAMSUNG DISPLAY CO., LTD., Yongin-City (KR)

(72) Inventors: Itoi HIROAKI, Yokohama (JP); Fuchiwaki JUNTA, Yokohama (JP); Sasaki IKUO, Yokohama (JP); Sato SHURI, Yokohama (JP)

(21) Appl. No.: 14/621,820

(22) Filed: Feb. 13, 2015

(30) Foreign Application Priority Data
Feb. 17, 2014 (JP) 2014-027224
Feb. 19, 2014 (JP) 2014-029953

(51) Int. Cl. H01L 51/00; H01L 51/50

(52) U.S. Cl. CPC H01L 51/0061; H01L 51/5004; H01L 51/006; H01L 51/0059; H01L 51/0058; H01L 51/0072; H01L 51/0073; H01L 51/0074; H01L 51/5012; H01L 51/5072; H01L 51/5056; H01L 2251/558; H01L 51/0052; H01L 51/0067

(57) ABSTRACT

An organic electroluminescence (EL) device including an anode; an emission layer for obtaining luminescence via a singlet excited state; and a laminated structure between the anode and the emission layer, the laminated structure including at least three layers having different components.

### CROSS-REFERENCE TO RELATED APPLICATIONS

Japanese Patent Application Nos. 2014-027224, filed on Feb. 17, 2014 and 2014-029953, filed on Feb. 19, 2014, in the Japanese Patent Office, and entitled: “Organic Electroluminescence Device,” are incorporated by reference herein in their entirety.

### BACKGROUND

1. Field

Embodiments relate to an organic electroluminescence device.

2. Description of the Related Art

Recently, an organic electroluminescence display (organic EL display) has been developed as an image display apparatus. The organic EL display is, unlike a liquid crystal display or the like, a self-emitting type display which embodies display through light emission of a light emitting material including an organic compound of the light emitting layer by recombining holes and electrons injected from an anode and a cathode in an emission layer.

An example of an organic electroluminescence device (organic EL device) may include an anode, a hole transport layer disposed on the anode, an emission layer disposed on the hole transport layer, an electron transport layer disposed on the emission layer, and a cathode disposed on the electron transport layer. Holes are injected from the anode, and the injected holes are injected into the emission layer through the hole transport layer. Meanwhile, electrons are injected from the cathode, and the injected electrons are injected into the emission layer through the electron transport layer. The holes and the electrons injected into the emission layer are recombined, and an exciton is generated in the emission layer. The organic EL device emits light by using light generated by the radiation deactivation of the exciton. The organic EL device is not limited to the aforementioned constitution, but many modifications thereof are possible.

### SUMMARY

The embodiments provide an organic EL device driven at a low voltage and having high efficiency and long life.

Embodiments provide organic EL devices including an anode, an emission layer for obtaining luminescence via a singlet excited state, and a laminated structure of at least three layers having different components between the anode and the emission layer. The laminated structure includes a first layer including a hole transport compound obtained by doping an electron accepting compound having a lowest unoccupied molecular orbital (LUMO) level of about −9.0 eV to about −4.0 eV in a compound represented by General Formula (1) of the following Formula 1, a second layer disposed closer to the emission layer than the first layer and including a compound represented by General Formula (1) of the following Formula 1, and a third layer disposed closer to the emission layer than the second layer and including a compound represented by General Formula (2) of the following Formula 1. The emission layer includes a compound represented by General Formula (3) of the following Formula 1.

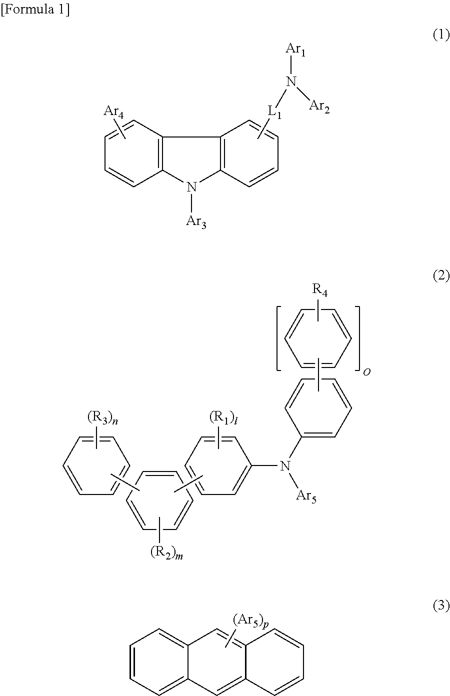

In General Formula (1) of the above Formula 1, Ar1, Ar2 and Ar3 are a substituted or unsubstituted aryl group or a substituted or unsubstituted heteroaryl group, Ar4 is a substituted or unsubstituted aryl group, a substituted or unsubstituted heteroaryl group, a carbazolyl group or an alkyl group, and L1 is a single bond, a substituted or unsubstituted arylene group or a substituted or unsubstituted heteroarylene group. In General Formula (2) of the above Formula 1, R1, R2 and R3 are independently a hydrogen atom, a halogen atom, an alkyl group having 1 to 15 carbon atoms, a substituted or unsubstituted aryl group having 6 to 30 carbon atoms for forming a ring, a substituted or unsubstituted heteroaryl group having 5 to 30 carbon atoms for forming a ring, l, m and n are independently an integer satisfying 0≦1≦4, 0≦m≦4, and 0≦n≦5, R4 is a hydrogen atom or a fluorine atom, o is an integer satisfying 0≦o≦3, and Ar5 is a substituted or unsubstituted aryl group having 6 to 30 carbon atoms for forming a ring. In General Formula (3) of the above Formula 1, each Ar6 is independently a hydrogen atom, a deuterium atom, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group or a hydroxyl group, and p is an integer from 1 to 10.

The organic EL device according to an embodiment of the inventive concept may be driven at a low voltage and realize improved emission efficiency and long life.

In some embodiments, the first layer may be disposed adjacent to the anode.

The hole injection properties from the anode may be improved by disposing the first layer including the electron accepting compound adjacent to the anode in the organic EL device according to an embodiment of the inventive concept.

In other embodiments, the third layer including the compound represented by General Formula (2) of the above Formula 1 may be disposed adjacent to the emission layer.

In the organic EL device according to an embodiment of the inventive concept, the hole transporting laminated structure may be passivated from electrons not consumed in the emission layer, and the diffusion of excited energy generated in the emission layer into the hole transporting laminated structure may be prevented.

In still other embodiments, the first layer, the second layer and the third layer may independently include a compound having a carbazolyl group.

The charge transporting properties and current flow durability of the organic EL device according to an embodiment of the inventive concept may be improved by including a compound having a carbazolyl group in the hole transporting laminated structure.

In even other embodiments, the first layer, the second layer and the third layer may independently include a compound represented by General Formula (1) of the above Formula 1.

In the organic EL device according to an embodiment of the inventive concept, the hole transporting laminated structure may be passivated from electrons not consumed in the emission layer, and the diffusion of excited energy generated in the emission layer into the hole transporting laminated structure may be prevented. In addition, the charge transporting properties and current flow durability of the organic EL device may be improved by including a compound having a carbazolyl group in the hole transporting laminated structure.

In yet other embodiments, the first layer may include at least one of compounds represented in the following Formula 2, Formula 3 and Formula 4.

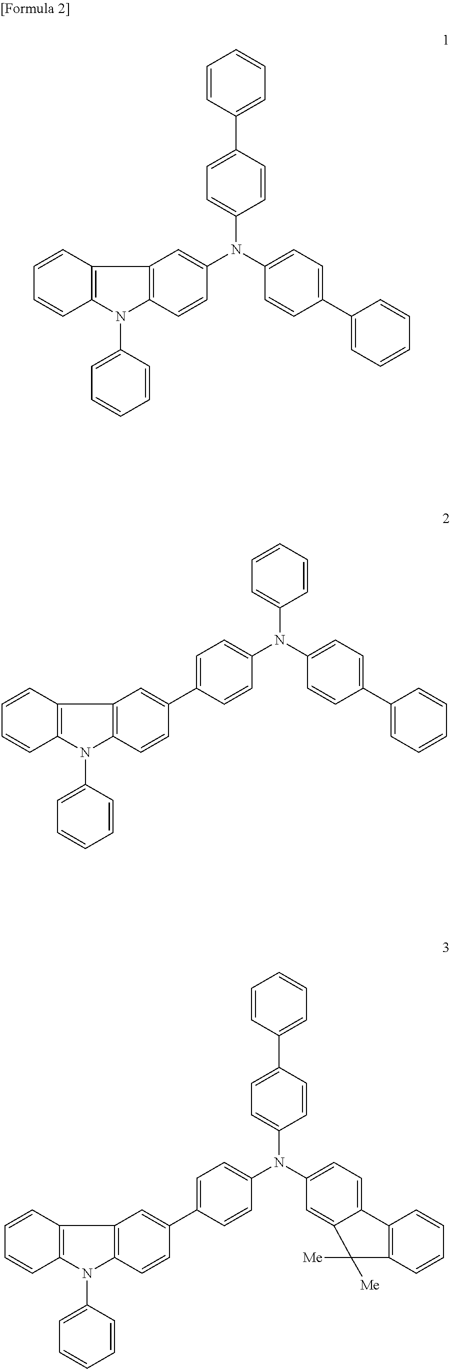 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

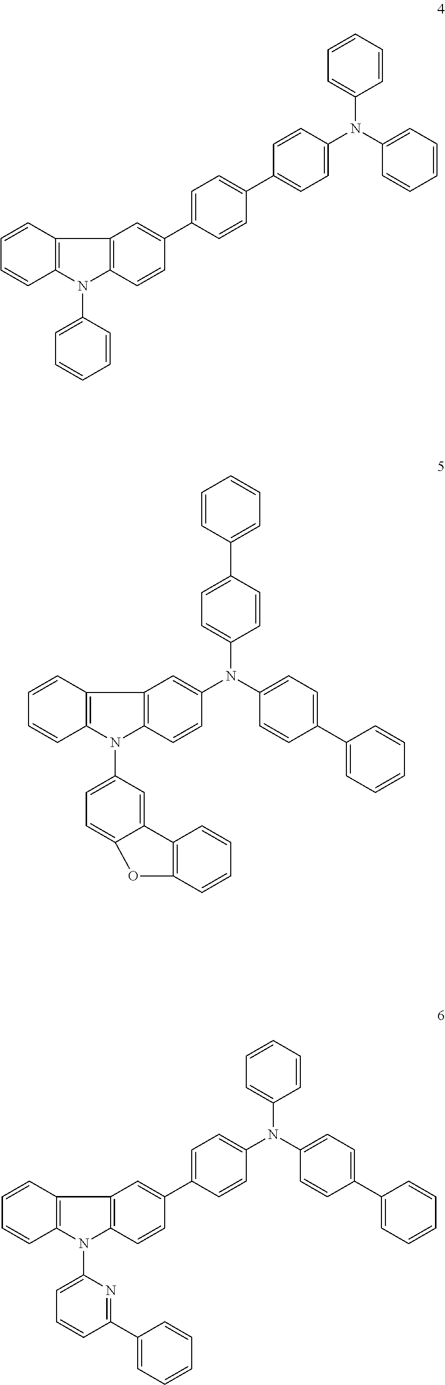 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

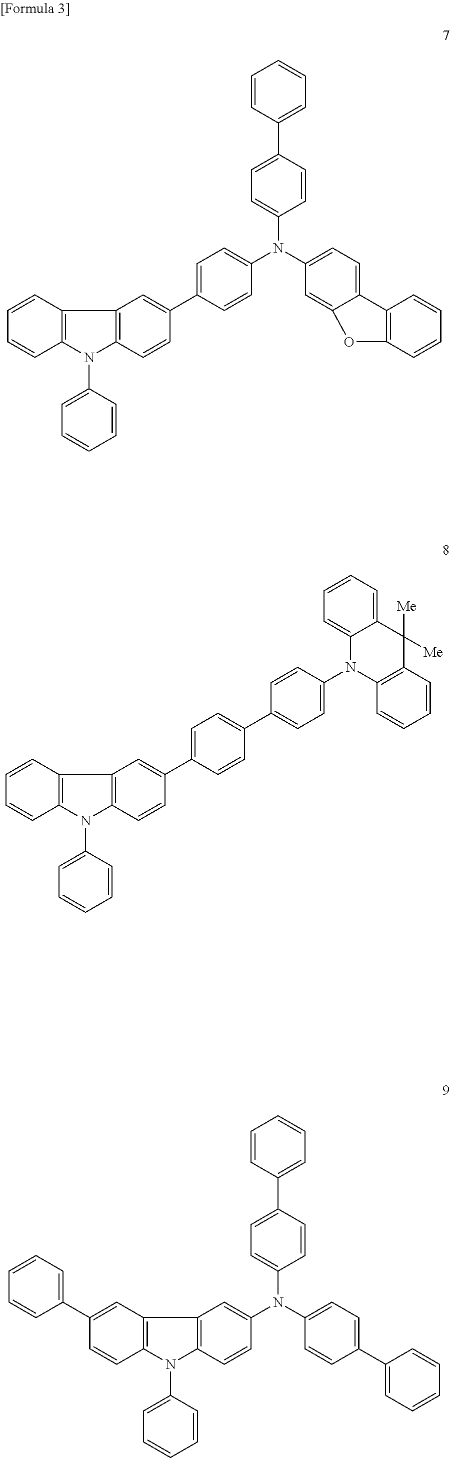 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

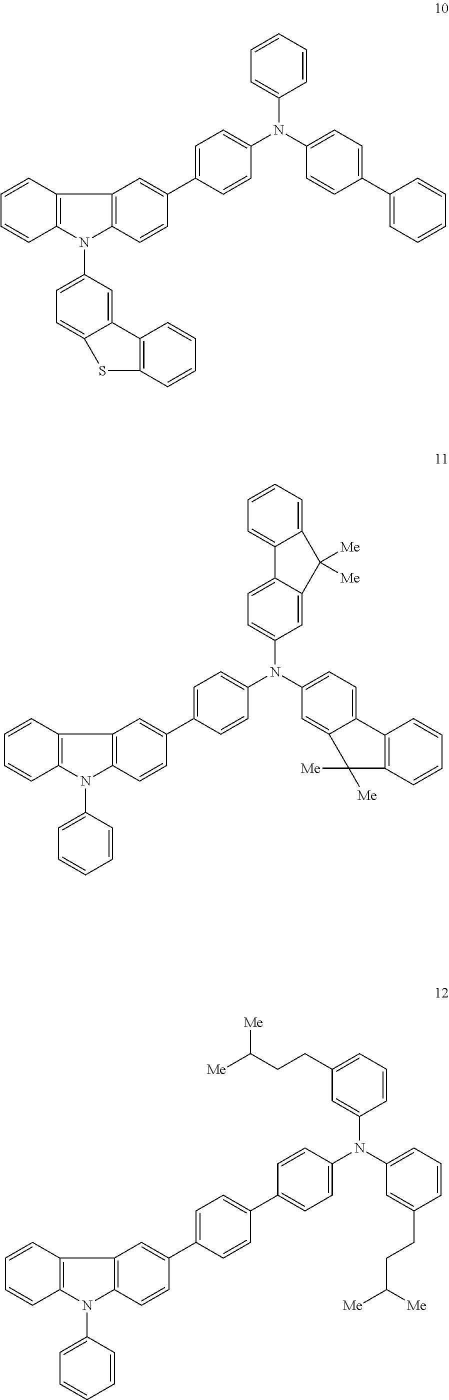 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

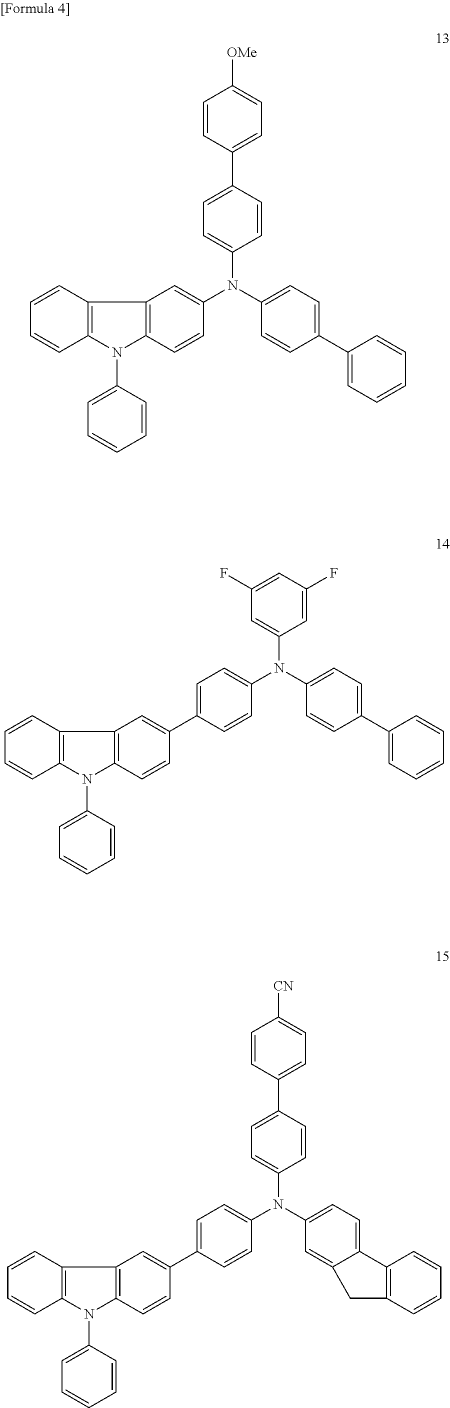 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

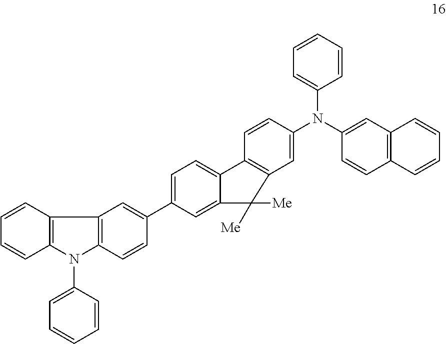 [SMILES: CC1(C)c2cc(-c3ccc4c(c3)c3ccccc3n4-c3ccccc3)ccc2-c2ccc(N(c3ccccc3)c3ccc4ccccc4c3)cc21]

In further embodiments, the electron accepting compound may include at least one of compounds represented in the following Formula 5.

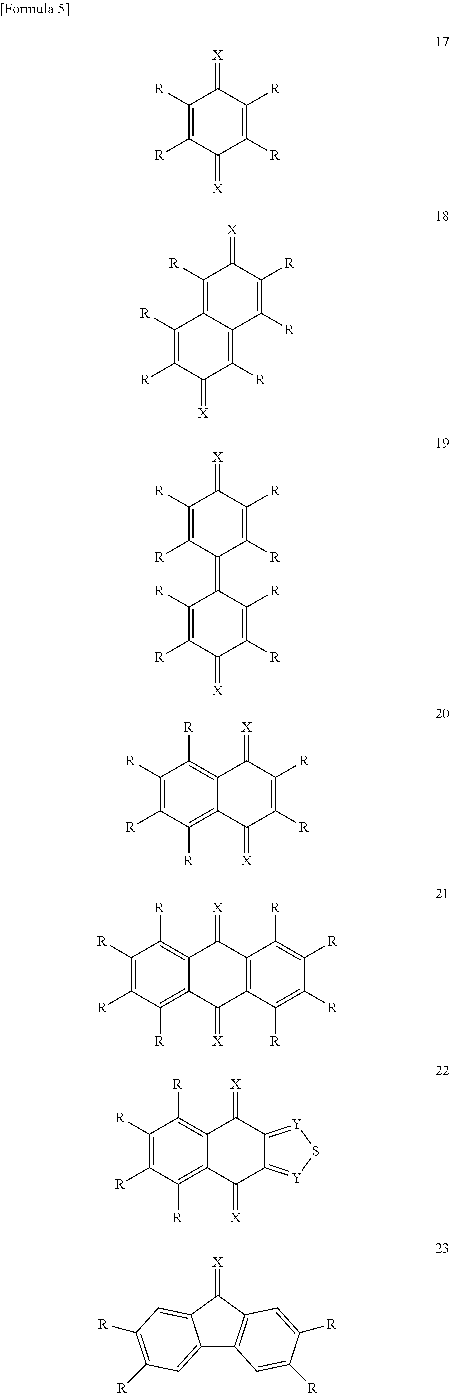

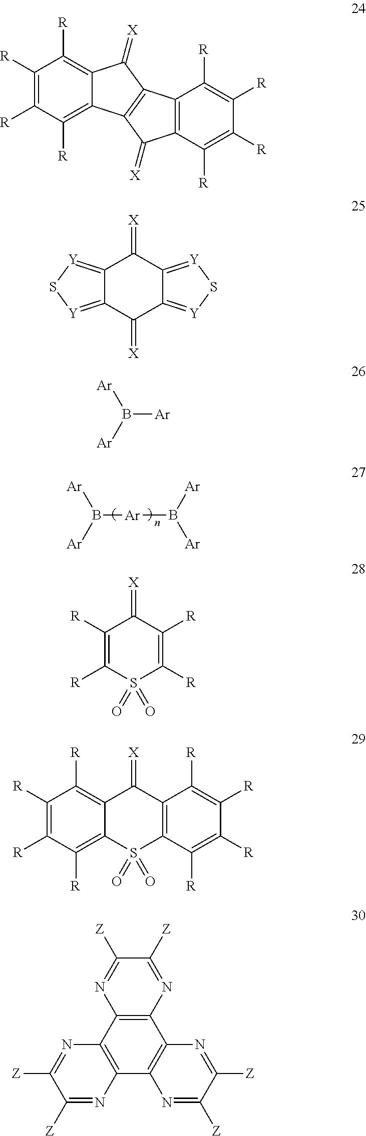

In the above electron accepting Compounds 17 to 30, R is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms or a heteroaryl group having 5 to 50 carbon atoms. Ar is a substituted or unsubstituted electron withdrawing aryl group having 6 to 50 carbon atoms or a substituted or unsubstituted heteroaryl group having 5 to 50 carbon atoms. Y is a methine group (—CH═) or a nitrogen atom (—N═). Z is pseudohalogen or sulfur (S). X is one of the following substituents of X1 to X7.

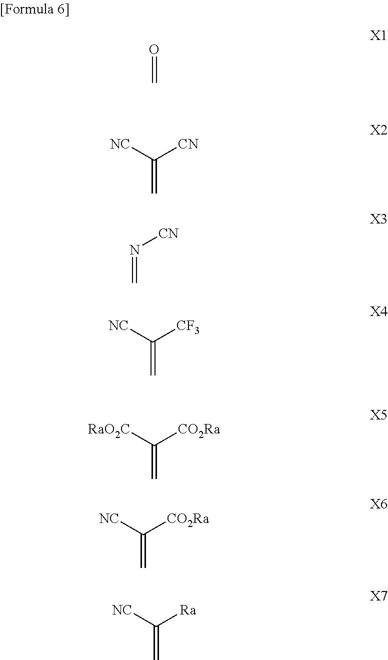

In the above Formula 6, Ra is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms for forming a ring or a substituted or unsubstituted heteroaryl group having 5 to 50 carbon atoms for forming a ring.

In still further embodiments, the third layer may include at least one of compounds represented in the following Formula 7, Formula 8, Formula 9, Formula 10, Formula 11 and Formula 12.

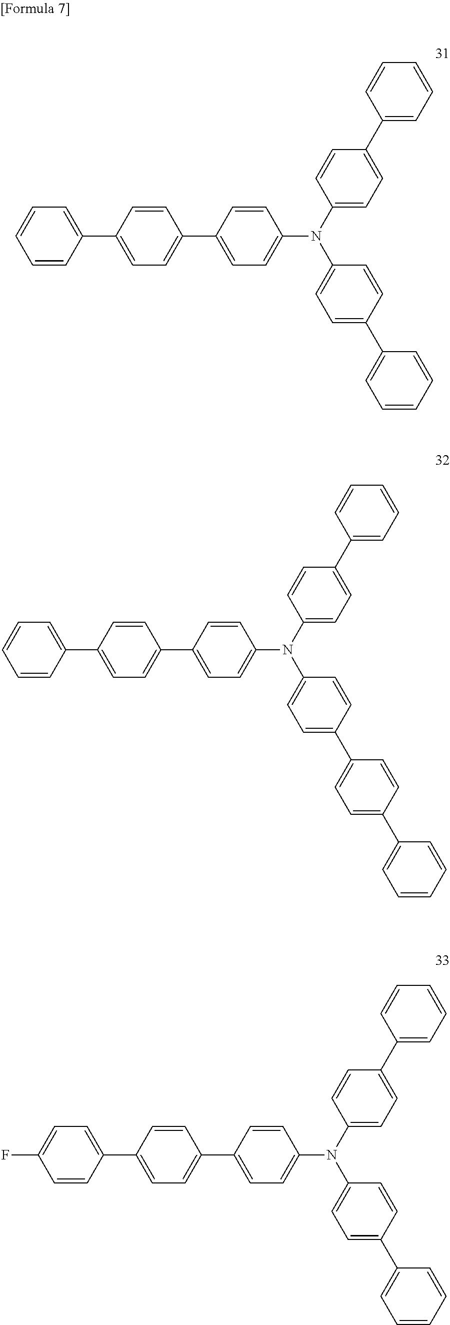 [SMILES: c1ccc(-c2ccc(-c3ccc(N(c4ccc(-c5ccccc5)cc4)c4ccc(-c5ccccc5)cc4)cc3)cc2)cc1 ; c1ccc(-c2ccc(-c3ccc(N(c4ccc(-c5ccccc5)cc4)c4ccc(-c5ccc(-c6ccccc6)cc5)cc4)cc3)cc2)cc1 ; Fc1ccc(-c2ccc(-c3ccc(N(c4ccc(-c5ccccc5)cc4)c4ccc(-c5ccccc5)cc4)cc3)cc2)cc1]

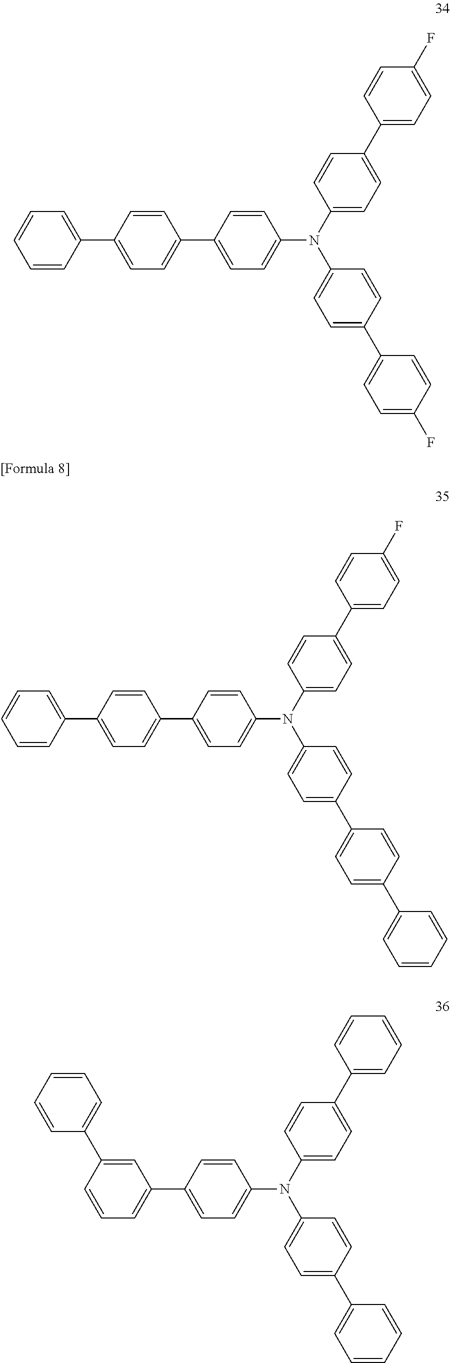 [SMILES: Fc1ccc(-c2ccc(N(c3ccc(-c4ccc(F)cc4)cc3)c3ccc(-c4ccc(-c5ccccc5)cc4)cc3)cc2)cc1 ; Fc1ccc(-c2ccc(N(c3ccc(-c4ccc(-c5ccccc5)cc4)cc3)c3ccc(-c4ccc(-c5ccccc5)cc4)cc3)cc2)cc1 ; c1ccc(-c2ccc(N(c3ccc(-c4ccccc4)cc3)c3ccc(-c4cccc(-c5ccccc5)c4)cc3)cc2)cc1]

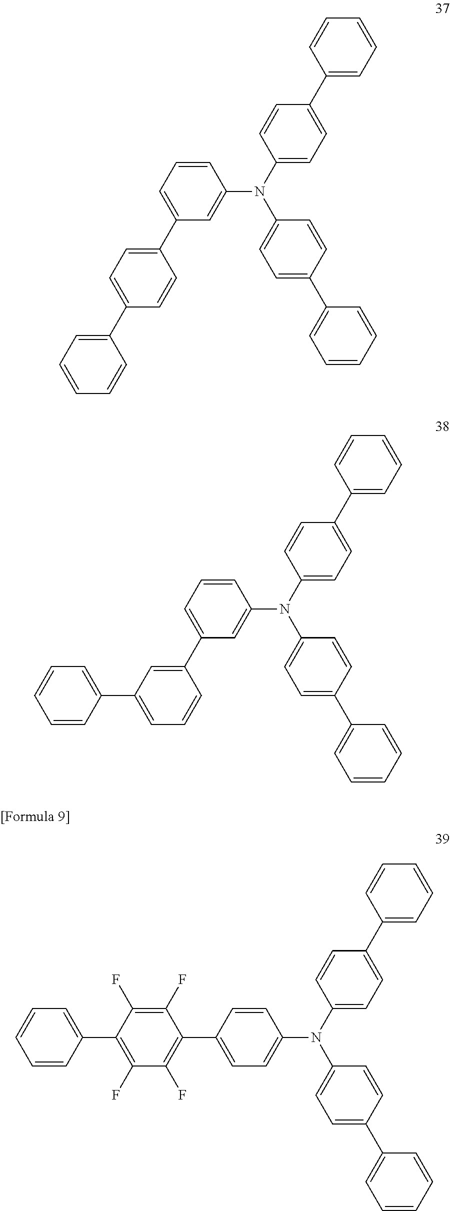 [SMILES: c1ccc(-c2ccc(-c3cccc(N(c4ccc(-c5ccccc5)cc4)c4ccc(-c5ccccc5)cc4)c3)cc2)cc1 ; c1ccc(-c2ccc(N(c3ccc(-c4ccccc4)cc3)c3cccc(-c4cccc(-c5ccccc5)c4)c3)cc2)cc1 ; Fc1c(F)c(-c2ccc(N(c3ccc(-c4ccccc4)cc3)c3ccc(-c4ccccc4)cc3)cc2)c(F)c(F)c1-c1ccccc1]

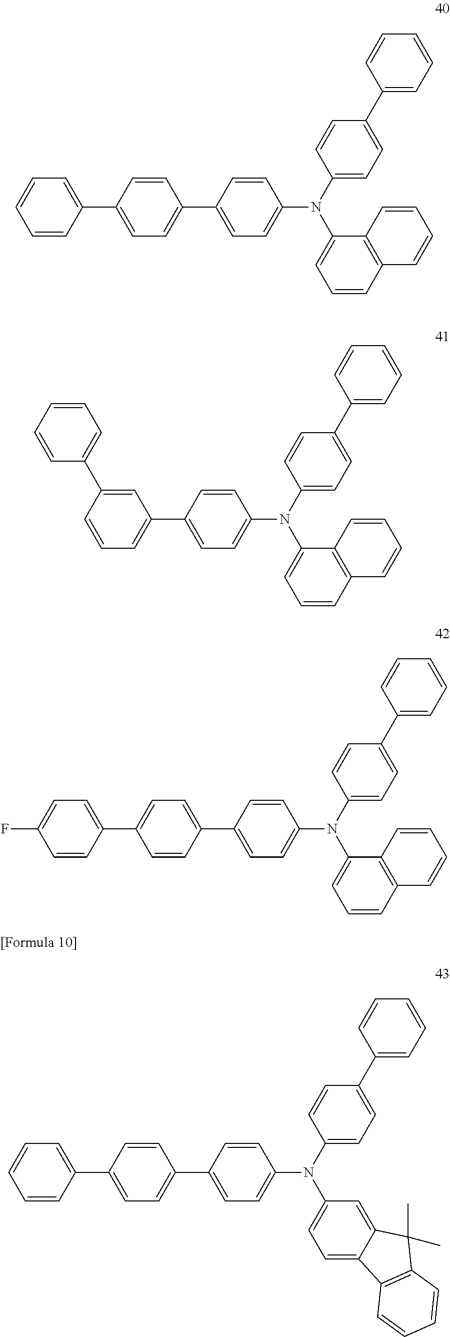 [SMILES: c1ccc(-c2ccc(-c3ccc(N(c4ccc(-c5ccccc5)cc4)c4cccc5ccccc45)cc3)cc2)cc1 ; c1ccc(-c2ccc(N(c3ccc(-c4cccc(-c5ccccc5)c4)cc3)c3cccc4ccccc34)cc2)cc1 ; Fc1ccc(-c2ccc(-c3ccc(N(c4ccc(-c5ccccc5)cc4)c4cccc5ccccc45)cc3)cc2)cc1 ; CC1(C)c2ccccc2-c2ccc(N(c3ccc(-c4ccccc4)cc3)c3ccc(-c4ccc(-c5ccccc5)cc4)cc3)cc21]

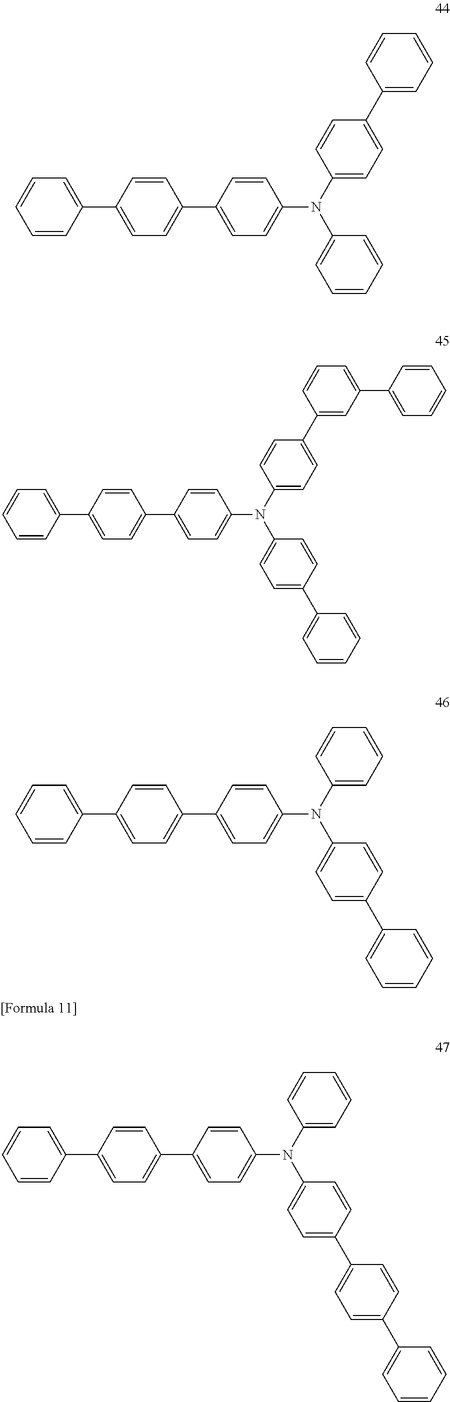 [SMILES: c1ccc(-c2ccc(-c3ccc(N(c4ccccc4)c4ccc(-c5ccccc5)cc4)cc3)cc2)cc1 ; c1ccc(-c2ccc(-c3ccc(N(c4ccc(-c5ccccc5)cc4)c4ccc(-c5cccc(-c6ccccc6)c5)cc4)cc3)cc2)cc1 ; c1ccc(-c2ccc(-c3ccc(N(c4ccccc4)c4ccc(-c5ccccc5)cc4)cc3)cc2)cc1 ; c1ccc(-c2ccc(-c3ccc(N(c4ccccc4)c4ccc(-c5ccc(-c6ccccc6)cc5)cc4)cc3)cc2)cc1]

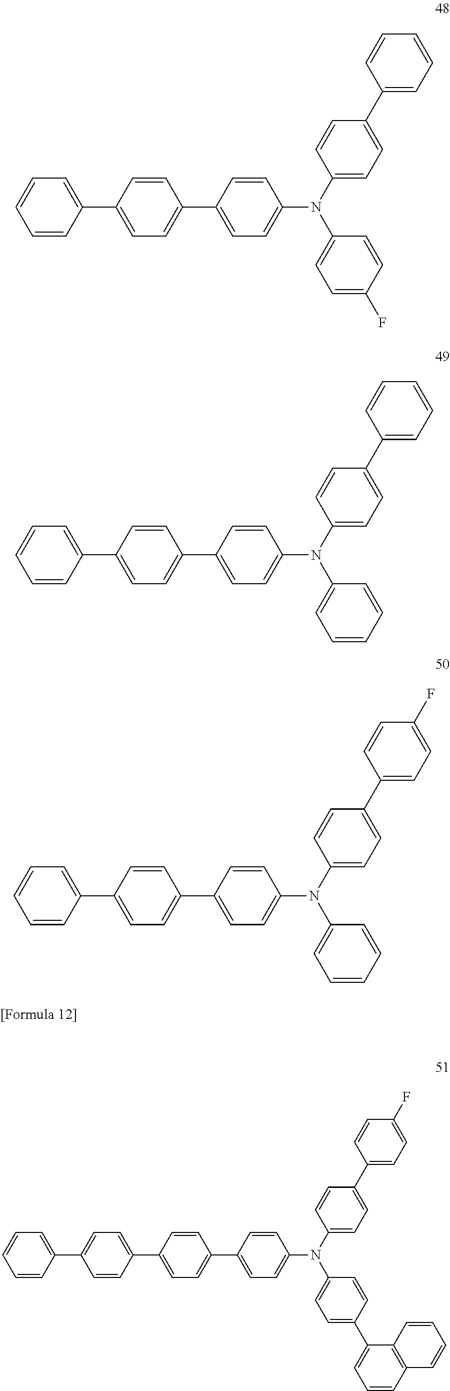 [SMILES: Fc1ccc(N(c2ccc(-c3ccccc3)cc2)c2ccc(-c3ccc(-c4ccccc4)cc3)cc2)cc1 ; c1ccc(-c2ccc(-c3ccc(N(c4ccccc4)c4ccc(-c5ccccc5)cc4)cc3)cc2)cc1 ; Fc1ccc(-c2ccc(N(c3ccccc3)c3ccc(-c4ccc(-c5ccccc5)cc4)cc3)cc2)cc1 ; Fc1ccc(-c2ccc(N(c3ccc(-c4ccc(-c5ccc(-c6ccccc6)cc5)cc4)cc3)c3ccc(-c4cccc5ccccc45)cc3)cc2)cc1]

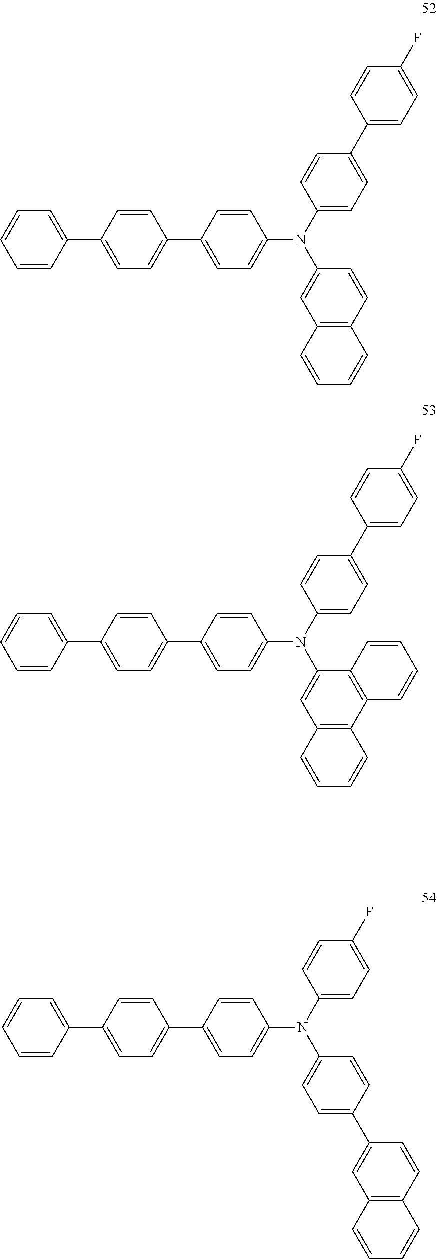 [SMILES: Fc1ccc(-c2ccc(N(c3ccc(-c4ccc(-c5ccccc5)cc4)cc3)c3ccc4ccccc4c3)cc2)cc1 ; Fc1ccc(-c2ccc(N(c3ccc(-c4ccc(-c5ccccc5)cc4)cc3)c3cc4ccccc4c4ccccc34)cc2)cc1 ; Fc1ccc(N(c2ccc(-c3ccc(-c4ccccc4)cc3)cc2)c2ccc(-c3ccc4ccccc4c3)cc2)cc1]

In even further embodiments, the emission layer may include at least one of compounds represented in the following Formula 13, Formula 14 and Formula 15.

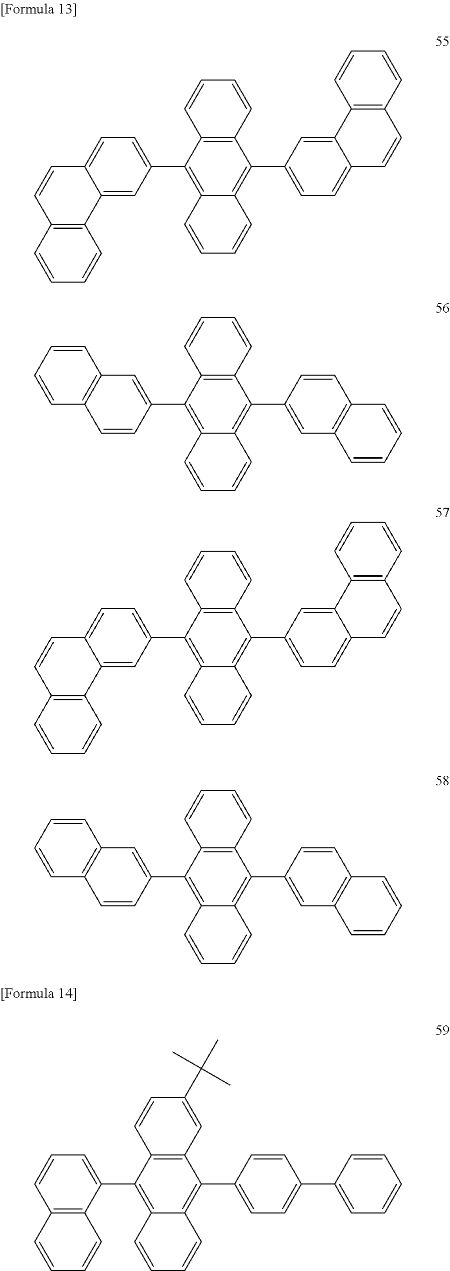

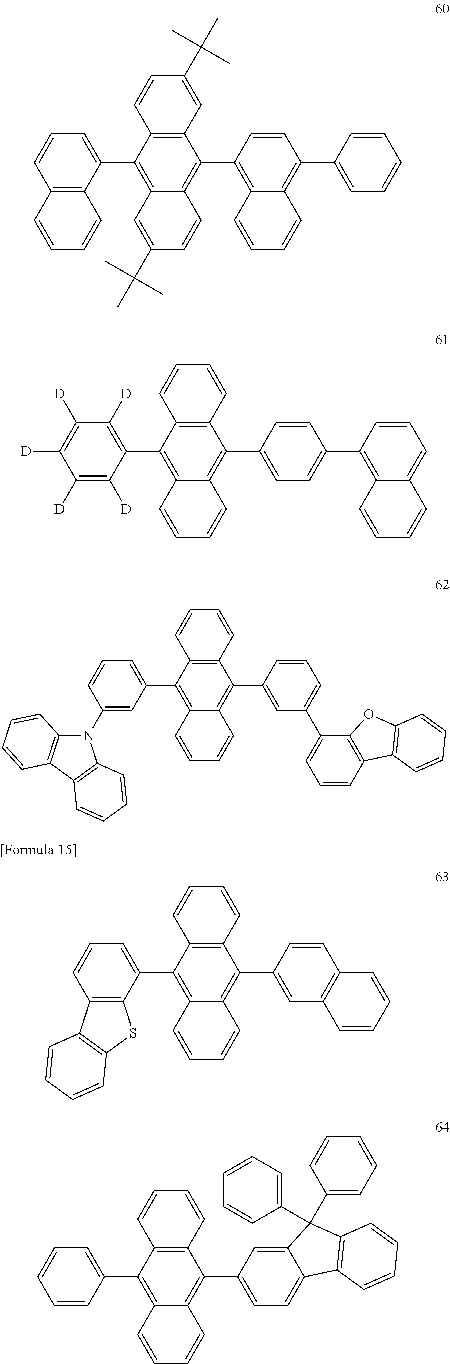

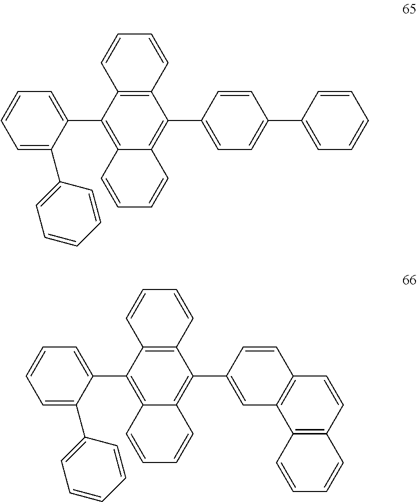

In other embodiments, organic EL devices include an anode and an emission layer for obtaining luminescence via a singlet excited state, and a laminated structure of at least three layers having different components between the anode and the emission layer. The laminated structure includes a first layer formed by using an electron accepting compound having a LUMO level of about −9.0 eV to about −4.0 eV, a second layer disposed closer to the emission layer than the first layer and including a compound represented by General Formula (1) of the following Formula 16, and a third layer disposed closer to the emission layer than the second layer and including a compound represented by General Formula (2) of the following Formula 16. The emission layer includes a compound represented by General Formula (3) of the following Formula 16.

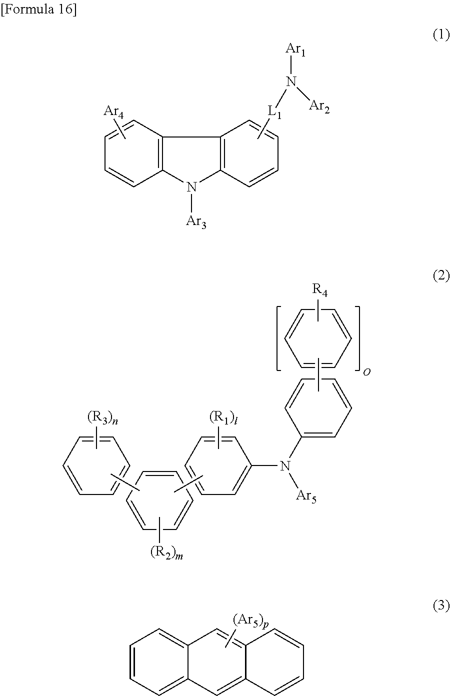

In General Formula (1) of the above Formula 16, Ar1, Ar2 and Ar3 are a substituted or unsubstituted aryl group or a substituted or unsubstituted heteroaryl group, Ar4 is a substituted or unsubstituted aryl group, a substituted or unsubstituted heteroaryl group, a carbazolyl group or an alkyl group, and L1 is a single bond, a substituted or unsubstituted arylene group or a substituted or unsubstituted heteroarylene group. In General Formula (2) of the above Formula 16, R1, R2 and R3 are independently a hydrogen atom, a deuterium atom, a halogen atom, an alkyl group having 1 to 15 carbon atoms, a substituted or unsubstituted aryl group having 6 to 30 carbon atoms for forming a ring, a substituted or unsubstituted heteroaryl group having 1 to 30 carbon atoms for forming a ring, l, m and n are independently an integer satisfying 0≦1≦4, 0≦m≦4, and 0≦n≦5, R4 is a hydrogen atom, a deuterium atom or a fluorine atom, and o is an integer satisfying 0≦o≦3, and Ar5 is a substituted or unsubstituted aryl group having 6 to 30 carbon atoms for forming a ring. In General Formula (3) of the above Formula 16, each Ar6 is independently a hydrogen atom, a deuterium atom, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group or a hydroxyl group, and p is an integer from 1 to 10.

The organic EL device according to an embodiment of the inventive concept may be driven at a low voltage and have improved emission efficiency and long life.

In some embodiments, the first layer may be disposed adjacent to the anode.

The hole injection properties from the anode may be improved by disposing the first layer including the electron accepting compound adjacent to the anode in the organic EL device according to an embodiment of the inventive concept.

In other embodiments, the third layer may be disposed adjacent to the emission layer.

### BRIEF DESCRIPTION OF THE DRAWINGS

Features will be apparent to those of skill in the art by describing in detail exemplary embodiments with reference to the attached drawings in which:

FIG. 1 illustrates a schematic diagram of an organic EL device 100 according to an embodiment;

FIG. 2 illustrates a schematic diagram of an organic EL device 200 according to an embodiment;

FIG. 3 illustrates a schematic diagram of an organic EL device 300 according to an embodiment; and

FIG. 4 illustrates a schematic diagram of an organic EL device 400 according to an embodiment of the inventive concept.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

Hole injection properties from an anode may be improved by doping an electron accepting compound in a hole transport layer and by disposing a layer including the electron accepting compound adjacent to the anode. According to an embodiment, a plurality of laminated layers having hole transporting properties between an emission layer and an anode are regarded as a structure, and a layer of a hole transport material doped with an electron accepting material may be laminated as a layer disposed adjacent to the anode in the laminated structure and an intermediate layer including an amine derivative having a terphenyl group may be laminated as a layer adjacent to the emission layer.

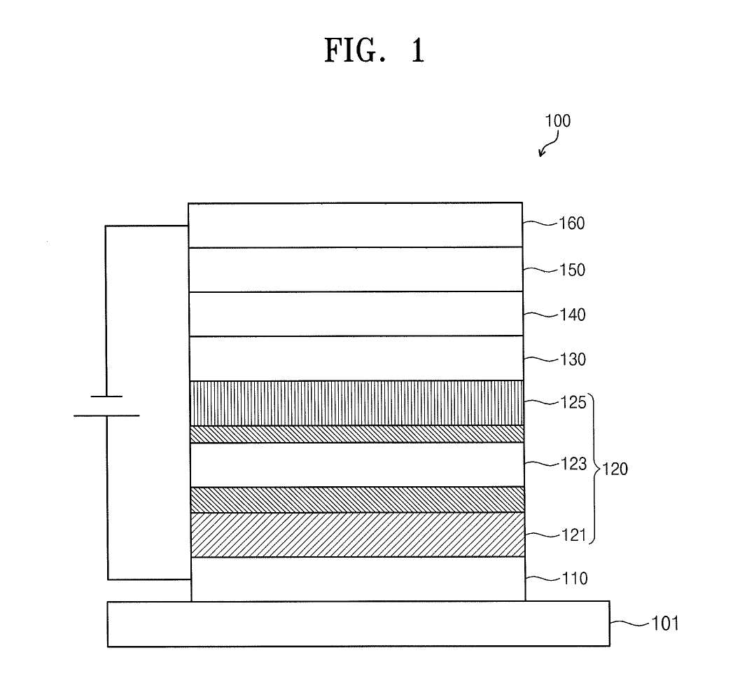

The organic EL device according to an embodiment will be explained. FIG. 1 illustrates a schematic diagram of an organic EL device 100 according to an embodiment. The organic EL device 100 may include, e.g., an anode 110 on a substrate 101, an emission layer 130 producing luminescence mainly via a singlet excited state, an electron transport layer 140, an electron injection layer 150, and a cathode 160. Between the anode 110 and the emission layer 130, a hole transport band 120 may be disposed. The hole transport band 120 may be a band for disposing a hole transport layer or a hole injection layer.

According to an embodiment, to realize an organic EL device driven at a low voltage and having improved emission efficiency and long life, a laminated structure of three layers having different components (a first layer 121, a second layer 123, and a third layer 125) may be provided in the hole transport band 120 between the anode 110 and the emission layer 130. At least one layer (the first layer 121) disposed toward the anode 110 of the laminated structure may include a hole transport compound obtained by doping an electron accepting compound (having a LUMO level from about −9.0 eV to about −4.0 eV) into a compound represented by the following Chemical Formula (1). At least one layer (the second layer 123) disposed closer to the emission layer 130 than the first layer 121 may include a compound represented by the following Chemical Formula (1). In addition, at least one layer (the third layer 125) disposed closer to the emission layer 130 than the second layer 123 may include a compound represented by the following Chemical Formula (2). In addition, the emission layer 130 may include a compound represented by the following Chemical Formula (3).

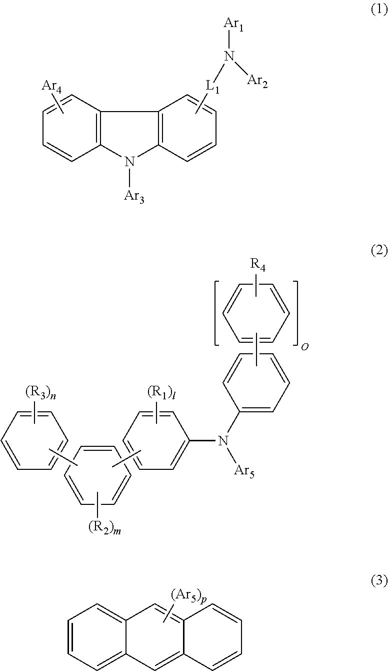

In Chemical Formula (1), Ar₁, Ar₂, and Ar₃ may each independently be or include, e.g., a substituted or unsubstituted aryl group or a substituted or unsubstituted heteroaryl group. Ar₄ may be or include, e.g., a substituted or unsubstituted aryl group, a substituted or unsubstituted heteroaryl group, a carbazolyl group, or an alkyl group. L₁ may be or include, e.g., a single bond, a substituted or unsubstituted arylene group, or a substituted or unsubstituted heteroarylene group.

In Chemical Formula (2), R₁, R₂, and R₃ may each independently be or include, e.g., a hydrogen atom, a halogen atom, an alkyl group having 1 to 15 carbon atoms, a substituted or unsubstituted aryl group having 6 to 30 ring carbon atoms, or a substituted or unsubstituted heteroaryl group having 5 to 30 ring carbon atoms. l, m, and n may each independently be an integer satisfying 0≦1≦4, 0≦m≦4, 0≦n≦5. Each R₄ may independently be or include, e.g., a hydrogen atom or a fluorine atom. o may be an integer satisfying 0≦o≦3. Ar₅ may be or may include, e.g., a substituted or unsubstituted aryl group having 6 to 30 ring carbon atoms.

In Chemical Formula (3), each Ar₆ may independently be or include, e.g., a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group, or a hydroxyl group, and p may be an integer of 1 to 10.

In an implementation, Ar₁ to Ar₄ in Chemical Formula (1) may each independently include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group, or a dibenzothienyl group. In an implementation, the phenyl group, the biphenyl group, the terphenyl group, the fluorenyl group, the carbazolyl group, the dibenzofuranyl group, etc. may be used.

In an implementation, L₁ in Chemical Formula (1) may include, e.g., a phenylene group, a biphenylene group, a terphenylene group, a naphthalene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienyl group, etc. In an implementation, the phenylene group, the biphenylene group, the terphenylene group, the fluorenylene group, the carbazolylene group, the dibenzofuranylene group, etc. may be used.

R₁, R₂, and R₃ in Chemical Formula (2) may each independently include, e.g., a hydrogen atom, a fluorine atom, a chlorine atom, a bromine atom, an iodine atom, a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a n-nonyl group, a n-decyl group, a n-undecyl group, a n-dodecyl group, a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group, or a dibenzothienyl group. In an implementation, the hydrogen atom, the fluorine atom, the methyl group, the phenyl group, the biphenyl group, etc. may be used.

In an implementation, Ar₅ in Chemical Formula (2) may include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a triphenylenylphenyl group, a fluorophenyl group, a fluorobiphenyl group, etc. In an implementation, the biphenyl group, etc. may be used.

In an implementation, Ar₆ in Chemical Formula (3) may include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group and a dibenzothienyl group. Preferably, the phenyl group, the biphenyl group, the terphenyl group, the fluorenyl group, the carbazolyl group, the dibenzofuranyl group, etc. may be used.

In the organic EL device 100, at least one layer of the first layer 121 (including a hole transport compound obtained by doping the compound represented by Chemical Formula (1) with an electron accepting compound having a LUMO level of about −9.0 eV to about −4.0 eV) may be disposed toward the anode 110 of the laminated structure, at least one layer of the second layer 123 (including the compound represented by Chemical Formula (1)) may be disposed closer to the emission layer 130 than the first layer 121, and at least one layer of the third layer 125 (including the compound represented by Chemical Formula (2)) may be disposed closer to the emission layer 130 than the second layer 123. In an implementation, the organic EL device 100 according to an embodiment may include the hole transporting first layer 121 and the second layer 123 including an amine derivative having a carbazolyl group. Thus, the hole transporting laminated structure may be passivated from electrons not consumed in the emission layer 130. In addition, the diffusion of excited energy generated in the emission layer 130 into the hole transporting laminated structure may be reduced and/or prevented, and the charge balance of the whole organic EL device 100 may be controlled.

In the organic EL device 100, the first layer 121 including the electron accepting compound may be disposed toward the anode 110, e.g., adjacent or directly adjacent to the anode 110. By disposing a layer including the electron accepting compound adjacent to the anode 110, hole injection properties from the anode may be improved.

In the organic EL device 100, the second layer 123 including a compound having a carbazolyl group, represented by Chemical Formula (1) may be disposed closer to the emission layer 130 than the first layer 121. By including the compound having the carbazolyl group in the hole transporting laminated structure, charge transporting properties and current flow durability may be improved. In addition, by including the compound represented by Chemical Formula (1) in the second layer 123, the hole transporting laminated structure may be passivated from electrons not consumed in the emission layer 130, and the diffusion of excited energy generated in the emission layer 130 into the hole transporting laminated structure may be prevented.

In addition, by disposing the third layer 125 (including the compound having a terphenyl group and represented by Chemical Formula (2)) closer to the emission layer 130 than the second layer 123, the diffusion of the electron accepting compound included in the first layer 121 into the emission layer 130 may be reduced and/or prevented, and the hole transporting first layer 121 and second layer 123 may be passivated from electrons not consumed in the emission layer 130. In addition, the diffusion of excited energy generated in the emission layer 130 into the hole transporting first layer 121 and second layer 123 may be reduced and/or prevented. In an implementation, the third layer 125 (including the compound represented by Chemical Formula (2)) may be disposed adjacent to, e.g., directly adjacent to, the emission layer 130.

In an implementation, in the organic EL device 100, a compound having a carbazolyl group may be included in all layers of the laminated structure. By including the compound having a carbazolyl group in the hole transporting laminated structure, charge transporting properties and current flow durability may be improved. In an implementation, in the organic EL device 100, the compound represented by Chemical Formula (1) may be included in all layers of the laminated structure. Thus, the hole transporting laminated structure may be passivated from electrons not consumed in the emission layer 130, and the diffusion of excited energy generated in the emission layer 130 into the hole transporting laminated structure may be prevented.

In an implementation, the compound represented by Chemical Formula (1), e.g., included in the first layer 121, may include one of the following Compounds 1 to 6.

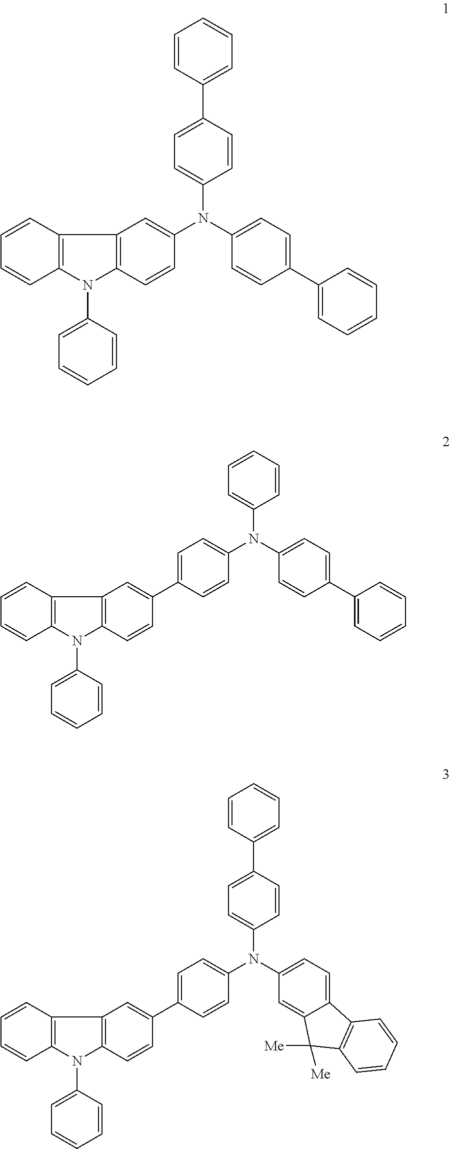 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

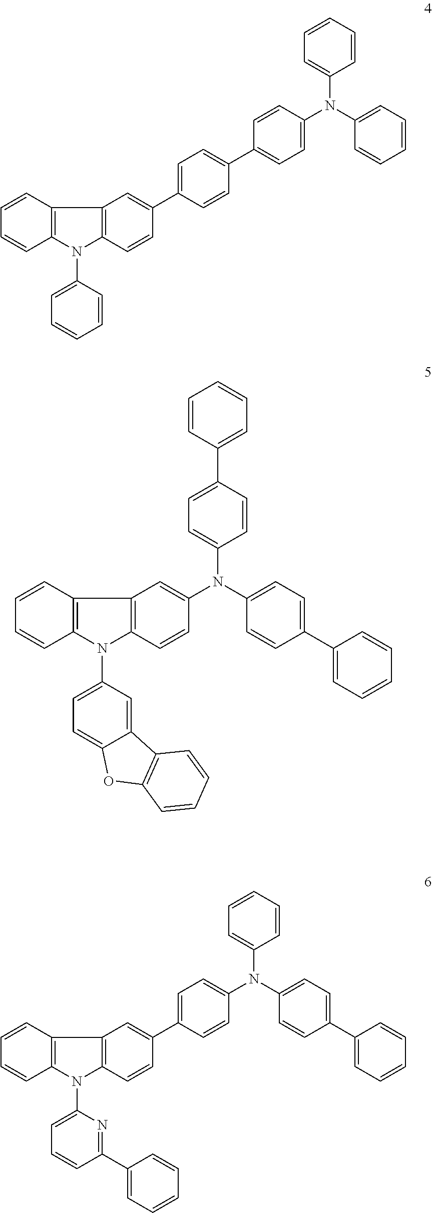 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

In an implementation, the compound represented by Chemical Formula (1), e.g., included in the first layer 121, may include one of the following Compounds 7 to 12.

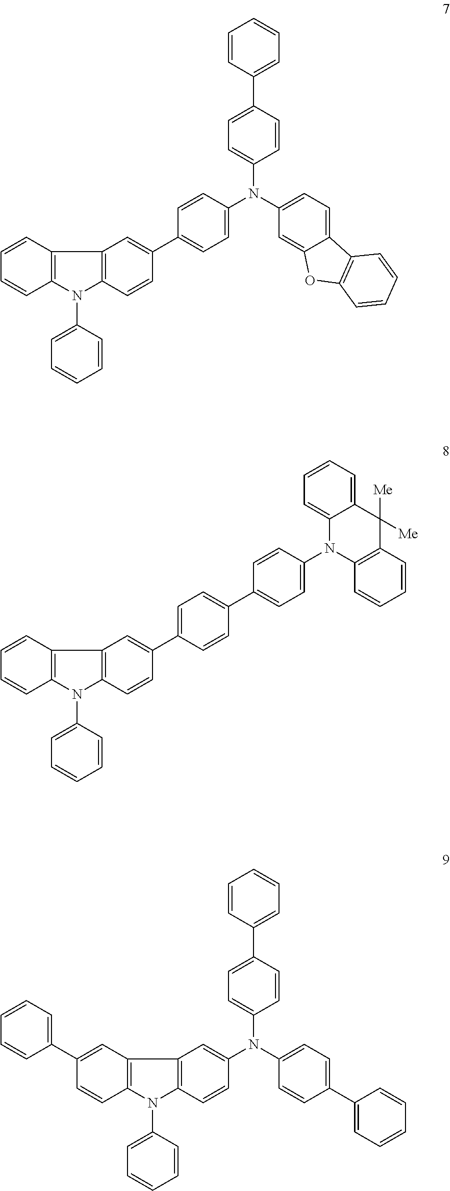 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

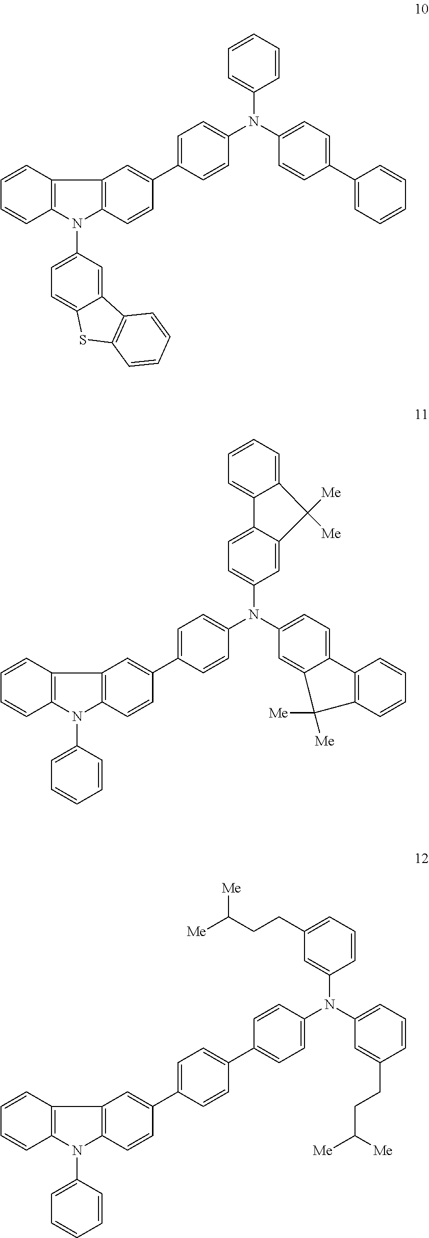 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

In an implementation, the compound represented by Chemical Formula (1), e.g., included in the first layer 121, may include one of the following Compounds 13 to 16.

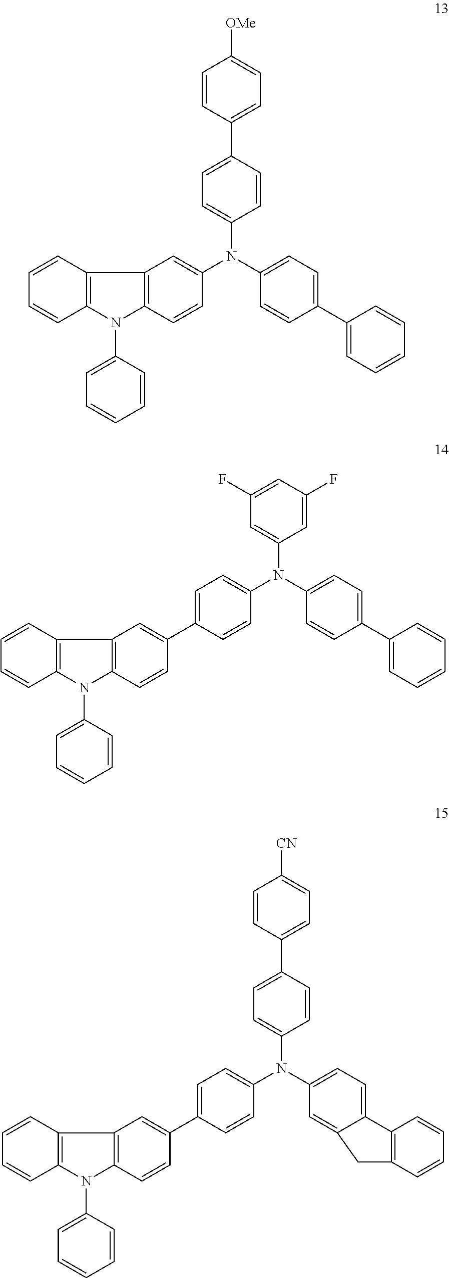 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

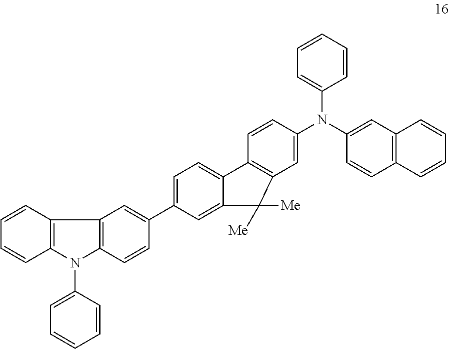 [SMILES: CC1(C)c2cc(-c3ccc4c(c3)c3ccccc3n4-c3ccccc3)ccc2-c2ccc(N(c3ccccc3)c3ccc4ccccc4c3)cc21]

In an implementation, the electron accepting compound (doped in the compound represented by Chemical Formula (1) and included in the first layer 121) may include a compound represented by one of the following Chemical Formulae 17 to 30. In an implementation, a doping amount of the electron accepting compound may be about 0.1% to about 50%, e.g., about 0.5% to about 5%, with respect to a weight of the compound represented by Chemical Formula (1).

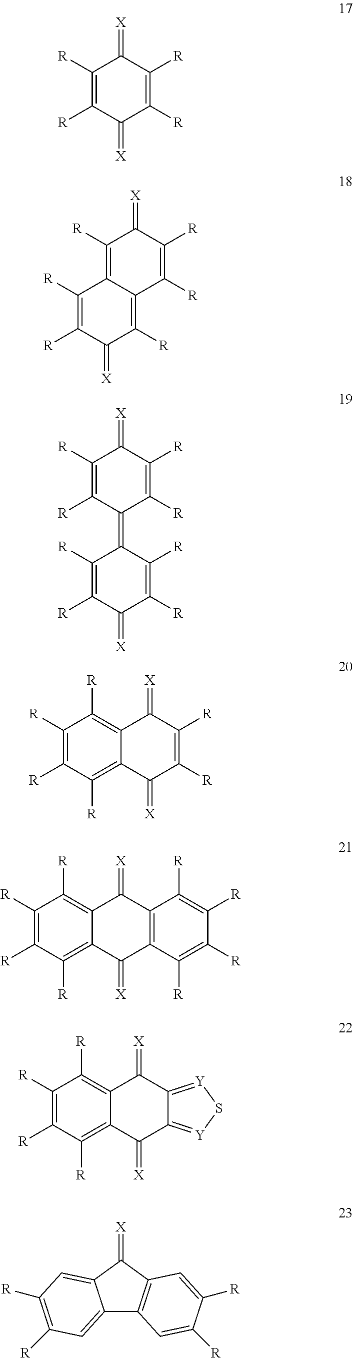

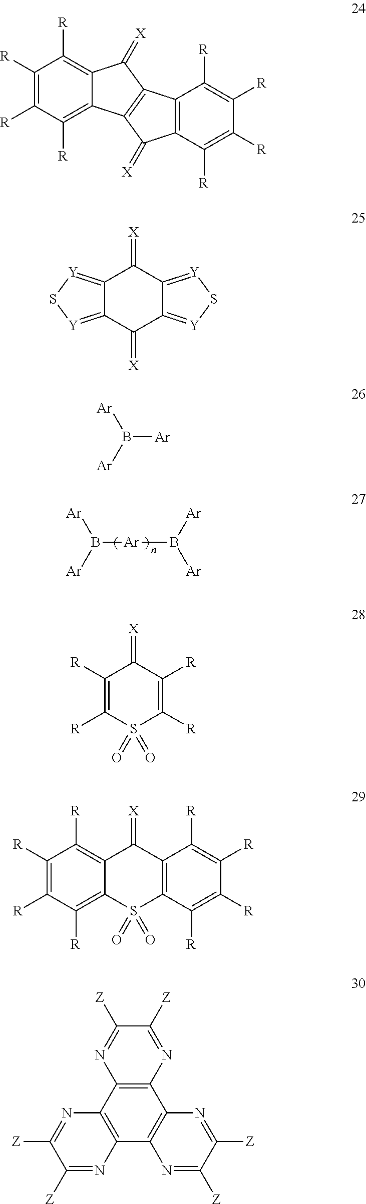

In Chemical Formulae 17 to 30, each R may independently be or include, e.g., a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms, or a heteroaryl group having 5 to 50 carbon atoms. Each Ar may independently be or include, e.g., a substituted or unsubstituted electron withdrawing aryl group having 6 to 50 (e.g., ring) carbon atoms or a substituted or unsubstituted heteroaryl group having 5 to 50 ring carbon atoms. Each Y may independently include, e.g., a methine group (—CH═) or a nitrogen atom (—N═). Each Z may independently include, e.g., a pseudohalogen or sulfur (S). Each X may independently include a group represented by one of the following Chemical Formulae X1 to X7.

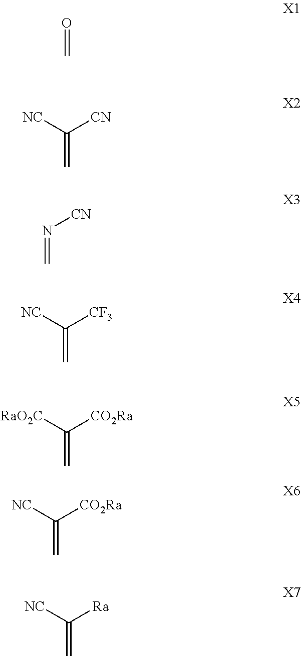

In Chemical Formulae X1 to X7, Ra may be or include, e.g., a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 ring carbon atoms, or a substituted or unsubstituted heteroaryl group having 5 to 50 ring carbon atoms.

Examples of the substituted or unsubstituted aryl group having 6 to 50 ring carbon atoms or the substituted or unsubstituted heteroaryl group having 5 to 50 ring carbon atoms may include a phenyl group, a 1-naphtyl group, a 2-naphtyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphtyl group, a 4-methyl-1-naphtyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyradinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrol-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrol-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl 3-indolyl group, etc.

Examples of the substituted or unsubstituted fluoroalkyl group having 1 to 50 carbon atoms may include a perfluoroalkyl group such as a trifluoromethyl group, a pentafluoroethyl group, a heptafluoropropyl group, a heptadecafluorooctane group, etc. or a monofluoromethyl group, a difluoromethyl group, a trifluoroethyl group, a tetrafluoropropyl group, an octafluoropentyl group, etc.

Examples of the substituted or unsubstituted alkyl group having 1 to 50 carbon atoms may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms may include, e.g., a group represented by —OY, and examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

A halogen atom represented by R and Ra may include, e.g., fluorine, chlorine, bromine, and iodine.

The second layer 123 according to an embodiment may include a compound represented by Chemical Formula (1). In an implementation, the compound represented by Chemical Formula (1) may include, e.g., the above-described Compounds 1 to 16.

The third layer according to an embodiment may include a compound represented by Chemical Formula (2). In an implementation, the compound represented by Chemical Formula (2) may include one of the following Compounds 31 to 34.

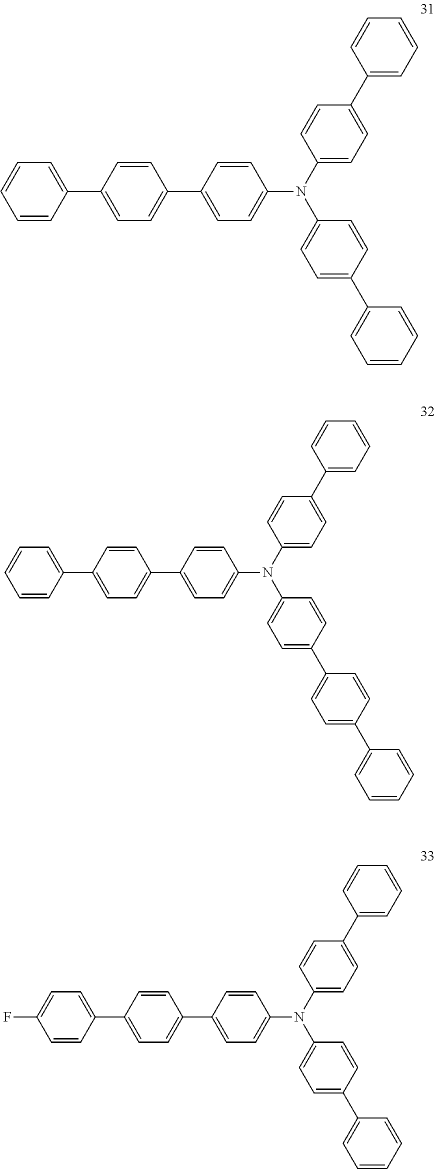 [SMILES: c1ccc(-c2ccc(-c3ccc(N(c4ccc(-c5ccccc5)cc4)c4ccc(-c5ccccc5)cc4)cc3)cc2)cc1 ; c1ccc(-c2ccc(-c3ccc(N(c4ccc(-c5ccccc5)cc4)c4ccc(-c5ccc(-c6ccccc6)cc5)cc4)cc3)cc2)cc1 ; Fc1ccc(-c2ccc(-c3ccc(N(c4ccc(-c5ccccc5)cc4)c4ccc(-c5ccccc5)cc4)cc3)cc2)cc1]

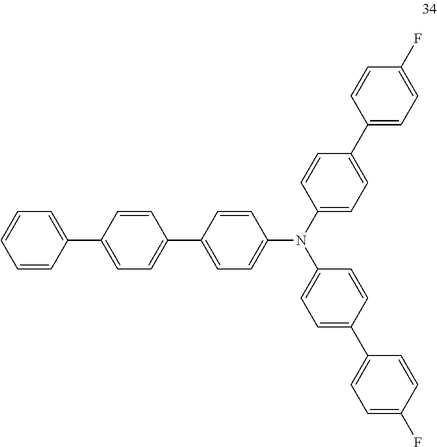 [SMILES: Fc1ccc(-c2ccc(N(c3ccc(-c4ccc(F)cc4)cc3)c3ccc(-c4ccc(-c5ccccc5)cc4)cc3)cc2)cc1]

In an implementation, the compound represented by Chemical Formula (2) may include one of the following Compounds 35 to 38.

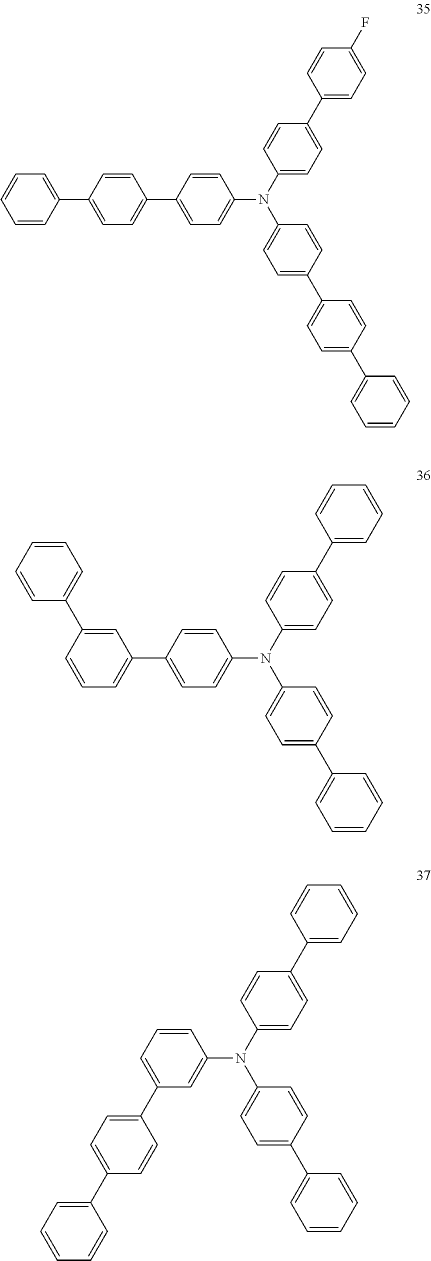 [SMILES: Fc1ccc(-c2ccc(N(c3ccc(-c4ccc(-c5ccccc5)cc4)cc3)c3ccc(-c4ccc(-c5ccccc5)cc4)cc3)cc2)cc1 ; c1ccc(-c2ccc(N(c3ccc(-c4ccccc4)cc3)c3ccc(-c4cccc(-c5ccccc5)c4)cc3)cc2)cc1 ; c1ccc(-c2ccc(-c3cccc(N(c4ccc(-c5ccccc5)cc4)c4ccc(-c5ccccc5)cc4)c3)cc2)cc1]

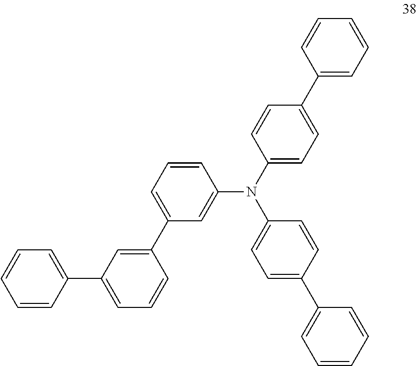 [SMILES: c1ccc(-c2ccc(N(c3ccc(-c4ccccc4)cc3)c3cccc(-c4cccc(-c5ccccc5)c4)c3)cc2)cc1]

In an implementation, the compound represented by Chemical Formula (2) may include one of the following Compounds 39 to 42.

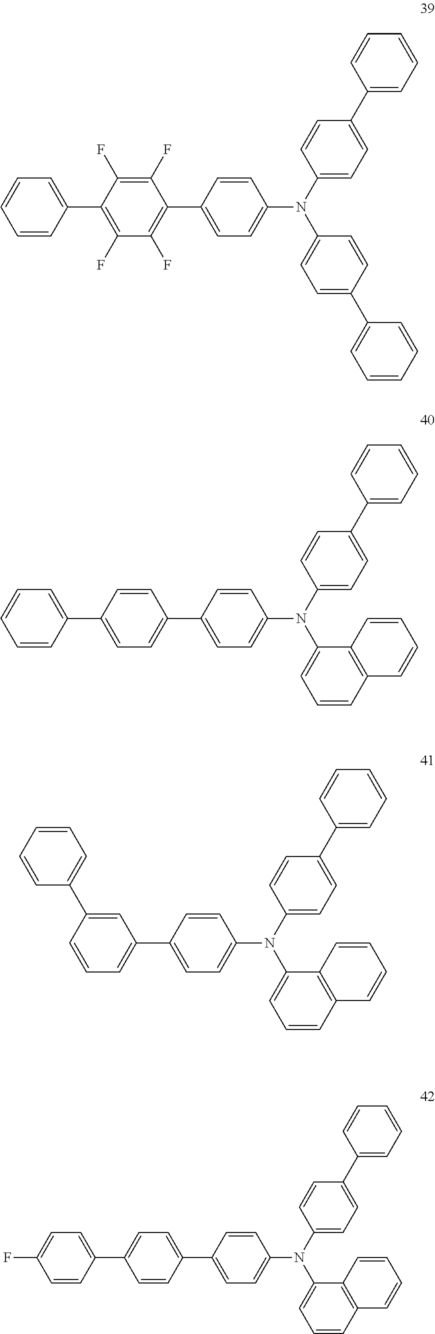 [SMILES: Fc1c(F)c(-c2ccc(N(c3ccc(-c4ccccc4)cc3)c3ccc(-c4ccccc4)cc3)cc2)c(F)c(F)c1-c1ccccc1 ; c1ccc(-c2ccc(-c3ccc(N(c4ccc(-c5ccccc5)cc4)c4cccc5ccccc45)cc3)cc2)cc1 ; c1ccc(-c2ccc(N(c3ccc(-c4cccc(-c5ccccc5)c4)cc3)c3cccc4ccccc34)cc2)cc1 ; Fc1ccc(-c2ccc(-c3ccc(N(c4ccc(-c5ccccc5)cc4)c4cccc5ccccc45)cc3)cc2)cc1]

In an implementation, the compound represented by Chemical Formula (2) may include one of the following Compounds 43 to 46.

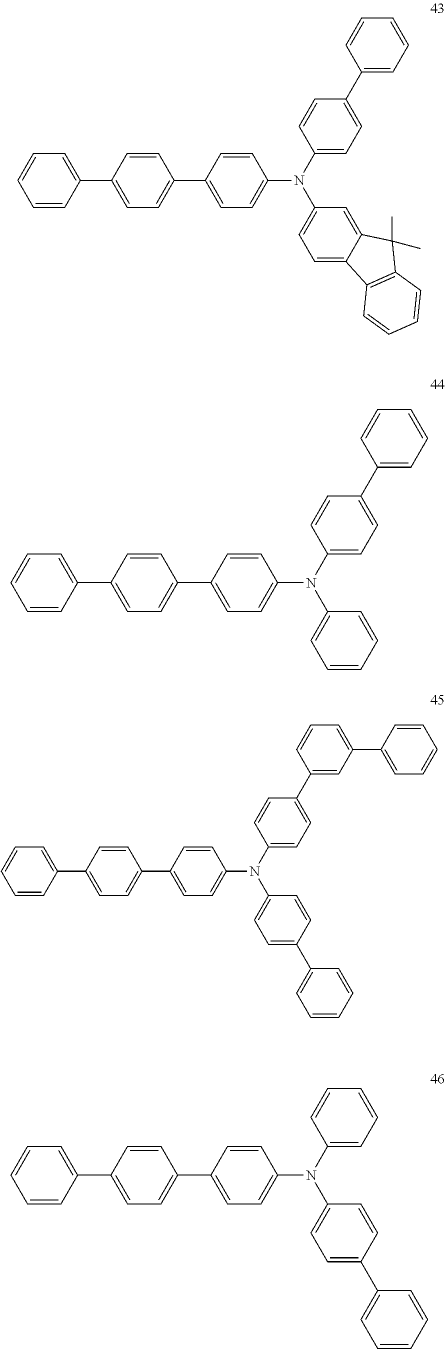 [SMILES: CC1(C)c2ccccc2-c2ccc(N(c3ccc(-c4ccccc4)cc3)c3ccc(-c4ccc(-c5ccccc5)cc4)cc3)cc21 ; c1ccc(-c2ccc(-c3ccc(N(c4ccccc4)c4ccc(-c5ccccc5)cc4)cc3)cc2)cc1 ; c1ccc(-c2ccc(-c3ccc(N(c4ccc(-c5ccccc5)cc4)c4ccc(-c5cccc(-c6ccccc6)c5)cc4)cc3)cc2)cc1 ; c1ccc(-c2ccc(-c3ccc(N(c4ccccc4)c4ccc(-c5ccccc5)cc4)cc3)cc2)cc1]

In an implementation, the compound represented by Chemical Formula (2) may include one of the following Compounds 47 to 50.

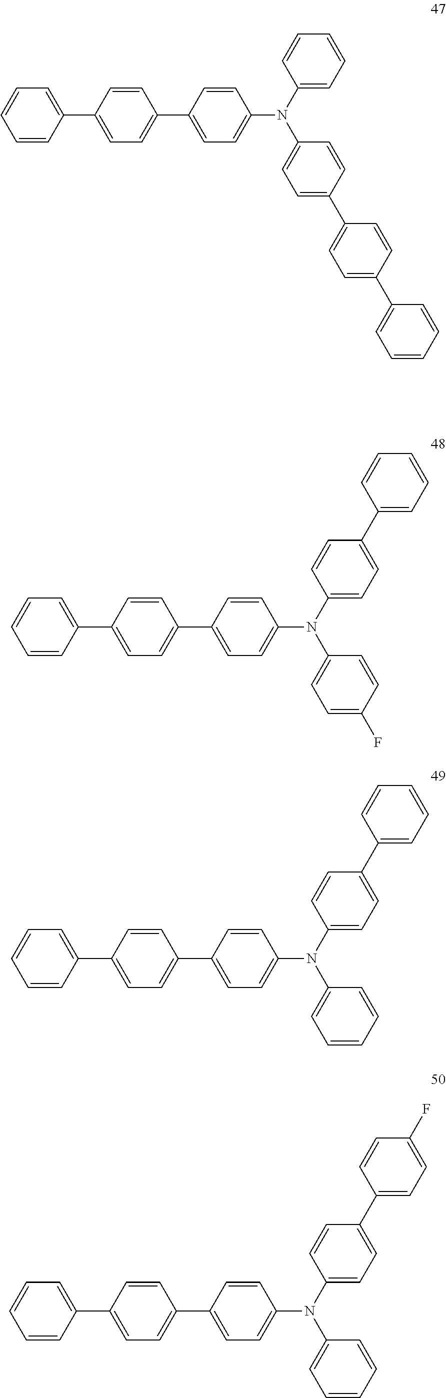

In an implementation, the compound represented by Chemical Formula (2) may include one of the following Compounds 51 to 54.

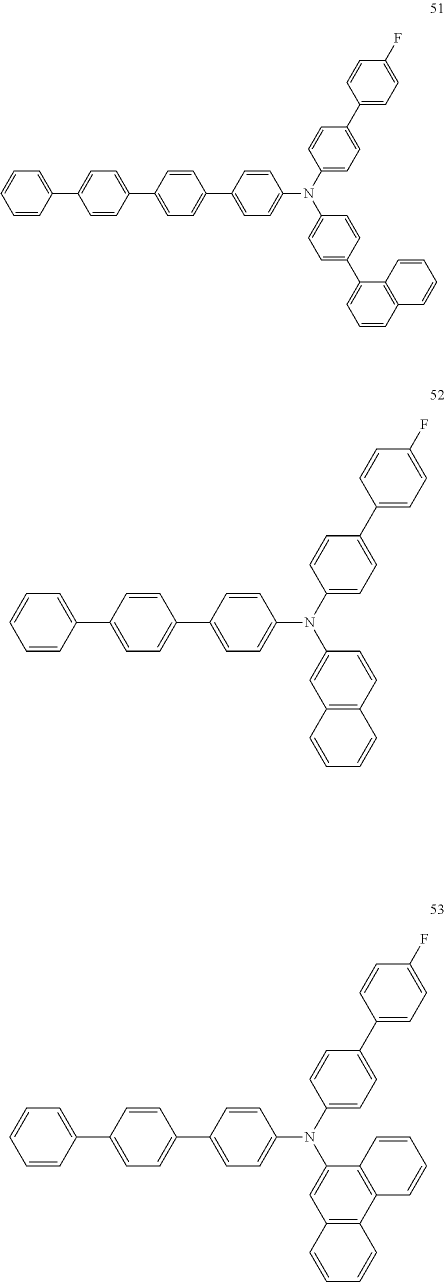 [SMILES: Fc1ccc(-c2ccc(N(c3ccc(-c4ccc(-c5ccc(-c6ccccc6)cc5)cc4)cc3)c3ccc(-c4cccc5ccccc45)cc3)cc2)cc1 ; Fc1ccc(-c2ccc(N(c3ccc(-c4ccc(-c5ccccc5)cc4)cc3)c3ccc4ccccc4c3)cc2)cc1 ; Fc1ccc(-c2ccc(N(c3ccc(-c4ccc(-c5ccccc5)cc4)cc3)c3cc4ccccc4c4ccccc34)cc2)cc1]

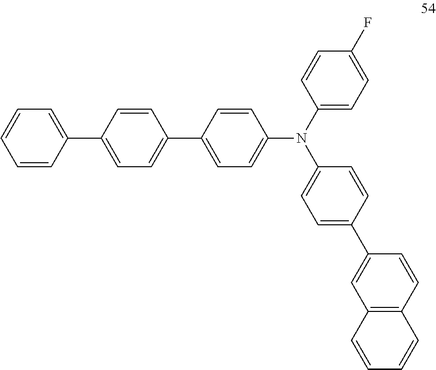 [SMILES: Fc1ccc(N(c2ccc(-c3ccc(-c4ccccc4)cc3)cc2)c2ccc(-c3ccc4ccccc4c3)cc2)cc1]

In an implementation, the compound represented by Chemical Formula (3) and included in the emission layer 130 may include one of the following Compounds 55 to 58.

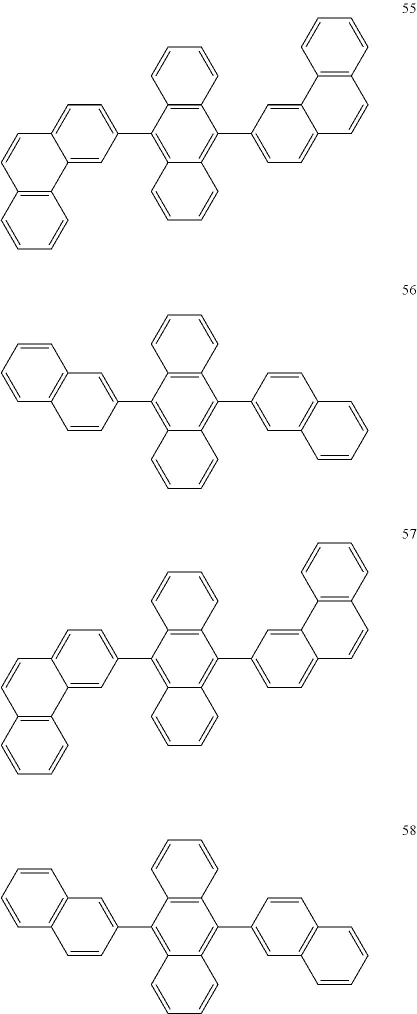

In an implementation, the compound represented by Chemical Formula (3) may include one of the following Compounds 59 to 62.

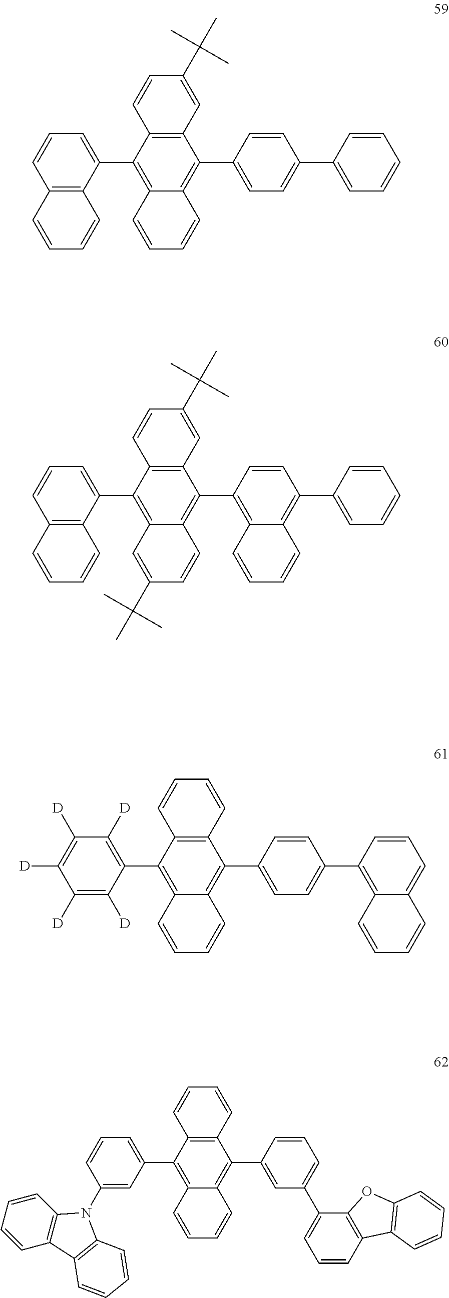

In an implementation, the compound represented by Chemical Formula (3) may include one of the following Compounds 63 to 66.

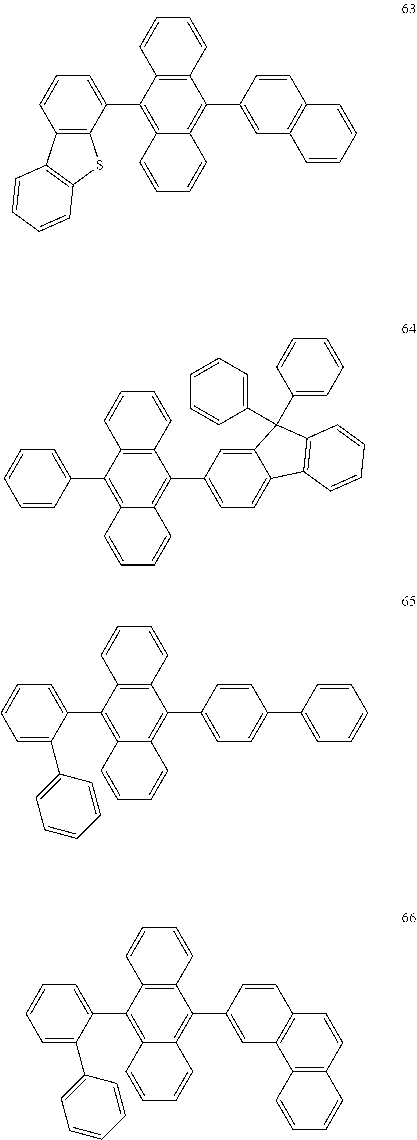

The organic EL device according to an embodiment will be described in more detail. In the organic EL device 100 according to an embodiment, the substrate 101 may be, e.g., a transparent glass substrate, a semiconductor substrate formed by using silicon, etc., or a flexible substrate of a resin, etc. The anode 110 is disposed on the substrate 101 and may be formed by using, e.g., indium tin oxide (ITO), indium zinc oxide (IZO), etc.

As described above, between the anode 110 and the emission layer 130, the hole transport band 120 may be disposed. On the anode 110, a hole injection layer may be formed as the first layer 121 by doping a hole transport material represented by Chemical Formula (1) with an electron accepting compound.

On the hole injection first layer 121, a hole transport layer may be formed as the second layer 123 using a material including a hole transport material represented by Chemical Formula (1). In addition, the hole transport second layer 123 may be obtained by laminating a plurality of layers, and in this case, the hole transport layer disposed toward the hole injection first layer 121 may include the electron accepting compound.

On the hole transport second layer 123, an intermediate layer may be formed as the third layer 125 using a material including a hole transport material represented by Chemical Formula (2). The intermediate layer third 125 may be disposed adjacent to the emission layer 130 so as to restrain the diffusion of the electron accepting compound included in the hole injection first layer 121 and/or the hole transport second layer 123 into the emission layer 130, to passivated the hole transporting laminated structure from electrons not consumed in the emission layer 130 and to prevent the diffusion of excited energy generated in the emission layer 130 into the hole transporting laminated structure. Thus, the emission efficiency and life of the organic EL device may be improved.

On the intermediate third layer 125, the emission layer 130 may be formed using the above-described material. In an implementation, the emission layer 130 may be doped with a suitable p-type dopant such as 2,5,8,11-tetra-butylperylene (TBP), etc.

On the emission layer 130, an electron transport layer 140 may be formed using a material, for example, tris(8-hydroxyquinolinato)aluminum (Alq3). On the electron transport layer 140, the electron injection layer 150 may be formed using a material including, for example, lithium fluoride, lithium 8-quinolinato, etc. In addition, on the electron injection layer 150, a cathode 160 may be formed using a metal such as Al, Ag, Ca, etc. or a transparent material such as ITO, IZO, etc. The thin layers may be formed by using a suitable layer forming method such as a vacuum deposition method, a sputtering method, various coating methods, etc. according to a material used.

In the organic EL device according to this embodiment, the material for an organic EL device according to an embodiment may be applied in an organic EL display of an active matrix using TFT.

In addition, in the organic EL device 100 according to this embodiment, by the combination of the above-described layer structure and material, the hole transporting laminated structure may be passivated from electrons not consumed in the emission layer 130, the diffusion of excited energy generated in the emission layer 130 into the hole transporting laminated structure may be prevented, and whole charge balance of the organic EL device 100 may be controlled. In addition, by disposing the intermediate third layer 125 toward the emission layer 130, the diffusion of the electron accepting compound into the emission layer 130 may be restrained, and the emission efficiency and life of the organic EL device may be improved.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

### Preparation Method 1

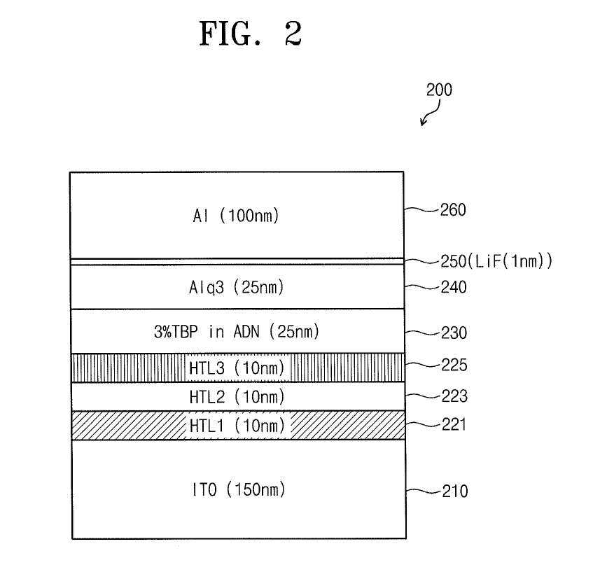

An organic EL device was manufactured using the above-described materials. FIG. 2 illustrates a schematic diagram of an organic EL device 200. An anode 210 was formed using ITO to a layer thickness of about 150 nm. HTL1 was formed as a hole injection first layer 221 by using Compound 3, below, as the compound represented by Chemical Formula (1), by forming a layer to a thickness of about 10 nm, and by doping Compound 3 with Compound 67, below. HTL2 was formed as a hole transport second layer 223 using Compound 3, below, to a layer thickness of about 10 nm. In addition, HTL3 was formed as an intermediate third layer 225 using Compound 31 and Compound 32, below, as the compounds represented by Chemical Formula (2), to a layer thickness of about 10 nm.

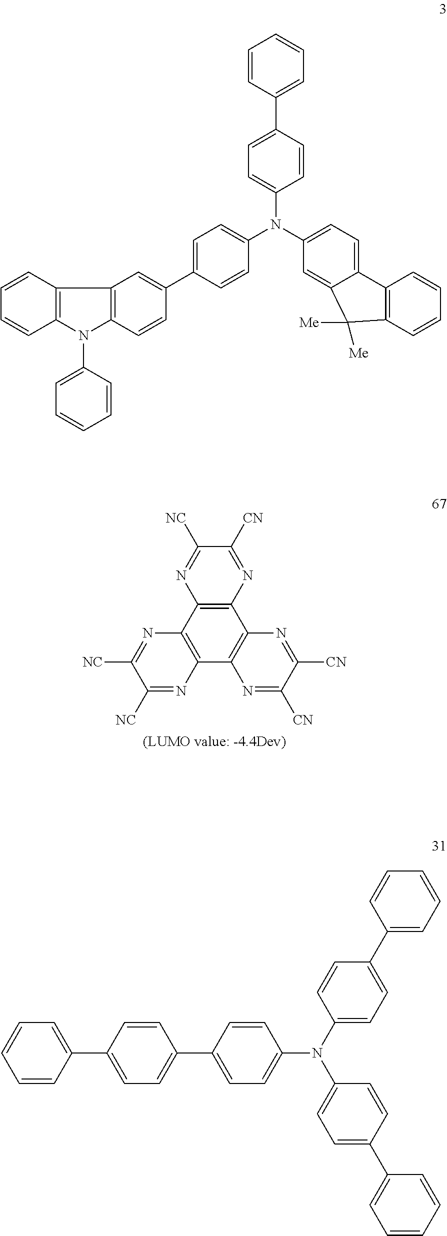 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#Cc1nc2c3nc(C#N)c(C#N)nc3c3nc(C#N)c(C#N)nc3c2nc1C#N ; c1ccc(-c2ccc(-c3ccc(N(c4ccc(-c5ccccc5)cc4)c4ccc(-c5ccccc5)cc4)cc3)cc2)cc1]

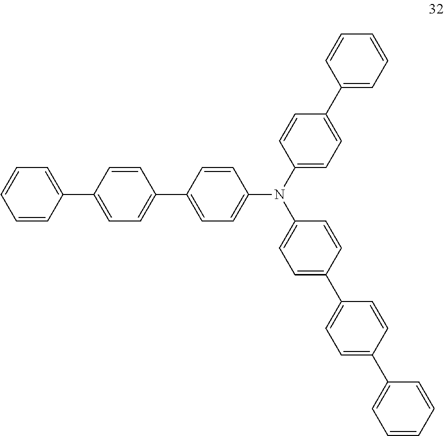 [SMILES: c1ccc(-c2ccc(-c3ccc(N(c4ccc(-c5ccccc5)cc4)c4ccc(-c5ccc(-c6ccccc6)cc5)cc4)cc3)cc2)cc1]

Then, an emission layer 230 was formed using a host material including 9,10-di(2-naphtyl)anthracene (ADN) as the compound represented by Chemical Formula (3), doped with about 3% of TBP to a layer thickness of about 25 nm. An electron transporting layer 240 was formed using Alq3 to a layer thickness of about 25 nm, and a cathode 260 was formed using Al to a layer thickness of about 100 nm.

In addition, organic EL devices were manufactured using Compounds 68 to 70, below, other than the above-described compounds in HTL1 to HTL3, as Comparative Examples.

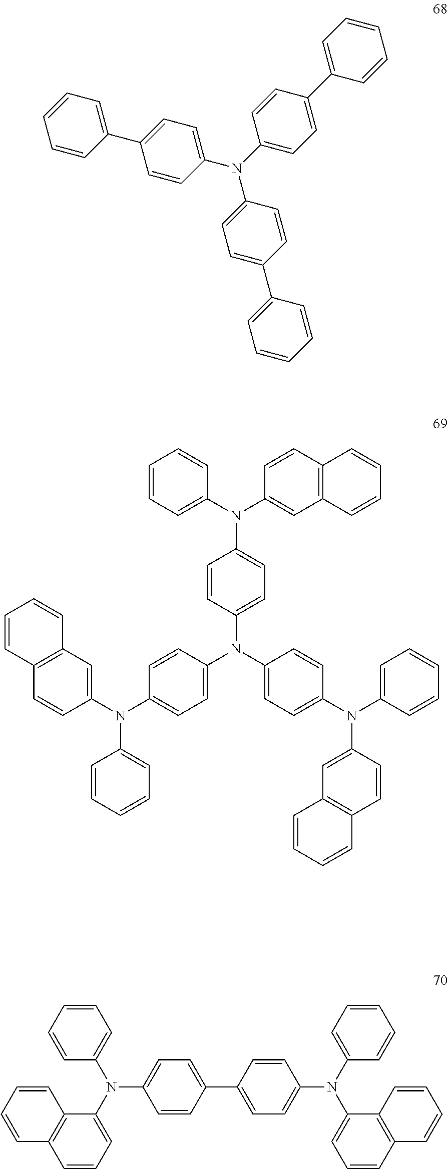 [SMILES: c1ccc(-c2ccc(N(c3ccc(-c4ccccc4)cc3)c3ccc(-c4ccccc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

The combinations of the compounds used in the HTL1 to HTL3 of the organic EL devices thus manufactured are summarized in the following Table 1.

TABLE 1

| | HTL1 | HTL2 | HTL3 |
|---|---|---|---|
| Example 1-1 | Compounds 3 + 67 | Compound 3 | Compound 31 |
| Example 1-2 | Compounds 3 + 67 | Compound 3 | Compound 32 |
| Comparative | Compounds 69 + 67 | Compound 3 | Compound 31 |
| Example 1-1 | | | |
| Comparative | Compounds 3 + 67 | Compound 31 | Compound 3 |
| Example 1-2 | | | |
| Comparative | Compound 31 | Compounds 3 + 67 | Compound 31 |
| Example 1-3 | | | |
| Comparative | Compounds 3 + 67 | Compound 3 | Compound 3 |
| Example 1-4 | | | |
| Comparative | Compounds 3 + 67 | Compound 3 | Compound 68 |
| Example 1-5 | | | |
| Comparative | Compound 69 | Compound 3 | Compound 68 |
| Example 1-6 | | | |
| Comparative | Compound 69 | Compound 70 | Compound 31 |
| Example 1-7 | | | |
| Comparative | Compound 69 | Compound 70 | Compound 68 |
| Example 1-8 | | | |
| Comparative | Compound 3 | Compound 3 | Compound 31 |
| Example 1-9 | | | |

With respect to the organic EL devices manufactured in the Examples and the Comparative Examples, voltage, power efficiency and current efficiency were evaluated. In addition, the current density was 10 mA/cm². Evaluation results are illustrated in the following Table 2.

TABLE 2

| | | Current Efficiency | |
|---|---|---|---|
| | Voltage (V) | (cd/A) | Half life (hr) |
| Example 1-1 | 6.2 | 7.5 | 4,700 |
| Example 1-2 | 6.5 | 7.3 | 3,900 |
| Comparative | 6.9 | 7.4 | 2,900 |
| Example 1-1 | | | |
| Comparative | 6.8 | 6.4 | 3,300 |
| Example 1-2 | | | |
| Comparative | 6.7 | 6.4 | 3,500 |
| Example 1-3 | | | |
| Comparative | 6.5 | 6.6 | 3,000 |
| Example 1-4 | | | |
| Comparative | 7.5 | 5.5 | 2,300 |
| Example 1-5 | | | |
| Comparative | 7.5 | 4.9 | 1,500 |
| Example 1-6 | | | |
| Comparative | 7.5 | 4.4 | 1,700 |
| Example 1-7 | | | |
| Comparative | 8.1 | 4.3 | 700 |
| Example 1-8 | | | |
| Comparative | 8.0 | 4.4 | 1.000 |
| Example 1-9 | | | |

As shown in Table 2, the driving voltage was lowered and the life of the devices was improved for the organic EL devices of Examples 1-1 and 1-2, when compared to that of

### Comparative Example 1

### 9. In addition, the driving voltage was lowered and the life of the

device was improved for the organic EL device of Example 1-1, when compared to a case (Comparative Example 1-1) including a carbazole-based hole transport material, i.e., Compound 69 doped with the electron accepting compound. In addition, the same efficiency improving effect was observed for the organic EL device of Example 1-1, when compared to a case (Comparative Example 1-2) in which the hole transport compound layers of HTL2 and HTL3 were replaced and a case (Comparative Example 1-3) in which the same Compound 31 was used in HTL1 and HTL3, and a layer including an electron accepting compound was inserted therebetween. In addition, the same efficiency improving effect was recognized for the organic EL devices of Examples 1-1 and 1-2 when compared to a case (Comparative Example 1-4) using the same Compound 3 in HTL2 and HTL3. When compared to a case (Comparative Example 1-5) using a non-carbazole-based hole transport Compound 68 in HTL3, the efficiency improving effect was recognized further.

In addition, a marked lowering of the driving voltage was observed, in addition to the improvement of the efficiency for Examples 1-1 and 1-2, when compared to cases (Comparative Examples 1-6, 1-7 and 1-8) using a starburst type hole injection material in a layer adjacent to the anode. From the lowering of the driving voltage and the improvement of the emission efficiency, the significance of the presence of the electron accepting compound in at least one layer of HTL1 to HTL3 was recognized.

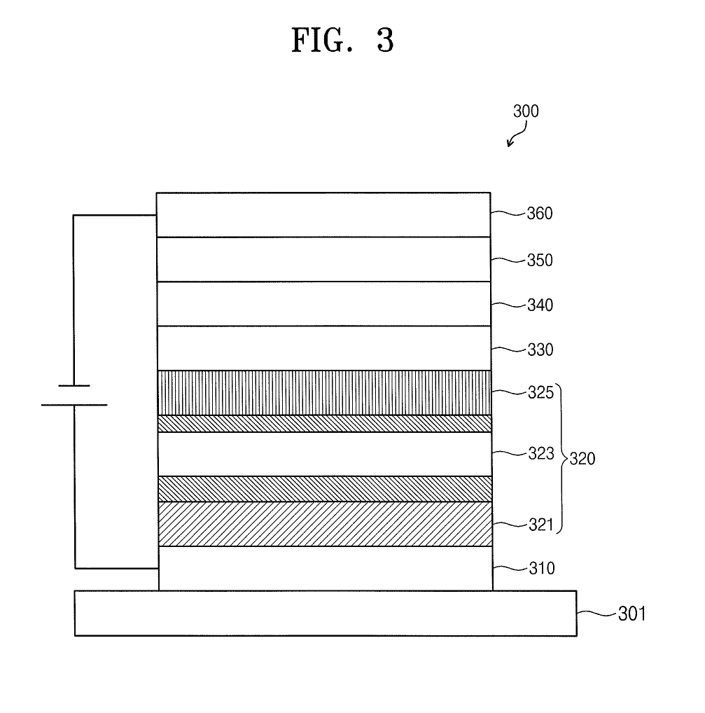

Hereinafter, an organic EL device according to FIG. 3 will be explained. FIG. 3 illustrates a schematic diagram of an organic EL device 300 according to an embodiment. The organic EL device 300 may include, e.g., an anode 310 on a substrate 301, an emission layer 330 for obtaining luminescence via mainly a singlet excited state, an electron transport layer 340, an electron injection layer 350, and a cathode 360. Between the anode 310 and the emission layer 330, a hole transport band 320 may be disposed. The hole transport band 320 may be a band for disposing a hole transport layer, a hole injection layer, etc.

According to an embodiment, to realize an organic EL device 300 driven at a low voltage and having improved emission efficiency and long life, a laminated structure of three layers having different components (a first layer 321, a second layer 323, and a third layer 325) may be provided in the hole transport band 320 between the anode 310 and the emission layer 330. At least three layers disposed toward the anode 310 of the laminated structure may include an electron accepting compound having a LUMO level from about −9.0 eV to about −4.0 eV. At least three layers (the second layer 323) disposed closer to the emission layer 330 than the first layer 321 may include a compound represented by Chemical Formula (1). In addition, at least one layer (the third layer 325) disposed closer to the emission layer 330 than the second layer 323 may include a compound represented by Chemical Formula (2). In addition, the emission layer 330 may include a compound represented by Chemical Formula (3).

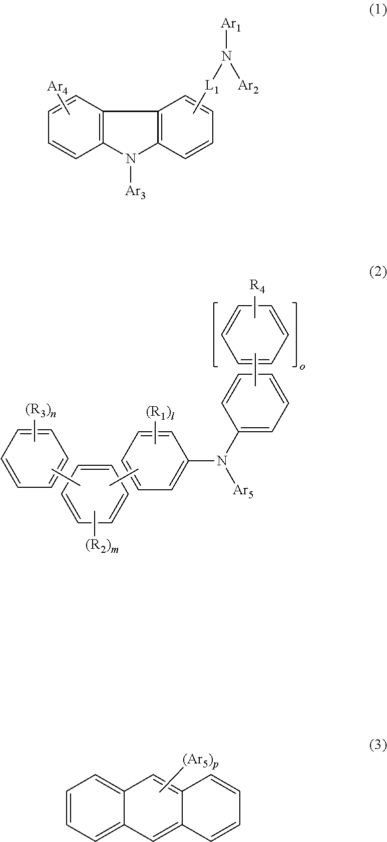

In Chemical Formula (1), Ar1, Ar2, and Ar3 may each independently be or include, e.g., a substituted or unsubstituted aryl group or a substituted or unsubstituted heteroaryl group. Ar4 may be or include, e.g., a substituted or unsubstituted aryl group, a substituted or unsubstituted heteroaryl group, a carbazolyl group, or an alkyl group. L1 may be or may include, e.g., a single bond, a substituted or unsubstituted arylene group, or a substituted or unsubstituted heteroarylene group.

In Chemical Formula (2), R1, R2 and R3 may each independently be or include, e.g., a hydrogen atom, a deuterium atom, a halogen atom, an alkyl group having 1 to 15 carbon atoms, a substituted or unsubstituted aryl group having 6 to 30 ring carbon atoms, or a substituted or unsubstituted heteroaryl group having 1 to 30 ring carbon atoms. l, m, and n may each independently be an integer satisfying 0≦1≦4, 0≦m≦4, and 0≦n≦5, R4 may be, e.g., a hydrogen atom, a deuterium atom or a fluorine atom, o may be an integer satisfying 0≦o≦3, and Ar5 may be or include, e.g., a substituted or unsubstituted aryl group having 6 to 30 ring carbon atoms.

In Chemical Formula (3), each Ar6 may independently be or include, e.g., a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group, or a hydroxyl group, and p may be an integer of 1 to 10.

In an implementation, Ar1 to Ar4 in Chemical Formula (1) may each independently include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group and a dibenzothienyl group. In an implementation, the phenyl group, the biphenyl group, the terphenyl group, the fluorenyl group, the carbazolyl group, the dibenzofuranyl group, etc. may be used.

In an implementation, L1 in Chemical Formula (1) may include, e.g., a phenylene group, a biphenylene group, a terphenylene group, a naphthalene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienyl group, etc. In an implementation, the phenylene group, the biphenylene group, the terphenylene group, the fluorenylene group, the carbazolylene group, the dibenzofuranylene group, etc. may be used.

In an implementation, R1, R2 and R3 in Chemical Formula (2) may each independently include, e.g., a methyl group, an ethyl group, a propyl group, an isopropyl group, a butyl group, a pentyl group, a hexyl group, a dodecyl group, a phenyl group, a biphenyl group, a terphenyl group, a toluyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group and a dibenzothienyl group. Preferably, the phenyl group, the biphenyl group, the terphenyl group, the fluorenyl group, the carbazolyl group, the dibenzofuranyl group, the fluorine atom, the chlorine atom, the deuterium atom, etc. may be used. In an implementation, the methyl group, the phenyl group, the biphenyl group, the fluorine atom, etc. may be used.

In an implementation, Ar5 in Chemical Formula (2) may include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group. In an implementation, the phenyl group, the biphenyl group, the terphenyl group, the naphtyl group, the anthryl group, the triphenylenyl group, etc. may be used.

In an implementation, Ar6 in Chemical Formula (3) may include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group and a dibenzothienyl group. In an implementation, the phenyl group, the biphenyl group, the terphenyl group, the fluorenyl group, the carbazolyl group, the dibenzofuranyl group, etc. may be used.

In the organic EL device 300, at least three layers of the first layer 321 (including the compound represented by Chemical Formula (1) and an electron accepting compound having a LUMO level of about −9.0 eV to about −4.0 eV) may be disposed toward the anode 310 of the laminated structure, at least three layers of the second layer 323 (including the compound represented by Chemical Formula (1)) may be disposed closer to the emission layer 330 than the first layer 321, and at least three layers of the third layer 325 (including the compound represented by Chemical Formula (2)) may be disposed closer to the emission layer 330 than the second layer 323. The organic EL device 300 according to an embodiment may include an amine derivative having a terphenyl group in the third layer 325. Thus, the hole transporting laminated structure may be passivated from electrons not consumed in the emission layer 330. In addition, the diffusion of excited energy generated in the emission layer 330 into the hole transporting laminated structure may be prevented, and the charge balance of the whole organic EL device 300 may be controlled.

In the organic EL device 300, the first layer 321 including the electron accepting compound may be disposed toward the anode 300, e.g., adjacent to or directly adjacent to the anode 310. By disposing a layer including the electron accepting compound adjacent to the anode 310, hole injection properties from the anode may be improved.

In the organic EL device 300, the second layer 323 including a compound having a carbazolyl group, represented by Chemical Formula (1) may be disposed closer to the emission layer 330 than the first layer 321. By including the compound having the carbazolyl group in the hole transporting laminated structure, charge transporting properties and current flow durability may be improved. In addition, by including the compound represented by Chemical Formula (1) in the second layer 323, the hole transporting laminated structure may be passivated from electrons not consumed in the emission layer 330, and the diffusion of excited energy generated in the emission layer 330 into the hole transporting laminated structure may be prevented.

In addition, by disposing the third layer 325 including the compound having a terphenyl group and represented by Chemical Formula (2) closer to the emission layer 330 than the second layer 323, the diffusion of the electron accepting compound included in the first layer 321 into the emission layer 330 may be prevented, and the hole transporting first layer 321 and second layer 323 may be passivated from electrons not consumed in the emission layer 330. In addition, the diffusion of excited energy generated in the emission layer 330 to the hole transporting first layer 321 and second layer 323 may be prevented. Thus, in an implementation, the third layer 325 including the compound represented by Chemical Formula (2) may be disposed adjacent to, e.g., directly adjacent to, the emission layer 330.

In an implementation, an electron accepting compound may be represented by one of the following Chemical Formulae 1 to 14.

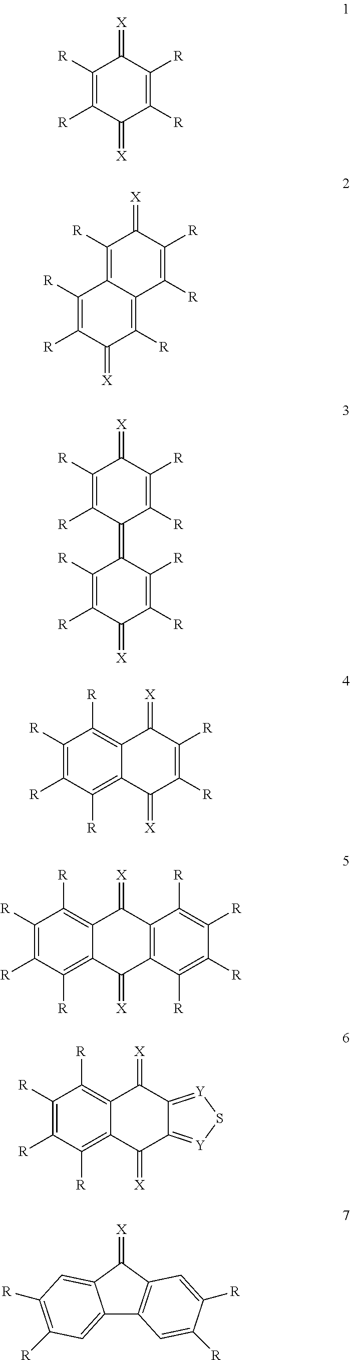

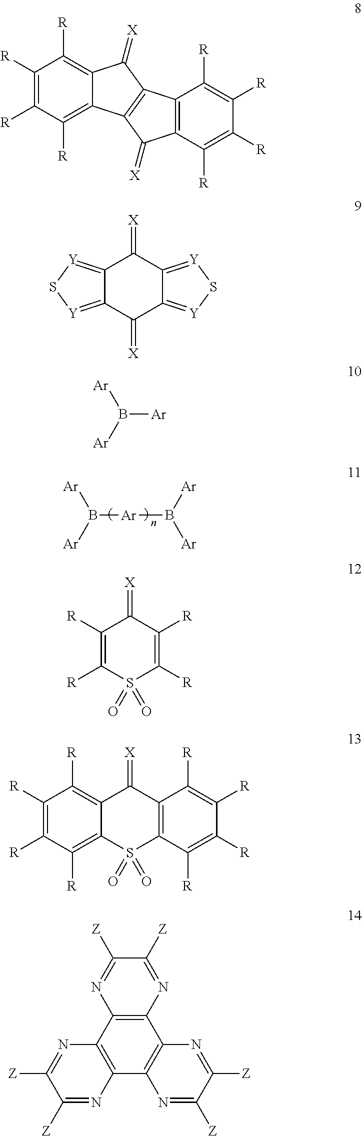

In Chemical Formulae 1 to 14, each R may independently be or include, e.g., a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 5 to 50 carbon atoms, or a heteroaryl group having 5 to 50 ring carbon atoms. Each Ar may independently be or include, e.g., a substituted or unsubstituted electron withdrawing aryl group having 5 to 50 carbon atoms or a substituted or unsubstituted heteroaryl group having 5 to 50 carbon atoms. Each Y may be or include, e.g., a methine group (—CH═) or a nitrogen atom (—N═). Each Z may be or include, e.g., a pseudohalogen or sulfur (S). Each X may independently be or include a group represented by one of the following Chemical Formulae X1 to X7.

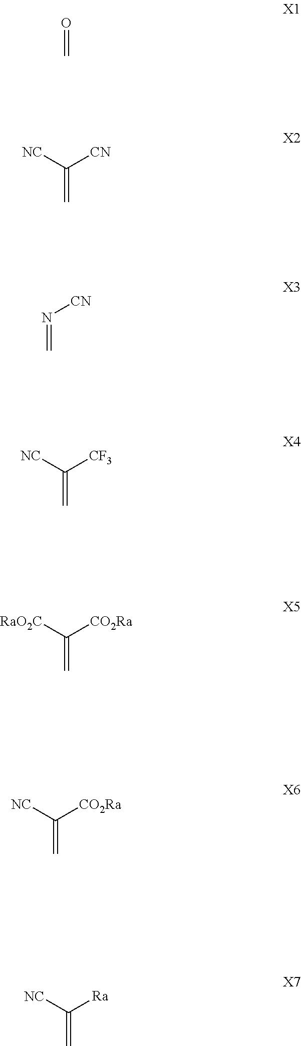

In Chemical Formulae X1 to X7, Ra may be or include, e.g., a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 5 to 50 ring carbon atoms, or a substituted or unsubstituted heteroaryl group having 5 to 50 ring carbon atoms.

In an implementation, R, Ar and Ra may be or include, e.g., one of the following substituents. Examples of the aryl group in the “substituted or unsubstituted aryl group having 5 to 50 ring carbon atoms” or the heteroaryl group in the “substituted or unsubstituted heteroaryl group having 5 to 50 ring carbon atoms” may include a phenyl group, a 1-naphtyl group, a 2-naphtyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphtyl group, a 4-methyl-1-naphtyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyradinyl group, a 2-pyridinyl group, a 3-pyridinyl group, a 4-pyridinyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrol-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrol-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl 3-indolyl group, etc.

Examples of the fluoroalkyl group in the “substituted or unsubstituted fluoroalkyl group having 1 to 50 carbon atoms” may include a perfluoroalkyl group such as a trifluoromethyl group, a pentafluoroethyl group, a heptafluoropropyl group, a heptadecafluorooctane group, etc. or a monofluoromethyl group, a difluoromethyl group, a trifluoroethyl group, a tetrafluoropropyl group, an octafluoropentyl group, etc.

Examples of the alkyl group in the “substituted or unsubstituted alkyl group having 1 to 50 carbon atoms” represented as R and Ra may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The alkoxy group in the “substituted or unsubstituted alkoxy group having 1 to 50 carbon atoms” may include a group represented by —OY, and examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

A halogen atom may include fluorine, chlorine, bromine, and iodine.

In an implementation, the second layer 323 may include a compound represented by Chemical Formula (1). In an implementation, the compound represented by Chemical Formula (1), included in the second layer 323, may include one of the following Compounds 15 to 20.

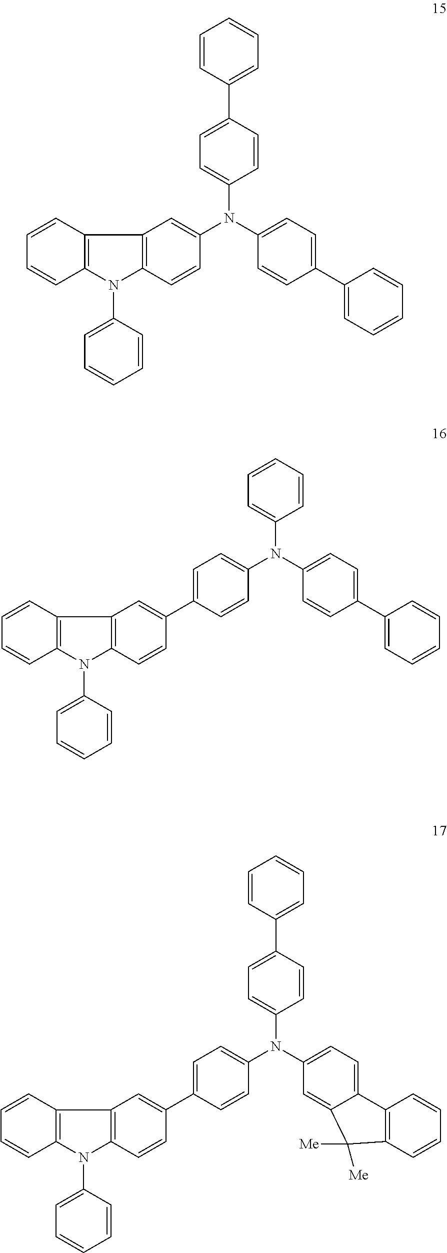 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

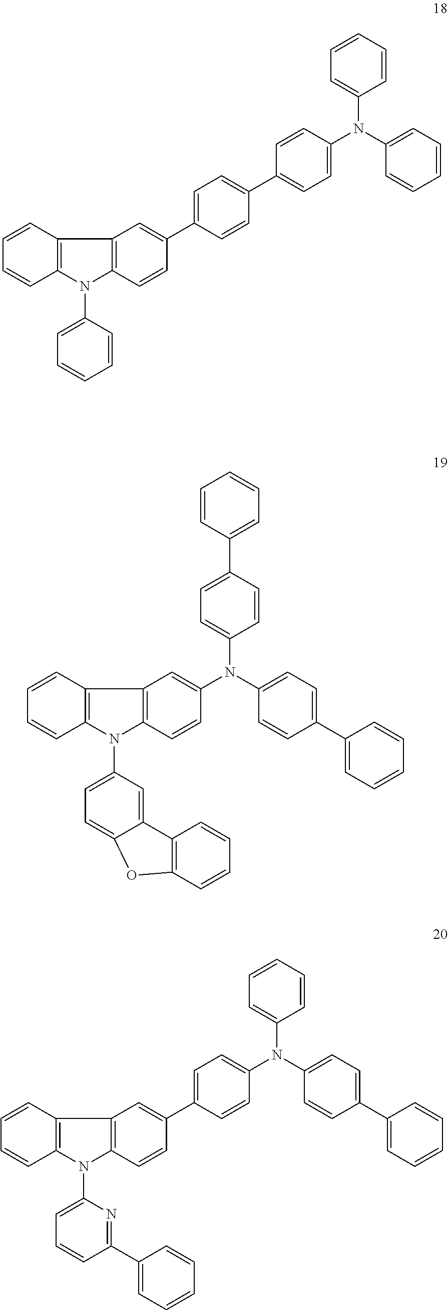 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

In an implementation, the compound represented by Chemical Formula (1), included in the second layer 323, may include one of the following Compounds 21 to 26.

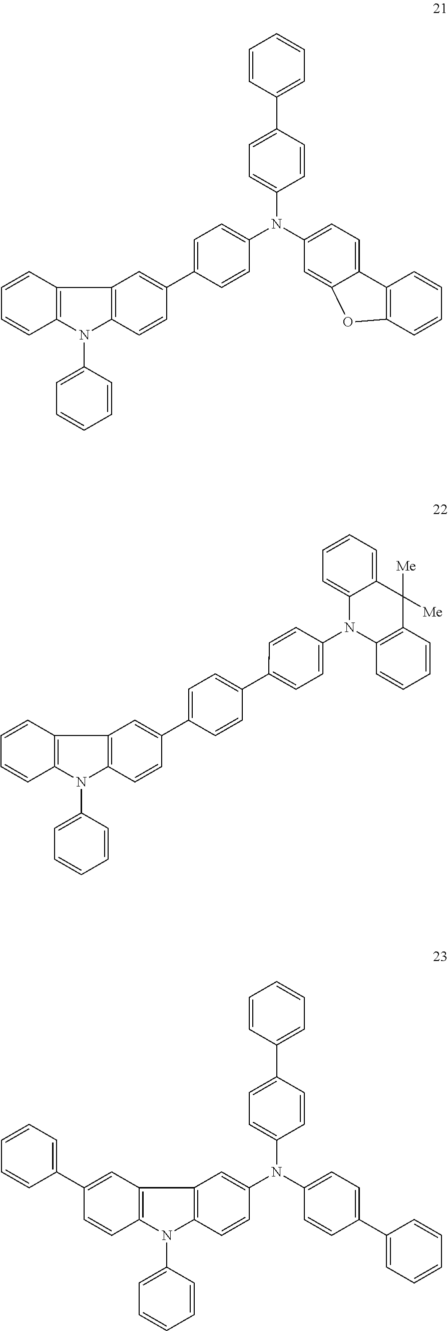 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

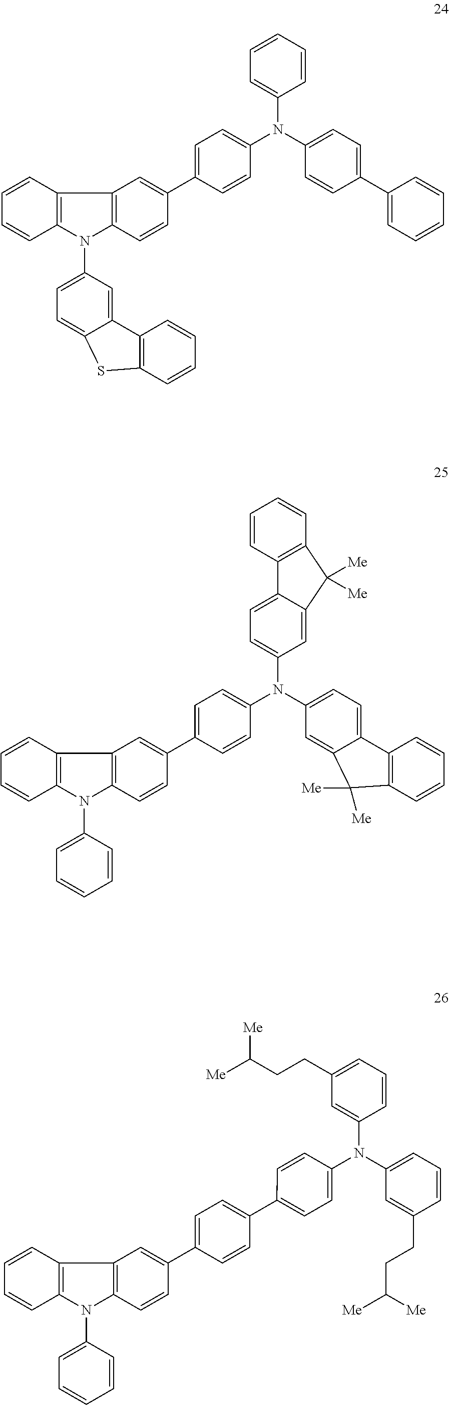

In an implementation, the compound represented by Chemical Formula (1), included in the second layer 323, may include one of the following Compounds 27 to 30.

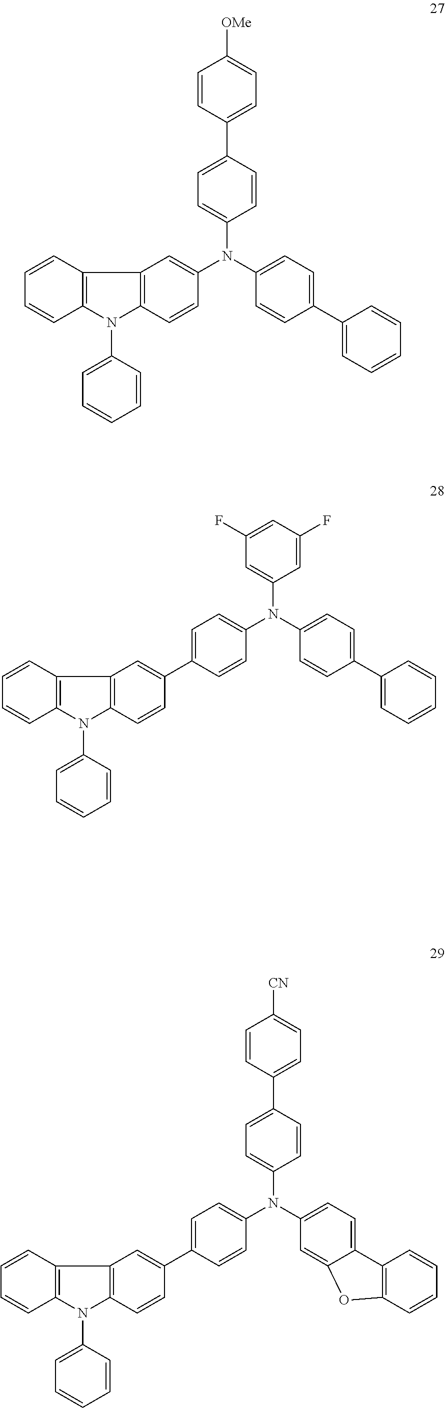

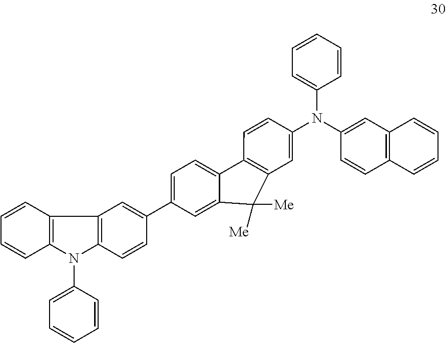 [SMILES: CC1(C)c2cc(-c3ccc4c(c3)c3ccccc3n4-c3ccccc3)ccc2-c2ccc(N(c3ccccc3)c3ccc4ccccc4c3)cc21]

The third layer 325 according to an embodiment may include the compound represented by Chemical Formula (2). In an implementation, the compound represented by Chemical Formula (2) and included in the third layer 325 may include one of the following Compounds 31 to 34.

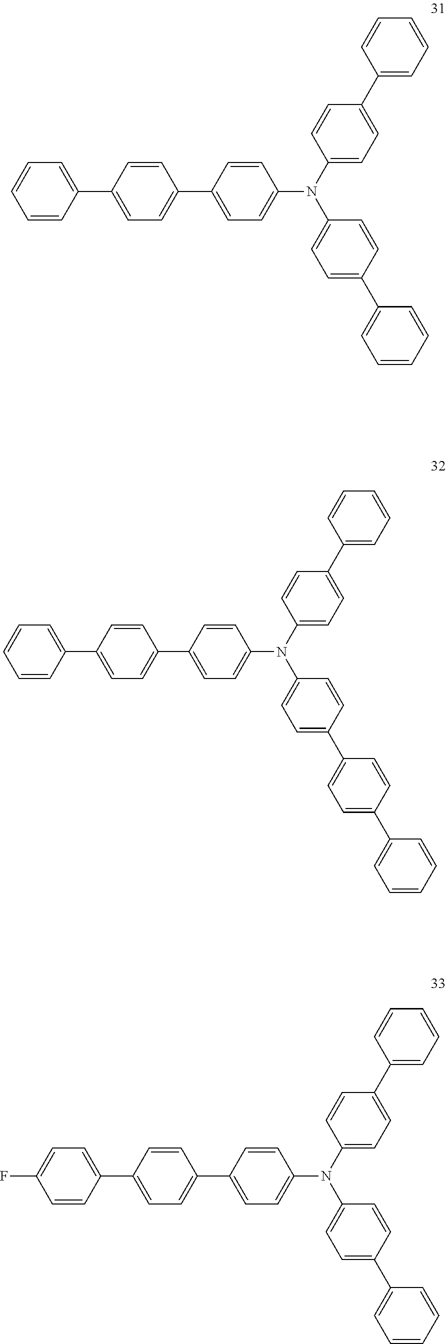 [SMILES: c1ccc(-c2ccc(-c3ccc(N(c4ccc(-c5ccccc5)cc4)c4ccc(-c5ccccc5)cc4)cc3)cc2)cc1 ; c1ccc(-c2ccc(-c3ccc(N(c4ccc(-c5ccccc5)cc4)c4ccc(-c5ccc(-c6ccccc6)cc5)cc4)cc3)cc2)cc1 ; Fc1ccc(-c2ccc(-c3ccc(N(c4ccc(-c5ccccc5)cc4)c4ccc(-c5ccccc5)cc4)cc3)cc2)cc1]

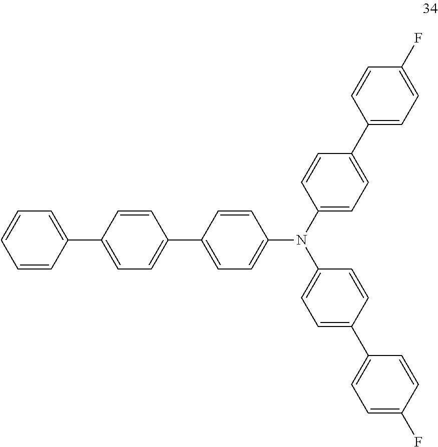 [SMILES: Fc1ccc(-c2ccc(N(c3ccc(-c4ccc(F)cc4)cc3)c3ccc(-c4ccc(-c5ccccc5)cc4)cc3)cc2)cc1]

In an implementation, the compound represented by Chemical Formula (2) and included in the third layer 325 may include one of the following Compounds 35 to 38.

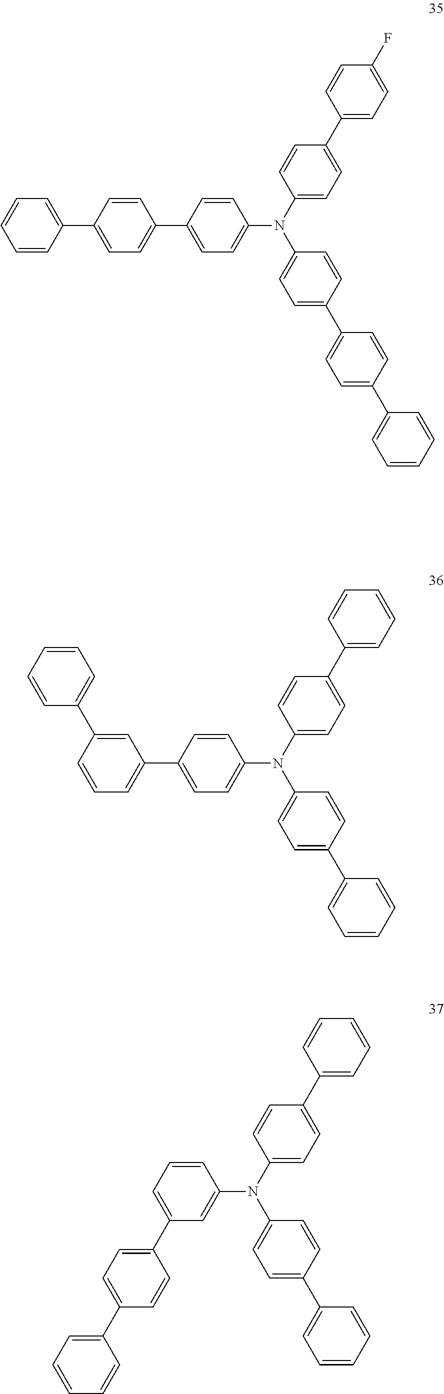 [SMILES: Fc1ccc(-c2ccc(N(c3ccc(-c4ccc(-c5ccccc5)cc4)cc3)c3ccc(-c4ccc(-c5ccccc5)cc4)cc3)cc2)cc1 ; c1ccc(-c2ccc(N(c3ccc(-c4ccccc4)cc3)c3ccc(-c4cccc(-c5ccccc5)c4)cc3)cc2)cc1 ; c1ccc(-c2ccc(-c3cccc(N(c4ccc(-c5ccccc5)cc4)c4ccc(-c5ccccc5)cc4)c3)cc2)cc1]

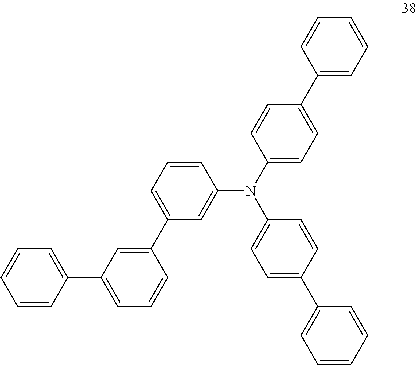 [SMILES: c1ccc(-c2ccc(N(c3ccc(-c4ccccc4)cc3)c3cccc(-c4cccc(-c5ccccc5)c4)c3)cc2)cc1]

In an implementation, the compound represented by Chemical Formula (2) and included in the third layer 325 may include one of the following Compounds 39 to 42.

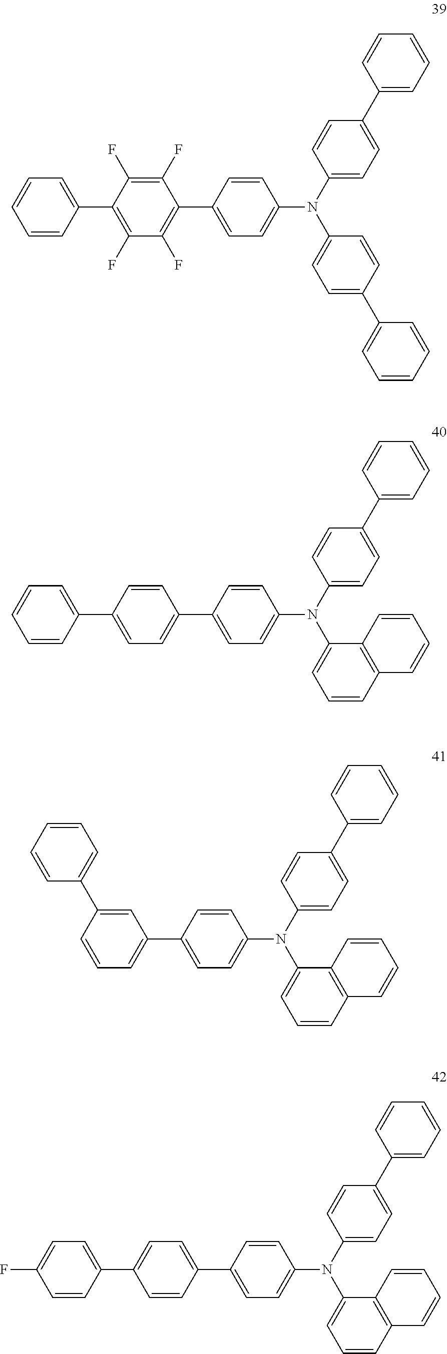 [SMILES: Fc1c(F)c(-c2ccc(N(c3ccc(-c4ccccc4)cc3)c3ccc(-c4ccccc4)cc3)cc2)c(F)c(F)c1-c1ccccc1 ; c1ccc(-c2ccc(-c3ccc(N(c4ccc(-c5ccccc5)cc4)c4cccc5ccccc45)cc3)cc2)cc1 ; c1ccc(-c2ccc(N(c3ccc(-c4cccc(-c5ccccc5)c4)cc3)c3cccc4ccccc34)cc2)cc1 ; Fc1ccc(-c2ccc(-c3ccc(N(c4ccc(-c5ccccc5)cc4)c4cccc5ccccc45)cc3)cc2)cc1]

In an implementation, the compound represented by Chemical Formula (2) and included in the third layer 325 may include one of the following Compounds 43 to 46.

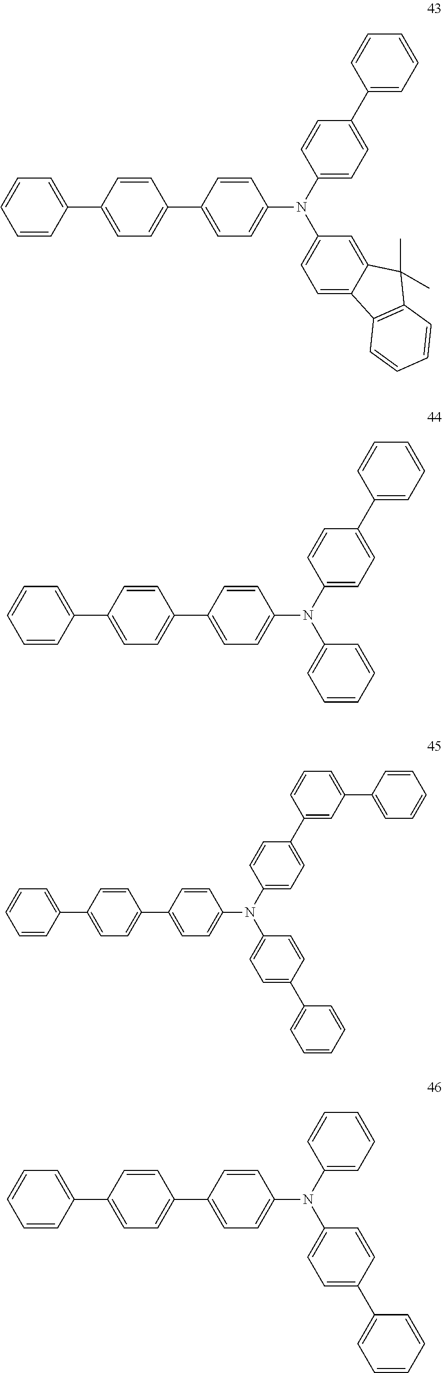 [SMILES: CC1(C)c2ccccc2-c2ccc(N(c3ccc(-c4ccccc4)cc3)c3ccc(-c4ccc(-c5ccccc5)cc4)cc3)cc21 ; c1ccc(-c2ccc(-c3ccc(N(c4ccccc4)c4ccc(-c5ccccc5)cc4)cc3)cc2)cc1 ; c1ccc(-c2ccc(-c3ccc(N(c4ccc(-c5ccccc5)cc4)c4ccc(-c5cccc(-c6ccccc6)c5)cc4)cc3)cc2)cc1 ; c1ccc(-c2ccc(-c3ccc(N(c4ccccc4)c4ccc(-c5ccccc5)cc4)cc3)cc2)cc1]

In an implementation, the compound represented by Chemical Formula (2) and included in the third layer 325 may include one of the following Compounds 47 to 50.

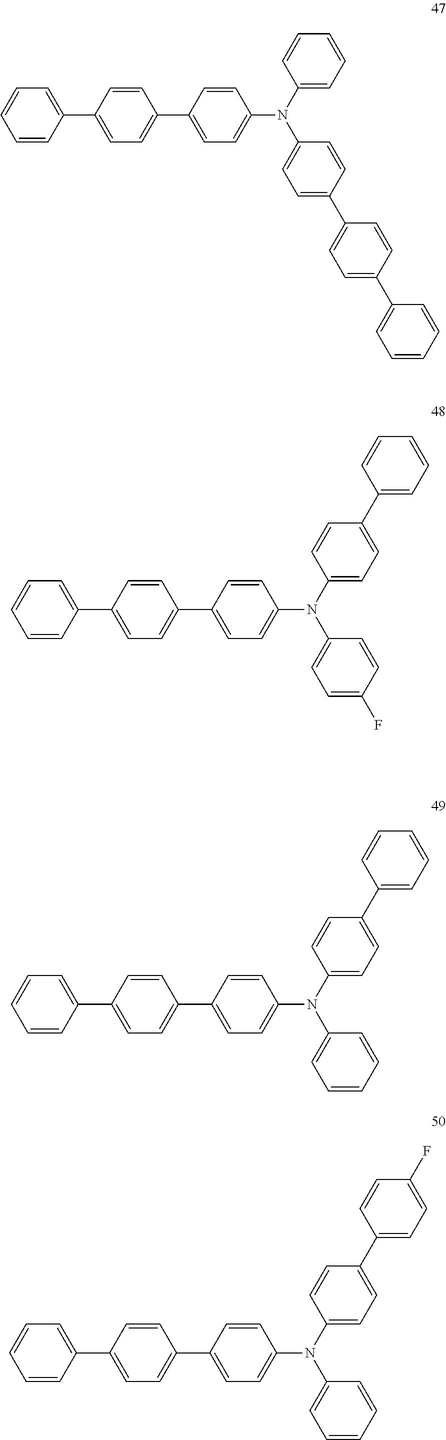 [SMILES: c1ccc(-c2ccc(-c3ccc(N(c4ccccc4)c4ccc(-c5ccc(-c6ccccc6)cc5)cc4)cc3)cc2)cc1 ; Fc1ccc(N(c2ccc(-c3ccccc3)cc2)c2ccc(-c3ccc(-c4ccccc4)cc3)cc2)cc1 ; c1ccc(-c2ccc(-c3ccc(N(c4ccccc4)c4ccc(-c5ccccc5)cc4)cc3)cc2)cc1 ; Fc1ccc(-c2ccc(N(c3ccccc3)c3ccc(-c4ccc(-c5ccccc5)cc4)cc3)cc2)cc1]

In an implementation, the compound represented by Chemical Formula (2) and included in the third layer 325 may include one of the following Compounds 51 to 54.

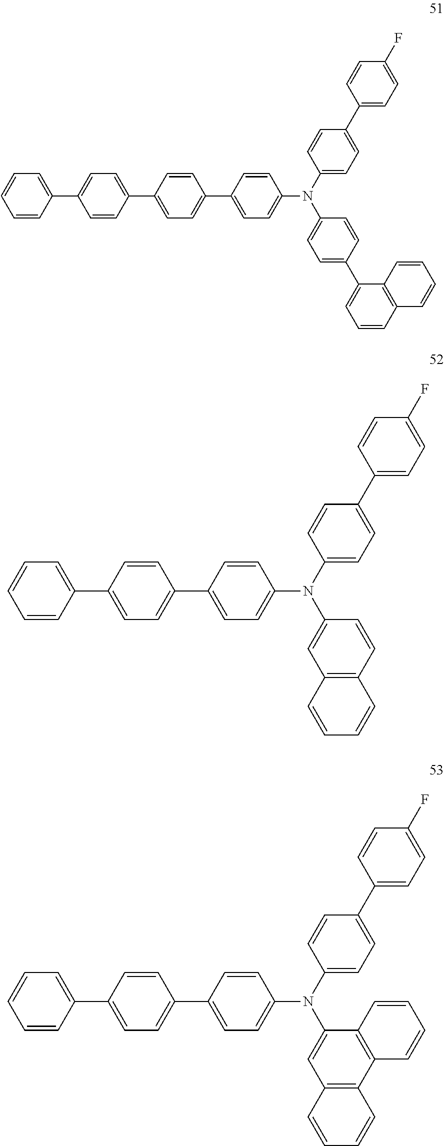 [SMILES: Fc1ccc(-c2ccc(N(c3ccc(-c4ccc(-c5ccc(-c6ccccc6)cc5)cc4)cc3)c3ccc(-c4cccc5ccccc45)cc3)cc2)cc1 ; Fc1ccc(-c2ccc(N(c3ccc(-c4ccc(-c5ccccc5)cc4)cc3)c3ccc4ccccc4c3)cc2)cc1 ; Fc1ccc(-c2ccc(N(c3ccc(-c4ccc(-c5ccccc5)cc4)cc3)c3cc4ccccc4c4ccccc34)cc2)cc1]

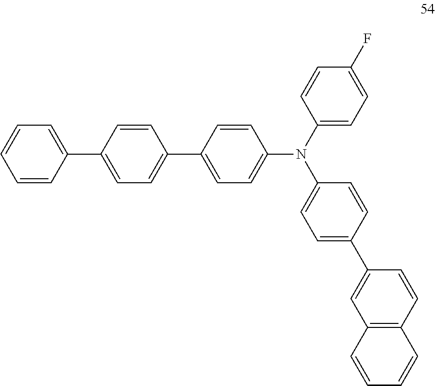 [SMILES: Fc1ccc(N(c2ccc(-c3ccc(-c4ccccc4)cc3)cc2)c2ccc(-c3ccc4ccccc4c3)cc2)cc1]

The organic EL device 300 according to an embodiment may include an amine derivative having a terphenyl group in the third layer 325, and the hole transporting laminated structure may be passivated from electrons not consumed in the emission layer 330. In addition, the diffusion of excited energy generated in the emission layer 330 into the hole transporting laminated structure may be prevented, and the whole charge balance of the organic EL device 300 may be controlled.

In an implementation, in the compound represented by Chemical Formula (3) and included in the emission layer 330, Ar6 may be, e.g., one of the following substituents, without limitation. In an implementation, in the case that at least two Ar6 are present, the substituents may be the same or different. In an implementation, Ar6 may include, e.g., a phenyl group, a biphenyl group, a terphenyl group, a naphtyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoxazolyl group, a pyrazolyl group, a dibenzofuranyl group, or a dibenzothienyl group. In an implementation, the phenyl group, the biphenyl group, the terphenyl group, the fluorenyl group, the carbazolyl group, the dibenzofuranyl group, etc. may be used.

In an implementation, the compound represented by Chemical Formula (3) and included in the emission layer 330 may include, e.g., one of the following Compounds 55 to 60.

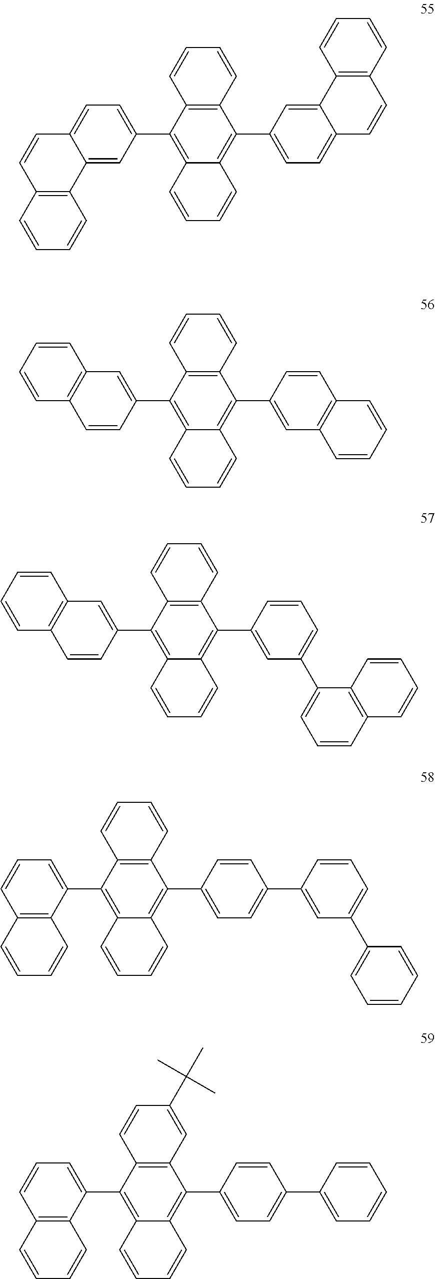

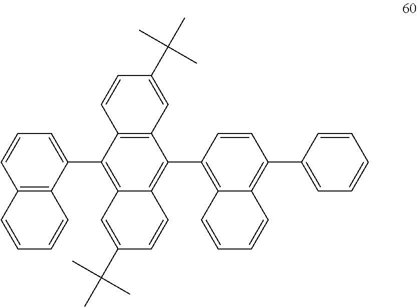 [SMILES: CC(C)(C)c1ccc2c(-c3ccc(-c4ccccc4)c4ccccc34)c3cc(C(C)(C)C)ccc3c(-c3cccc4ccccc34)c2c1]

In an implementation, the compound represented by Chemical Formula (3) and included in the emission layer 330 may include, e.g., one of the following Compounds 61 to 66.

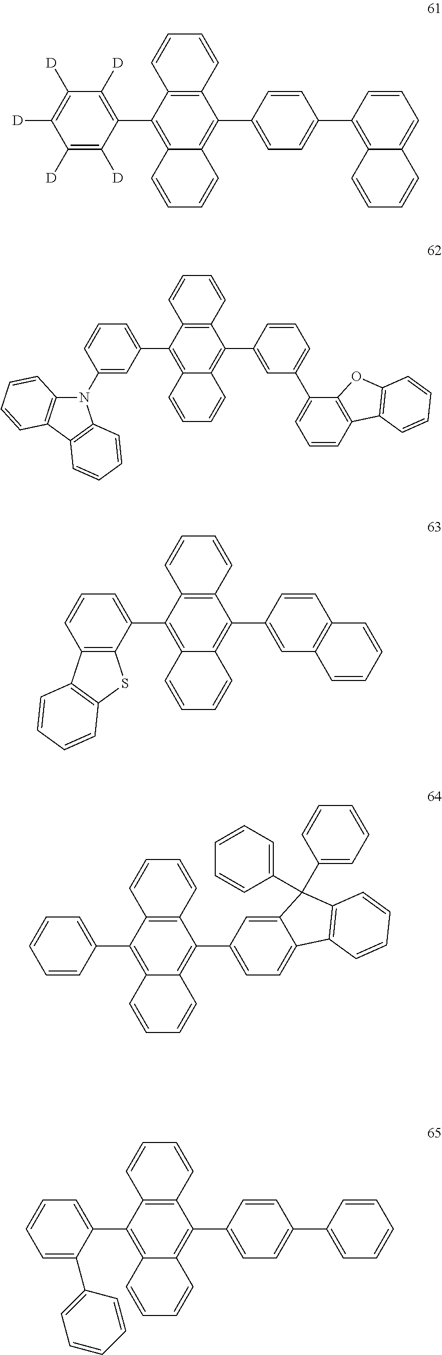

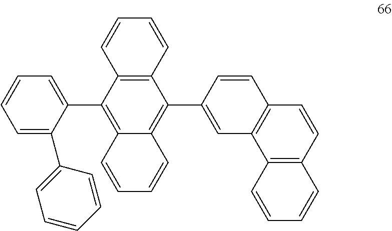 [SMILES: c1ccc(-c2ccccc2-c2c3ccccc3c(-c3ccc4ccc5ccccc5c4c3)c3ccccc23)cc1]

By forming the laminated structure of at least three layers disposed in the hole transport band 320 and having different components in the organic EL device 300, using an electron accepting compound having a LUMO level of about −9.0 eV to about −4.0 eV, a hole injection properties from the anode 310 may be improved. Accordingly, the layer including the electron accepting compound may be disposed adjacent to the anode 310 like the first layer 321, and hole injection properties from the anode 310 of the organic EL device 300 may be markedly improved. In addition, the effects may be marked when combined with the emission layer 330 including the compound represented by Chemical Formula (3). In addition, the driving or the organic EL device 300 at a low voltage may be realized.

As described above, in an implementation, the first layer including the electron accepting compound may be the hole injection first layer 321 and may disposed adjacent to, e.g., directly adjacent to, the anode 310. Thus, in the organic EL device 300 according to an embodiment, the second layer (including the compound represented by Chemical Formula (1)) and the third layer (including the compound represented by Chemical Formula (2)) may be disposed closer to the emission layer 330 than the first layer (formed by using the electron accepting compound). By including a compound having a carbazolyl group in the second layer of the hole transporting laminated structure, charge transport properties and current flow durability may be improved.

In an implementation, in the organic EL device 300, the third layer 325 (including the compound represented by Chemical Formula (2)) may be disposed closer to the emission layer 330 than the second layer 323 (including the compound represented by Chemical Formula (1)). For example, by disposing the third layer 325 (including the compound represented by Chemical Formula (2)) adjacent to (e.g., directly adjacent to) the emission layer 330, the hole transporting laminated structure (the first layer 321 and the second layer 323) may be passivated from electrons not consumed in the emission layer 330, and the diffusion of excited energy generated in the emission layer 330 into the hole transporting first layer 321 and second layer 323 may be prevented in the organic EL device 300. Thus, in an implementation, the third layer 325 (including the compound represented by Chemical Formula (2)) may be disposed adjacent to, e.g., directly adjacent to, the emission layer 330.

The organic EL device according to an embodiment will be described in more detail. In the organic EL device 300 according to an embodiment, the substrate 301 may be, e.g., a transparent glass substrate, a semiconductor substrate formed by using silicon, etc., or a flexible substrate of a resin, etc. The anode 310 may be disposed on the substrate 301 and may be formed by using, e.g., ITO, IZO, etc.

As described above, between the anode 310 and the emission layer 330, the hole transport band 320 may be disposed. On the anode 310, a hole injection first layer 321 may be formed by using a material including the above-described electron accepting compound in an embodiment.

On the hole injection first layer 321, a hole transport second layer 323 may be using a material including a hole transport material represented by Chemical Formula (1). In an implementation, the hole transport second layer 323 may be obtained by laminating a plurality of layers, as the second layer and in this case, the hole transport layer disposed toward the hole injection layer 321 may include the electron accepting compound.

On the hole transport second layer 323, an intermediate third layer 325 may be formed using a material including a hole transport material represented by Chemical Formula (2). The intermediate third layer 325 may be disposed adjacent to the emission layer 330 so as to passivate the hole transporting laminated structure from electrons not consumed in the emission layer 330, to prevent the diffusion of excited energy generated in the emission layer 330 into the hole transporting laminated structure and to control whole charge balance of the organic EL device 300. In addition, by disposing the intermediate third layer 325 toward the emission layer 330, the diffusion of the electron accepting compound into the emission layer 330 may be restrained, and the emission efficiency and life of the organic EL device may be improved.

On the intermediate third layer 325, the emission layer 330 may be formed using a material including the compound represented by Chemical Formula (3). In an implementation, the emission layer 330 may include a suitable p-type dopant such as TBP, etc.

On the emission layer 330, an electron transport layer 340 may be formed using a material including, e.g., Alq3. On the electron transport layer 340, the electron injection layer 350 may be formed using a material including, e.g., lithium fluoride, lithium 8-quinolinato, etc. In addition, on the electron injection layer 350, a cathode 360 may be formed using a metal such as Al, Ag, Ca, etc. or a transparent material such as ITO, IZO, etc. The thin layers may be formed by using a suitable layer forming method such as a vacuum deposition method, a sputtering method, various coating methods, etc. according to a material used.

In the organic EL device according to this embodiment, the material for an organic EL device may be applied in an organic EL display of an active matrix using TFT.

In an implementation, in the organic EL device 300, by the combination of the above-described layer structure and material, the hole transporting laminated structure may be passivated from electrons not consumed in the emission layer 330, the diffusion of excited energy generated in the emission layer 330 into the hole transporting laminated structure may be prevented, and whole charge balance of the organic EL device 300 may be controlled. In addition, by disposing the intermediate third layer 325 toward the emission layer 330, the diffusion of the electron accepting compound into the emission layer 330 may be restrained, and the emission efficiency and life of the organic EL device may be improved.

### Example 2

### Preparation Method 2

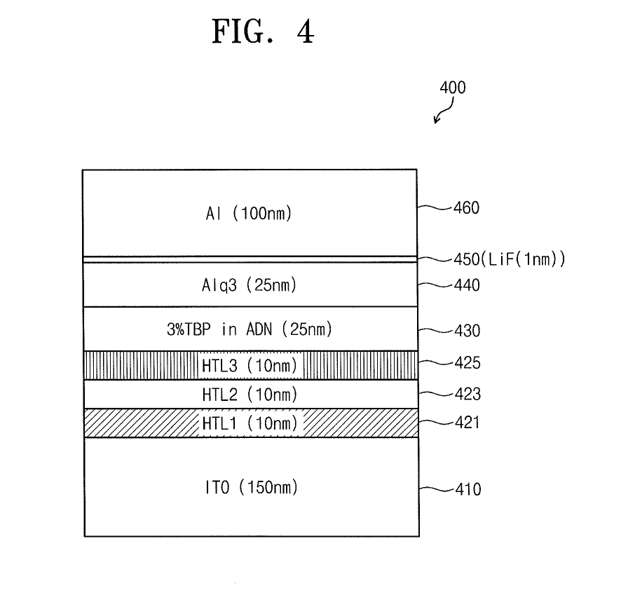

An organic EL device was manufactured using the above-described materials. FIG. 4 illustrates a schematic diagram of an organic EL device 400. An anode 410 was formed using ITO to a layer thickness of about 150 nm. Compound 67, below, was used during the formation of HTL1, and HTL1 was formed to a thickness of about 10 nm, as a hole injection first layer 421. HTL2 was formed using Compound 17 below as a compound represented by Chemical Formula (1) to a layer thickness of about 10 nm, as a hole transport second layer 423. In addition, HTL3 was formed using Compound 43, below, as the compound represented by Chemical Formula (2) to a layer thickness of about 10 nm, as an intermediate third layer 425.

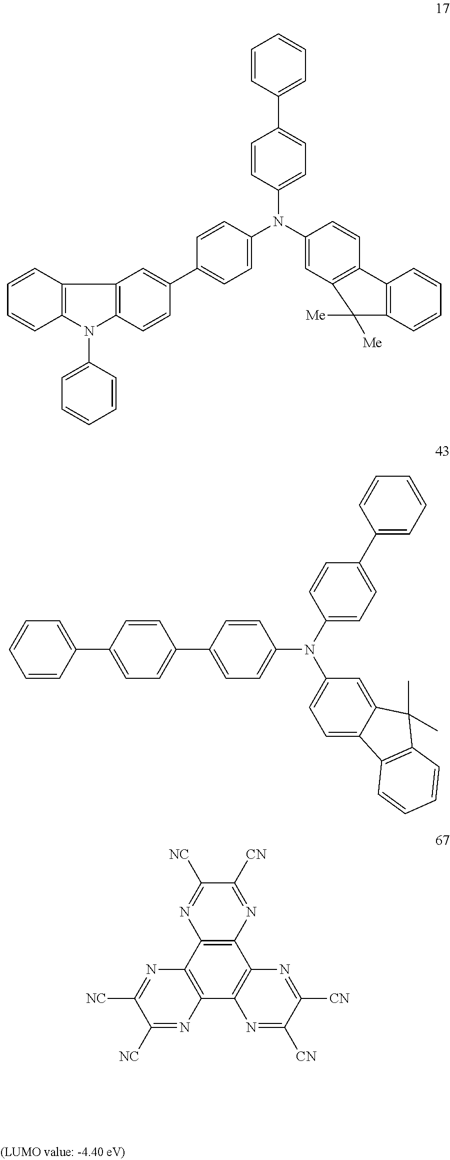 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc(-c4ccc(-c5ccccc5)cc4)cc3)cc21 ; N#Cc1nc2c3nc(C#N)c(C#N)nc3c3nc(C#N)c(C#N)nc3c2nc1C#N]

Then, an emission layer 430 was formed using a host material including ADN as the compound represented by Chemical Formula (3) and doped with about 3% of TBP to a layer thickness of about 25 nm. An electron transporting layer 440 was formed using Alq3 to a layer thickness of about 25 nm, an electron injection layer 450 was formed using LiF to a layer thickness of about 1 nm, and a cathode 460 was formed using A1 to a layer thickness of about 100 nm.

In addition, organic EL devices were manufactured using Compounds 68 to 70, below, e.g., other than the above-described compounds in HTL1 to HTL3, as Comparative Examples.

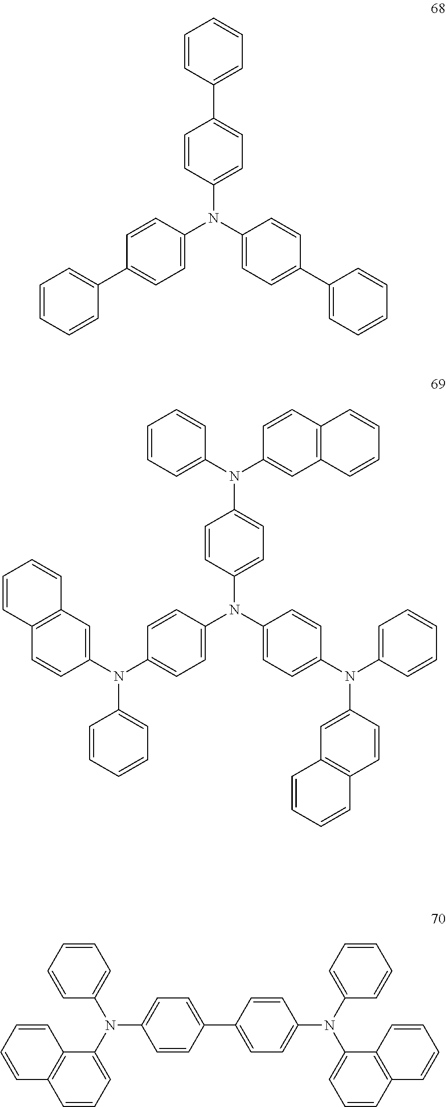 [SMILES: c1ccc(-c2ccc(N(c3ccc(-c4ccccc4)cc3)c3ccc(-c4ccccc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

The combinations of the compounds used in the HTL1 to HTL3 of the organic EL devices thus manufactured are summarized in the following Table 3.

TABLE 3

| | HTL1 | HTL2 | HTL3 |
|---|---|---|---|
| Example 2-1 | Compound 67 | Compound 17 | Compound 43 |
| Comparative | Compound 67 | Compound 43 | Compound 17 |
| Example 2-1 | | | |
| Comparative | Compound 43 | Compound 67 | Compound 43 |
| Example 2-2 | | | |
| Comparative | Compound 67 | Compound 17 | Compound 17 |
| Example 2-3 | | | |
| Comparative | Compound 67 | Compound 17 | Compound 68 |
| Example 2-4 | | | |
| Comparative | Compound 69 | Compound 17 | Compound 68 |
| Example 2-5 | | | |
| Comparative | Compound 69 | Compound 70 | Compound 43 |
| Example 2-6 | | | |
| Comparative | Compound 69 | Compound 70 | Compound 68 |
| Example 2-7 | | | |

With respect to the organic EL devices manufactured in the Examples and the Comparative Examples, voltage, power efficiency, and current efficiency were evaluated. In addition, the current density was 10 mA/cm². Evaluation results are illustrated in the following Table 4.

TABLE 4

| | | Current Efficiency | |
|---|---|---|---|
| | Voltage (V) | (cd/A) | Half life (hr) |
| Example 2-1 | 6.5 | 7.4 | 3,900 |
| Comparative | 6.9 | 6.3 | 3,300 |
| Example 2-1 | | | |
| Comparative | 7.1 | 6.3 | 3,000 |
| Example 2-2 | | | |
| Comparative | 6.6 | 6.5 | 2,900 |
| Example 2-3 | | | |
| Comparative | 7.5 | 5.5 | 1,800 |
| Example 2-4 | | | |
| Comparative | 7.5 | 4.9 | 1,500 |
| Example 2-5 | | | |
| Comparative | 7.6 | 4.7 | 1,900 |
| Example 2-6 | | | |
| Comparative | 8.1 | 4.3 | 700 |
| Example 2-7 | | | |

As shown in Table 4, a slight improving effect of emission efficiency was recognized for the device according to Example 2-1, when compared to a case (Comparative Example 2-1) in which HTL2 was replaced with HTL3 and a case (Comparative Example 2-2) in which Compound 43 was used in HTL1 and HTL3, and a layer of an electron accepting compound was inserted therebetween. In addition, efficiency improving effects were recognized for the device according to Example 2-1, when compared to a case (Comparative Example 2-3) in which the same Compound 17 was used in HTL2 and HTL3. Great efficiency improving effects were recognized when compared to a case (Comparative Example 2-4) using a non-carbazole-based hole transport Compound 68 in HTL3.

In addition, a marked lowering of the driving voltage was observed, in addition to the improvement in the efficiency for Example 2-1 of the inventive concept when compared to cases (Comparative Examples 2-5, 2-6 and 2-7) using a starburst type hole injection material in a layer adjacent to the anode. From the lowering of the driving voltage and the improvement of the emission efficiency, the significance of the presence of the electron accepting compound in at least one layer of HTL1 to HTL3 was recognized.

By way of summation and review, for the application of an organic EL device in a display apparatus, the organic EL device may need to be driven at a low voltage and may need to have high efficiency and long life. For example, in a blue emission region and a green emission region, the emission efficiency and life of the organic EL device may be insufficient. To realize the driving at a low voltage and high efficiency of the organic EL device, a band between an anode and an emission layer, and the normalization and stabilization with the emission layer may be significant points. A layer formed using an electron accepting material (hereinafter, will be referred to as an acceptor layer) to assist hole transportation may be used. However, in a device having the above-described constitution, electron acceptors may be diffused into an emission layer while applying an electric current, and life may be deteriorated.

As a hole transport material used in a hole transport layer, various compounds such as an aromatic amine compound, etc. have been considered. Decreasing the driving voltage of the organic EL device further and realizing high efficiency have been considered. For example, an organic EL device using tri(terphenyl)amine in a hole transport layer may be considered. However, this technique is derived from a material for forming only a specific layer, and the driving at a low voltage and high efficiency of a whole organic EL device may not be realized.

In an organic EL image display having a specific structure, a method of improving manufacturing efficiency by using an amine having a terphenyl group in a hole transport layer may be considered. However, the decrease of the driving voltage and the realization of the high efficiency of the organic EL device may still be insufficient.

In addition, a method of using a compound having a specific diamine structure as a first hole transport material and using an aromatic amine derivative having a terphenyl structure and a carbazole structure as a second hole transport material, or a method of using a specific electron accepting compound and using an aromatic amine derivative having a terphenyl amine structure and a carbazole structure as a first hole transport material may be considered.

The embodiments may provide an organic electroluminescence device driven at a low voltage and that has high efficiency and long life.

In the organic EL device according to an embodiment, the hole transporting laminated structure may be passivated from electrons not consumed in the emission layer, and the diffusion of excited energy generated in the emission layer into the hole transporting laminated structure may be prevented.

According to an embodiment, an organic EL device possibly driven at a low voltage and having high efficiency and long life may be formed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic electroluminescence (EL) device, comprising:
an anode;
an emission layer for obtaining luminescence via a singlet excited state; and
a laminated structure between the anode and the emission layer, the laminated structure including at least three layers having different components,
wherein the laminated structure includes:
a first layer that includes a hole transport compound obtained by doping an electron accepting compound having a lowest unoccupied molecular orbital (LUMO) level of about −9.0 eV to about −4.0 eV in a compound represented by the following Chemical Formula (1); 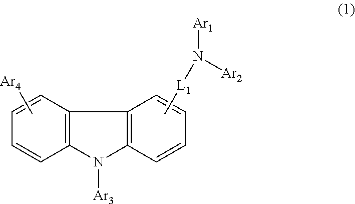
a second layer disposed closer to the emission layer than the first layer, the second layer including a compound represented by Chemical Formula (1); and
a third layer disposed closer to the emission layer than the second layer, the third layer including a compound represented by the following Chemical Formula (2), 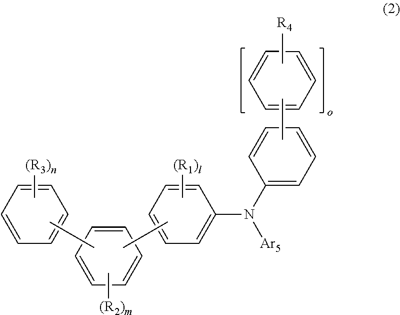
wherein the emission layer includes a compound represented by the following Chemical Formula (3), 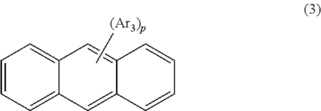
wherein, in Chemical Formula (1),
Ar₁, Ar₂, and Ar₃ are each independently a substituted or unsubstituted aryl group or a substituted or unsubstituted heteroaryl group,
Ar₄ is a substituted or unsubstituted aryl group, a substituted or unsubstituted heteroaryl group, a carbazolyl group, or an alkyl group, and
L₁ is a single bond, a substituted or unsubstituted arylene group, or a substituted or unsubstituted heteroarylene group,
wherein, in Chemical Formula (2),
R₁, R₂, and R₃ are each independently a hydrogen atom, a halogen atom, an alkyl group having 1 to 15 carbon atoms, a substituted or unsubstituted aryl group having 6 to 30 ring carbon atoms, or a substituted or unsubstituted heteroaryl group having 5 to 30 ring carbon atoms,
l, m, and n are each independently an integer and satisfy the following relations 0≦1≦4, 0≦m≦4, and 0≦n≦5,
R₄ is a hydrogen atom or a fluorine atom,
o is an integer that satisfies the following relation 0≦o≦3, and
Ar₅ is a substituted or unsubstituted aryl group having 6 to 30 ring carbon atoms,
wherein, in Chemical Formula (3),
each Ar₆ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group, or a hydroxyl group, and
p is an integer of 1 to 10.

2. The organic EL device as claimed in claim 1, wherein the first layer is disposed adjacent to the anode.

3. The organic EL device as claimed in claim 1, wherein the third layer is disposed adjacent to the emission layer.

4. The organic EL device as claimed in claim 1, wherein the first layer, the second layer, and the third layer each independently include a compound having a carbazolyl group.

5. The organic EL device as claimed in claim 4, wherein the first layer, the second layer, and the third layer each independently include a compound represented by Chemical Formula (1).

6. The organic EL device as claimed in claim 1, wherein the first layer includes at least one of the following Compounds 1 to 16:

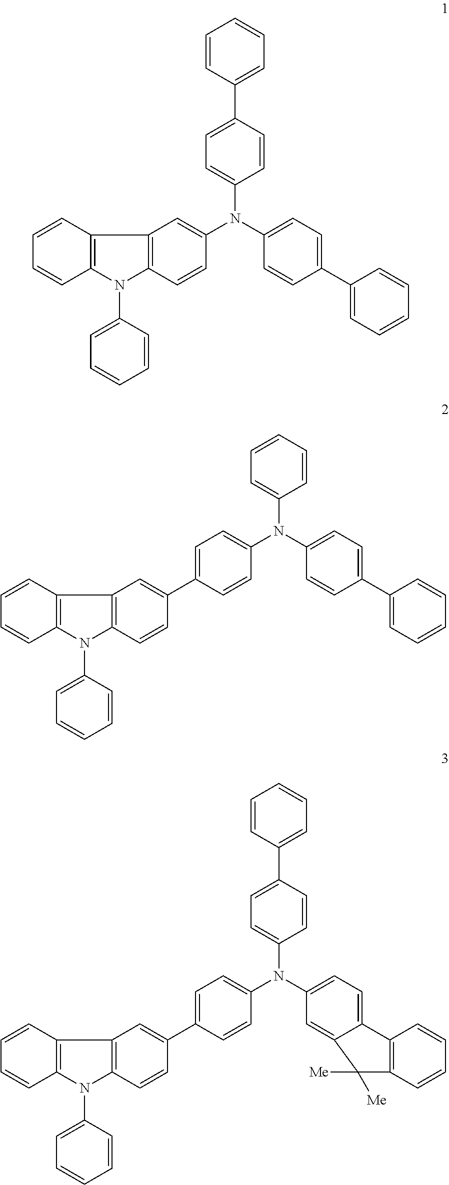 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

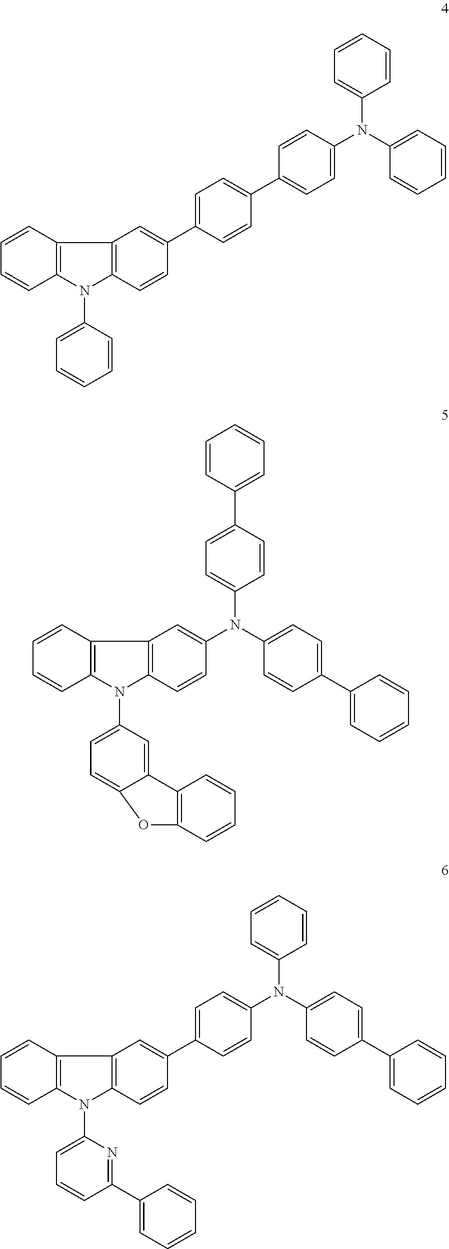 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

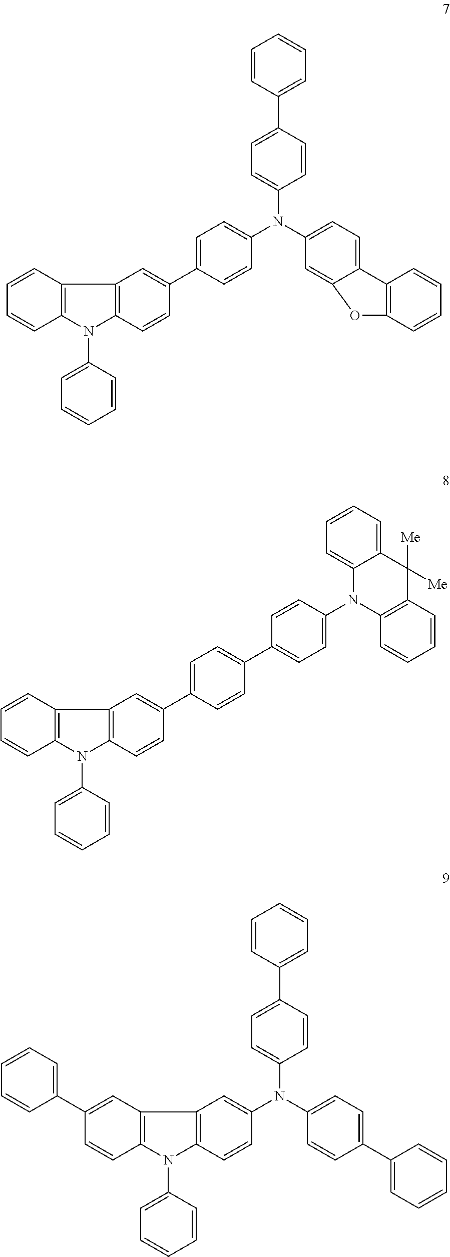 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

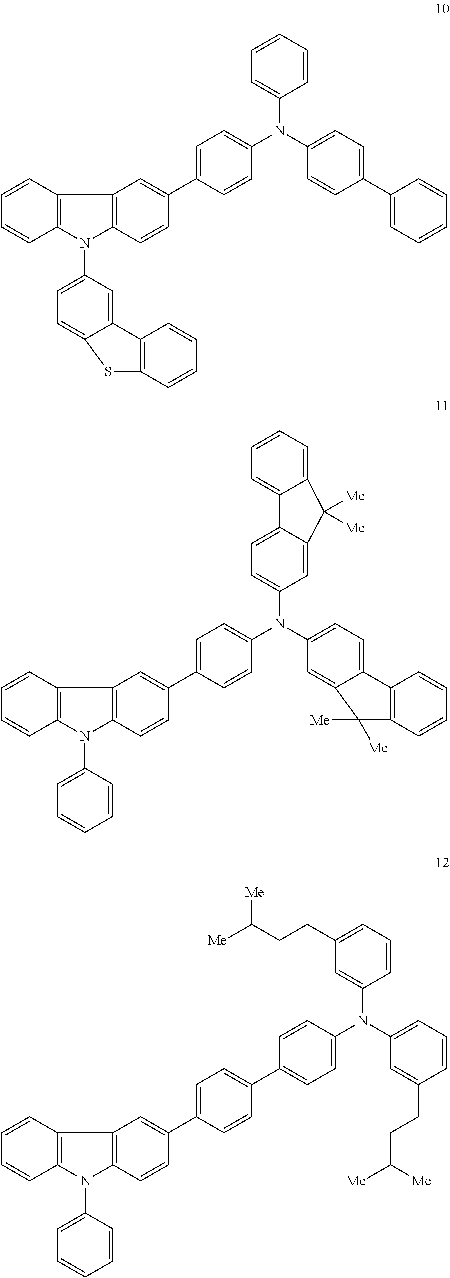 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

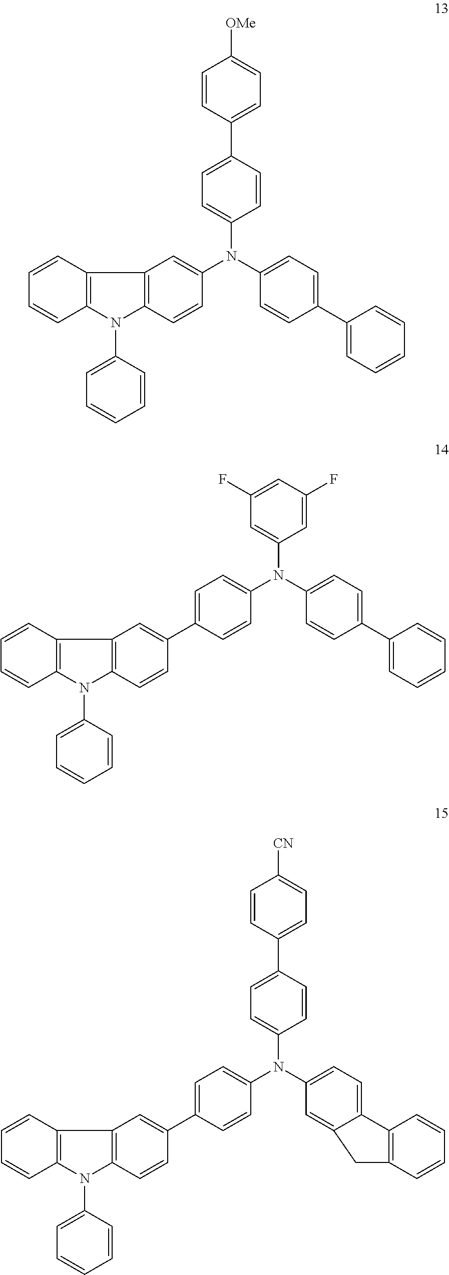 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

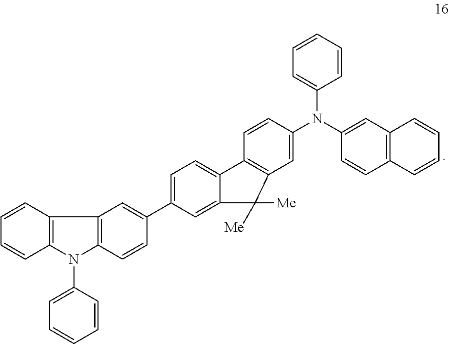 [SMILES: CC1(C)c2cc(-c3ccc4c(c3)c3ccccc3n4-c3ccccc3)ccc2-c2ccc(N(c3ccccc3)c3ccc4ccccc4c3)cc21]

7. The organic EL device as claimed in claim 1, wherein the electron accepting compound includes a compound represented by one of the following Chemical Formulae 17 to 30: 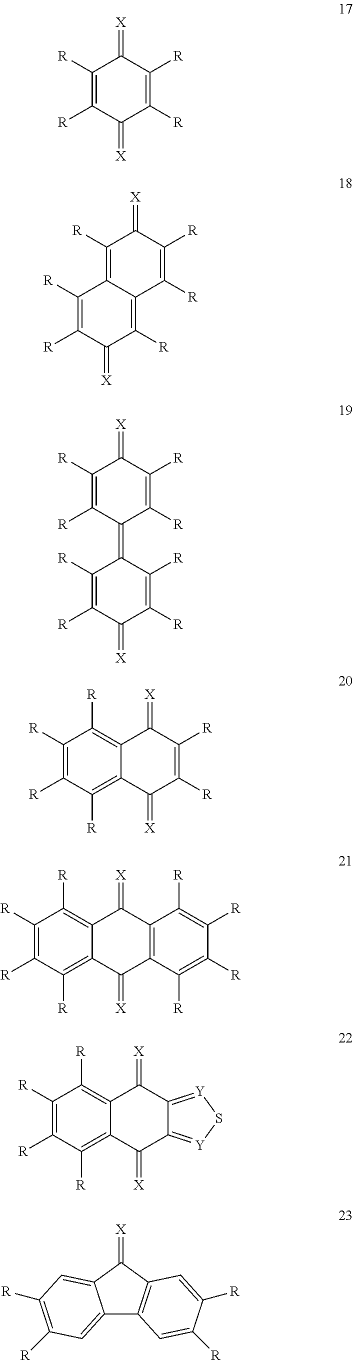 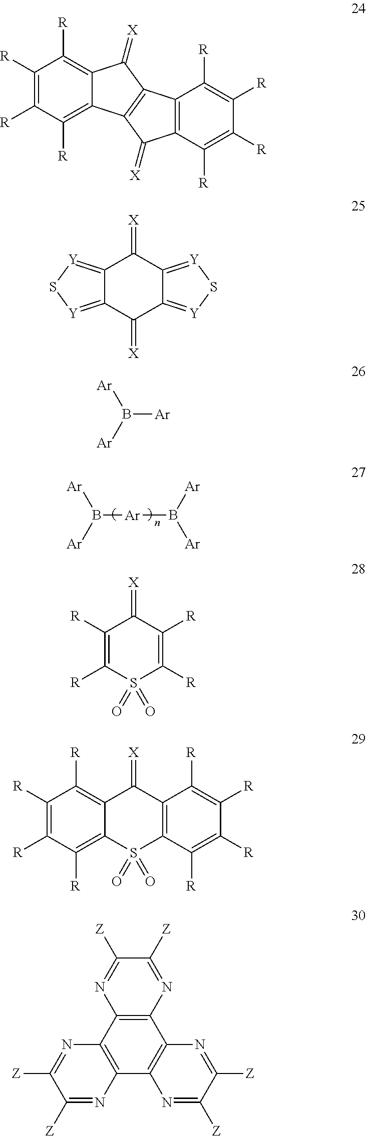
wherein, in Chemical Formulae 17 to 30,
each R is independently a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms, or a heteroaryl group having 5 to 50 carbon atoms,
each Ar is independently a substituted or unsubstituted electron withdrawing aryl group having 6 to 50 carbon atoms or a substituted or unsubstituted heteroaryl group having 5 to 50 carbon atoms,
each Y is independently a methine group or a nitrogen atom,
each Z is independently a pseudohalogen or sulfur, and
each X is independently a group represented by one of the following Chemical Formulae X1 to X7: 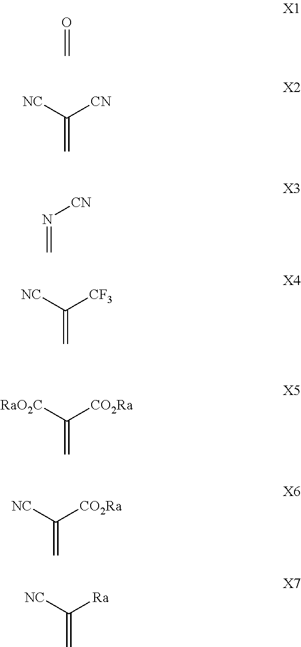
wherein, in Formulae X1 to X7, each Ra is independently a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 ring carbon atoms, or a substituted or unsubstituted heteroaryl group having 5 to 50 ring carbon atoms.

8. An organic EL device as claimed in claim 1, wherein the third layer includes one of the following Compounds 31 to 54:

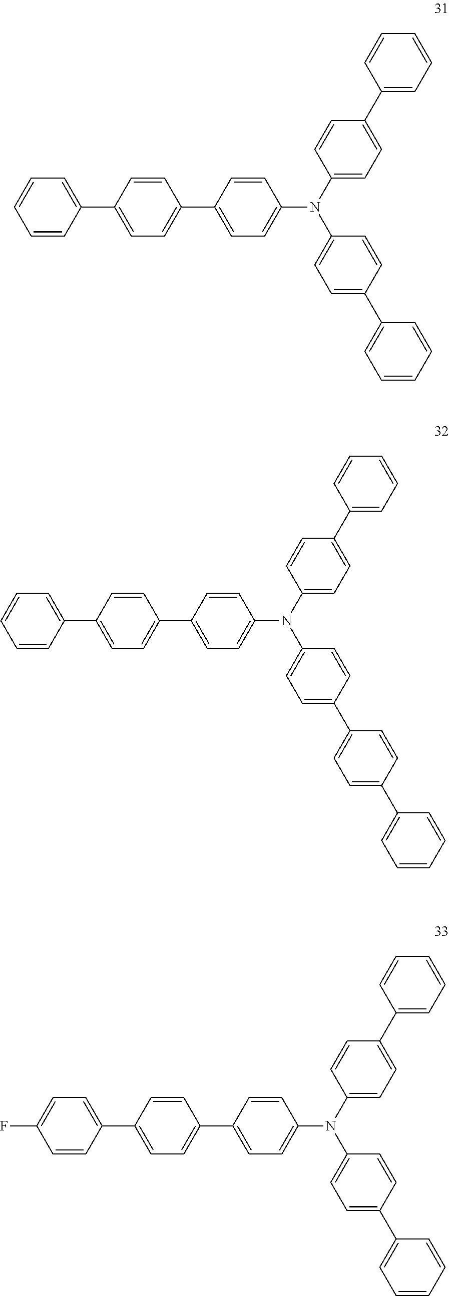 [SMILES: c1ccc(-c2ccc(-c3ccc(N(c4ccc(-c5ccccc5)cc4)c4ccc(-c5ccccc5)cc4)cc3)cc2)cc1 ; c1ccc(-c2ccc(-c3ccc(N(c4ccc(-c5ccccc5)cc4)c4ccc(-c5ccc(-c6ccccc6)cc5)cc4)cc3)cc2)cc1 ; Fc1ccc(-c2ccc(-c3ccc(N(c4ccc(-c5ccccc5)cc4)c4ccc(-c5ccccc5)cc4)cc3)cc2)cc1]

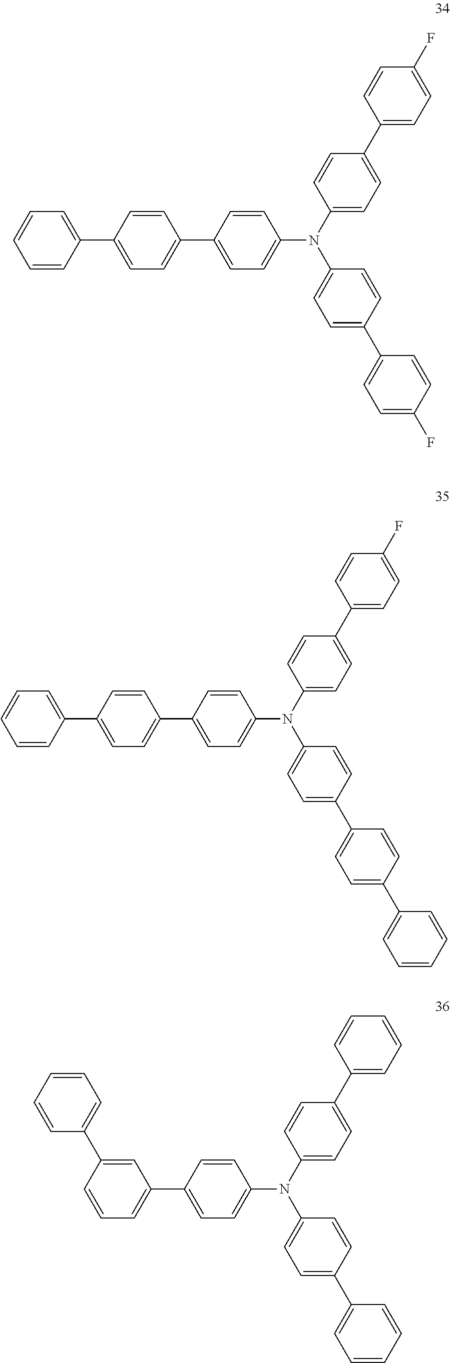 [SMILES: Fc1ccc(-c2ccc(N(c3ccc(-c4ccc(F)cc4)cc3)c3ccc(-c4ccc(-c5ccccc5)cc4)cc3)cc2)cc1 ; Fc1ccc(-c2ccc(N(c3ccc(-c4ccc(-c5ccccc5)cc4)cc3)c3ccc(-c4ccc(-c5ccccc5)cc4)cc3)cc2)cc1 ; c1ccc(-c2ccc(N(c3ccc(-c4ccccc4)cc3)c3ccc(-c4cccc(-c5ccccc5)c4)cc3)cc2)cc1]

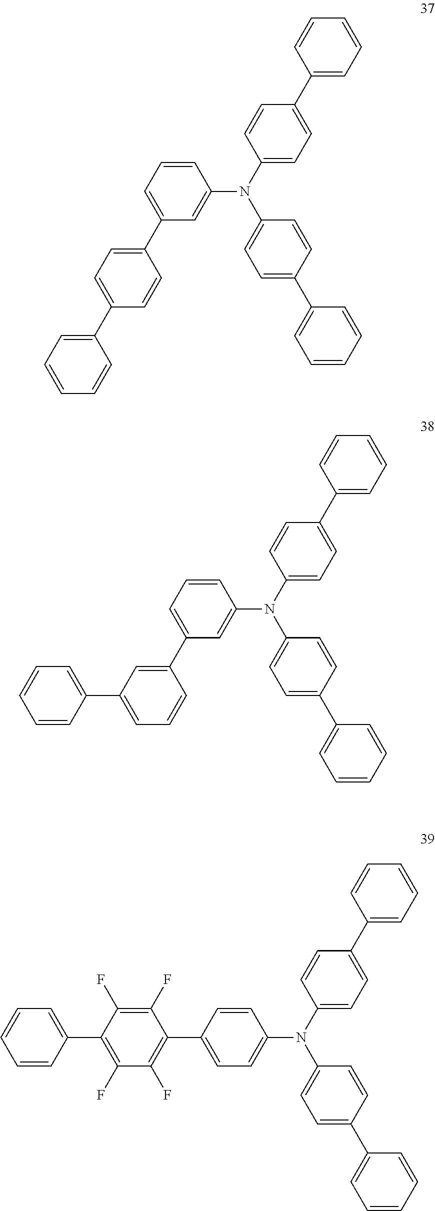 [SMILES: c1ccc(-c2ccc(-c3cccc(N(c4ccc(-c5ccccc5)cc4)c4ccc(-c5ccccc5)cc4)c3)cc2)cc1 ; c1ccc(-c2ccc(N(c3ccc(-c4ccccc4)cc3)c3cccc(-c4cccc(-c5ccccc5)c4)c3)cc2)cc1 ; Fc1c(F)c(-c2ccc(N(c3ccc(-c4ccccc4)cc3)c3ccc(-c4ccccc4)cc3)cc2)c(F)c(F)c1-c1ccccc1]

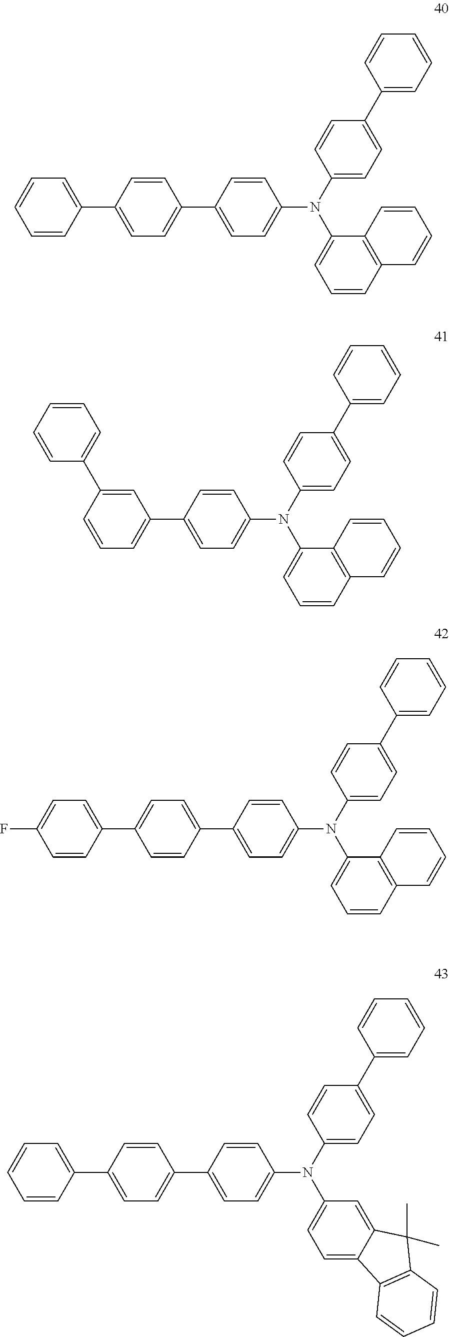 [SMILES: c1ccc(-c2ccc(-c3ccc(N(c4ccc(-c5ccccc5)cc4)c4cccc5ccccc45)cc3)cc2)cc1 ; c1ccc(-c2ccc(N(c3ccc(-c4cccc(-c5ccccc5)c4)cc3)c3cccc4ccccc34)cc2)cc1 ; Fc1ccc(-c2ccc(-c3ccc(N(c4ccc(-c5ccccc5)cc4)c4cccc5ccccc45)cc3)cc2)cc1 ; CC1(C)c2ccccc2-c2ccc(N(c3ccc(-c4ccccc4)cc3)c3ccc(-c4ccc(-c5ccccc5)cc4)cc3)cc21]

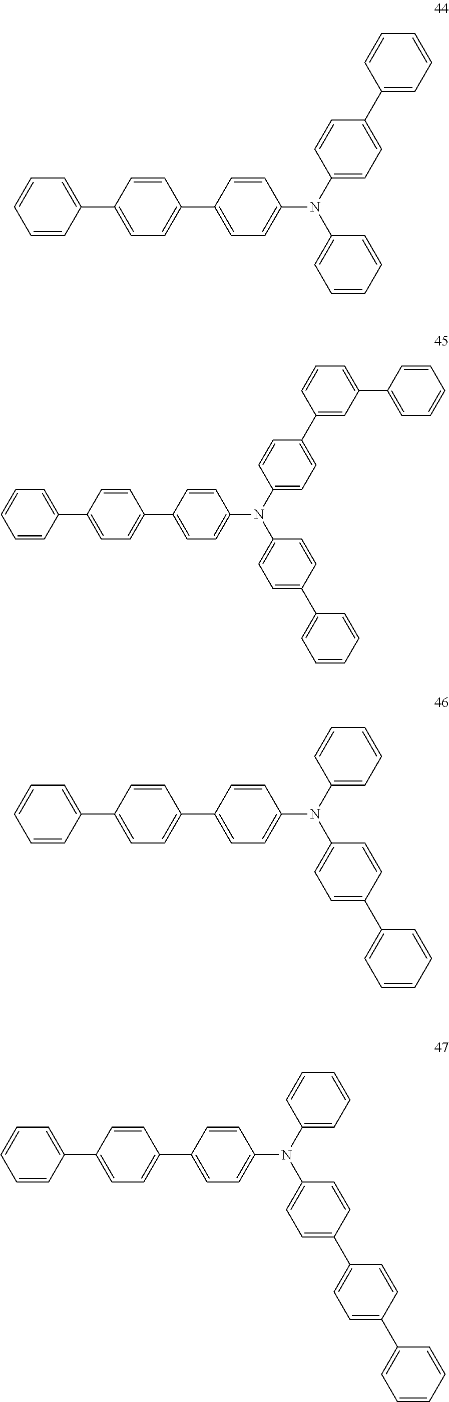 [SMILES: c1ccc(-c2ccc(-c3ccc(N(c4ccccc4)c4ccc(-c5ccccc5)cc4)cc3)cc2)cc1 ; c1ccc(-c2ccc(-c3ccc(N(c4ccc(-c5ccccc5)cc4)c4ccc(-c5cccc(-c6ccccc6)c5)cc4)cc3)cc2)cc1 ; c1ccc(-c2ccc(-c3ccc(N(c4ccccc4)c4ccc(-c5ccccc5)cc4)cc3)cc2)cc1 ; c1ccc(-c2ccc(-c3ccc(N(c4ccccc4)c4ccc(-c5ccc(-c6ccccc6)cc5)cc4)cc3)cc2)cc1]

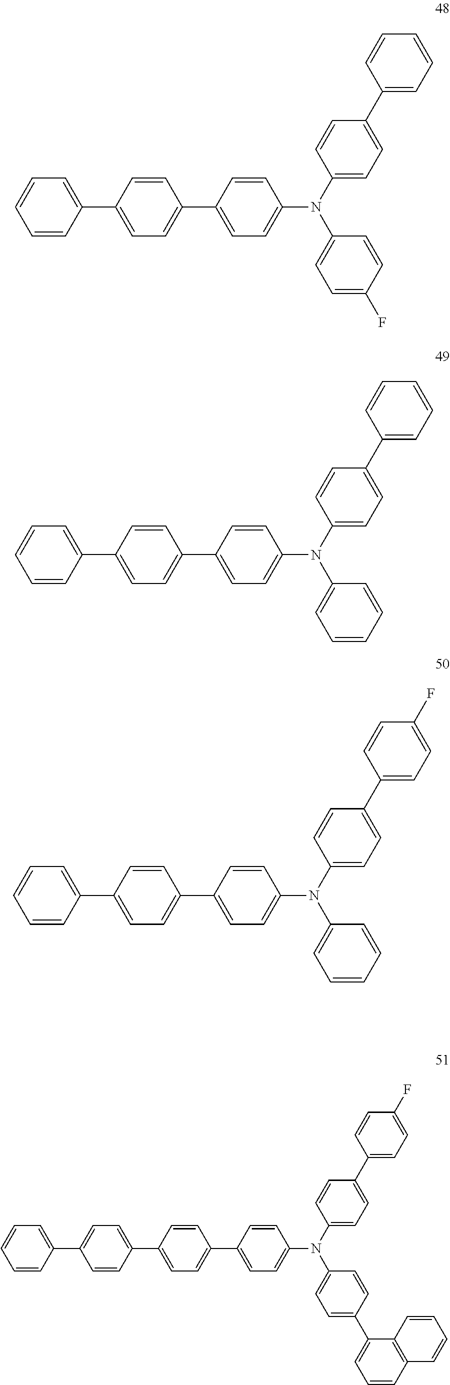 [SMILES: Fc1ccc(N(c2ccc(-c3ccccc3)cc2)c2ccc(-c3ccc(-c4ccccc4)cc3)cc2)cc1 ; c1ccc(-c2ccc(-c3ccc(N(c4ccccc4)c4ccc(-c5ccccc5)cc4)cc3)cc2)cc1 ; Fc1ccc(-c2ccc(N(c3ccccc3)c3ccc(-c4ccc(-c5ccccc5)cc4)cc3)cc2)cc1 ; Fc1ccc(-c2ccc(N(c3ccc(-c4ccc(-c5ccc(-c6ccccc6)cc5)cc4)cc3)c3ccc(-c4cccc5ccccc45)cc3)cc2)cc1]

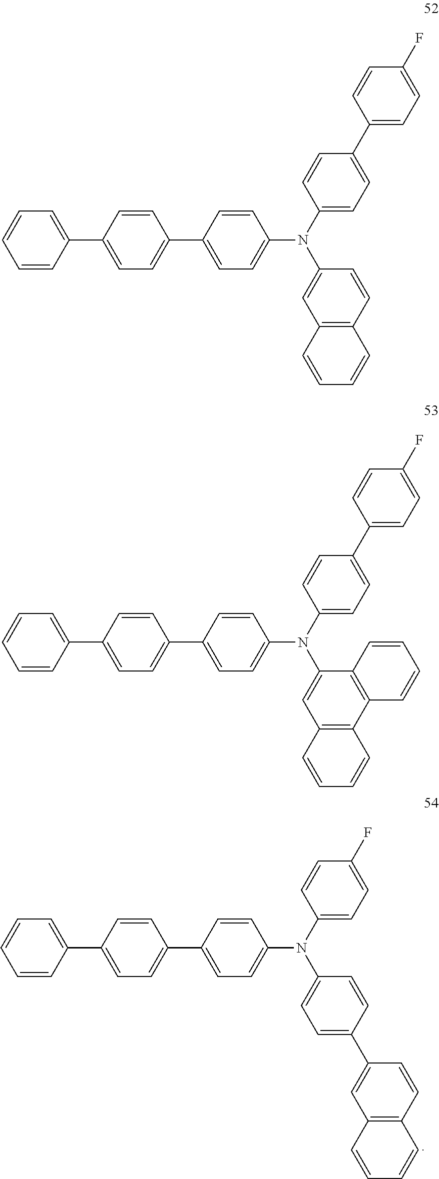 [SMILES: Fc1ccc(-c2ccc(N(c3ccc(-c4ccc(-c5ccccc5)cc4)cc3)c3ccc4ccccc4c3)cc2)cc1 ; Fc1ccc(-c2ccc(N(c3ccc(-c4ccc(-c5ccccc5)cc4)cc3)c3cc4ccccc4c4ccccc34)cc2)cc1 ; Fc1ccc(N(c2ccc(-c3ccc(-c4ccccc4)cc3)cc2)c2ccc(-c3ccc4ccccc4c3)cc2)cc1]

9. The organic EL device as claimed in claim 1, wherein the emission layer includes one of the following Compounds 55 to 66:

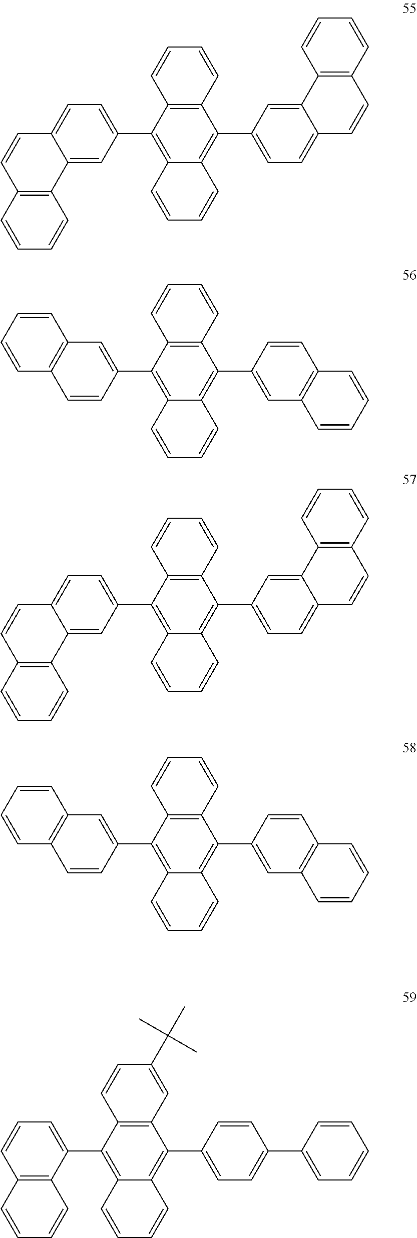

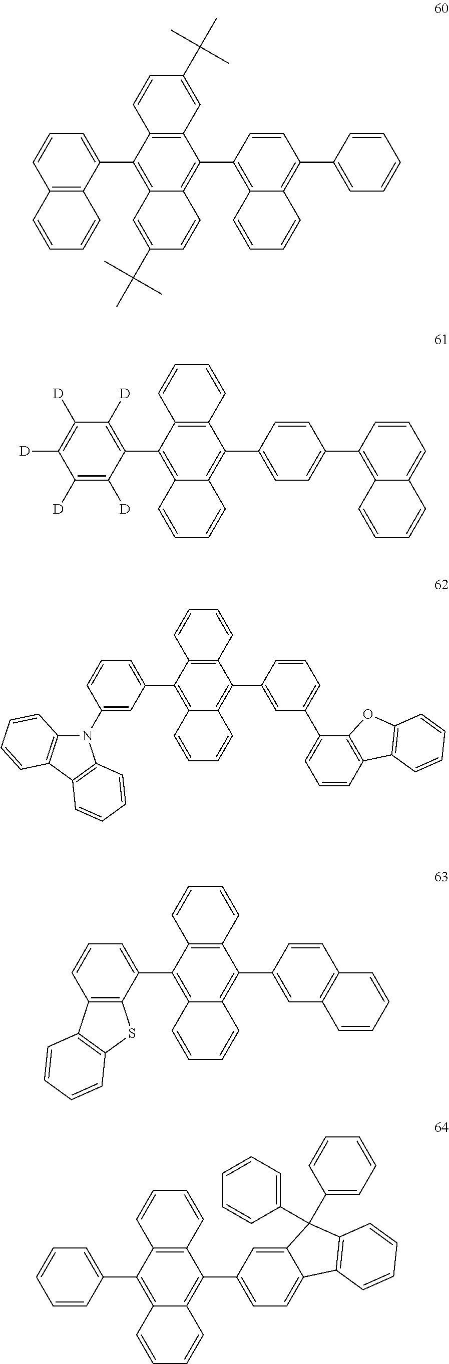

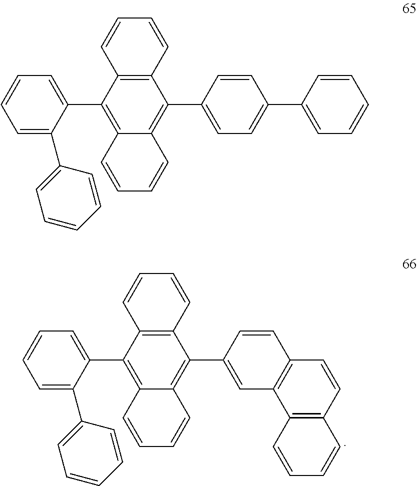

10. An organic electroluminescence (EL) device, comprising:
an anode;
an emission layer for obtaining luminescence via a singlet excited state; and
a laminated structure between the anode and the emission layer, the laminated structure having at least three layers having different components,
wherein the laminated structure includes:
a first layer including an electron accepting compound having a lowest unoccupied molecular orbital (LUMO) level of about −9.0 eV to about −4.0 eV;
a second layer disposed closer to the emission layer than the first layer, the second layer including a compound represented by the following Chemical Formula (1); and 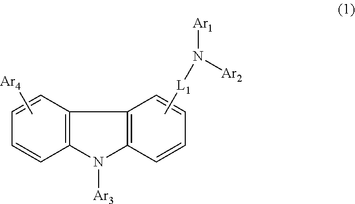
a third layer disposed closer to the emission layer than the second layer, the third layer including a compound represented by the following Chemical Formula (2), 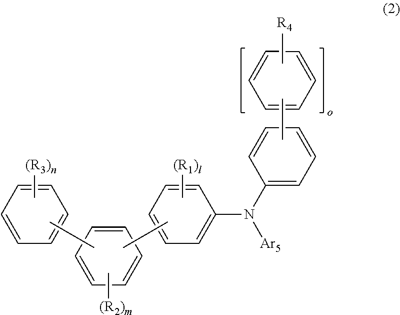
wherein the emission layer includes a compound represented by the following Chemical Formula (3), 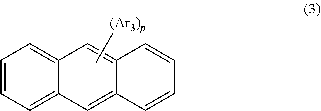
wherein, in Chemical Formula (1),
Ar₁, Ar₂, and Ar₃ are each independently a substituted or unsubstituted aryl group or a substituted or unsubstituted heteroaryl group,
Ar₄ is a substituted or unsubstituted aryl group, a substituted or unsubstituted heteroaryl group, a carbazolyl group, or an alkyl group, and
L₁ is a single bond, a substituted or unsubstituted arylene group or a substituted or unsubstituted heteroarylene group,
wherein, in Chemical Formula (2),
R₁, R₂ and R₃ are each independently a hydrogen atom, a deuterium atom, a halogen atom, an alkyl group having 1 to 15 carbon atoms, a substituted or unsubstituted aryl group having 6 to 30 ring carbon atoms, or a substituted or unsubstituted heteroaryl group having 1 to 30 ring carbon atoms,
l, m, and n are each independently an integer and satisfy the following relations 0≦1≦4, 0≦m≦4, and 0≦n≦5,
R₄ is a hydrogen atom, a deuterium atom, or a fluorine atom,
o is an integer that satisfies the following relation 0≦o≦3, and
Ar₅ is a substituted or unsubstituted aryl group having 6 to 30 ring carbon atoms,
wherein, in Chemical Formula (3),
each Ar₆ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group, or a hydroxyl group, and
p is an integer or 1 to 10.

11. The organic EL device as claimed in claim 10, wherein the first layer is disposed adjacent to the anode.

12. The organic EL device as claimed in claim 10, wherein the third layer is disposed adjacent to the emission layer.

13. The organic EL device as claimed in claim 10, wherein the electron accepting compound includes a compound represented by one of the following Chemical Formulae 17 to 30: 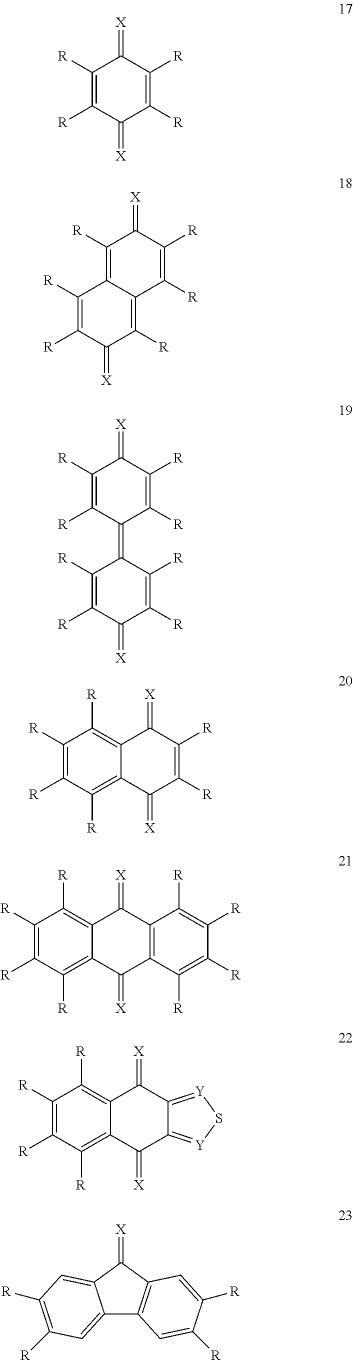 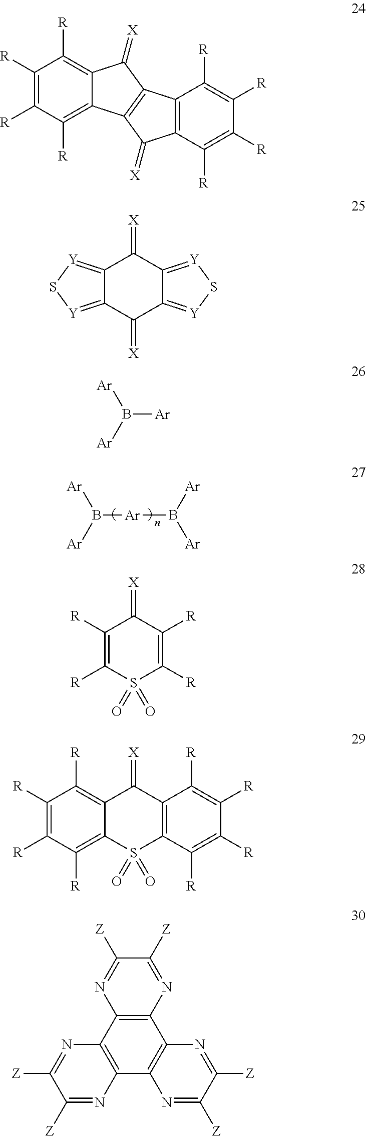
wherein, in Chemical Formulae 17 to 30,
each R is independently a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 5 to 50 carbon atoms, or a heteroaryl group having 5 to 50 carbon atoms,
each Ar is independently a substituted or unsubstituted electron withdrawing aryl group having 5 to 50 carbon atoms or a substituted or unsubstituted heteroaryl group having 5 to 50 carbon atoms,
each Y is independently a methine group or a nitrogen atom,
each Z is independently a pseudohalogen or sulfur, and
each X is independently a group represented by one of the following Chemical Formulae X1 to X7, 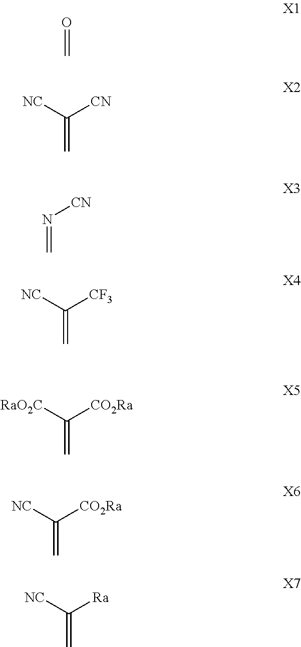
wherein, in Formulae X1 to X7, each Ra is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 5 to 50 ring carbon atoms, or a substituted or unsubstituted heteroaryl group having 5 to 50 ring carbon atoms.

14. An organic EL device as claimed in claim 10, wherein the second layer includes one of the following Compounds 1 to 16:

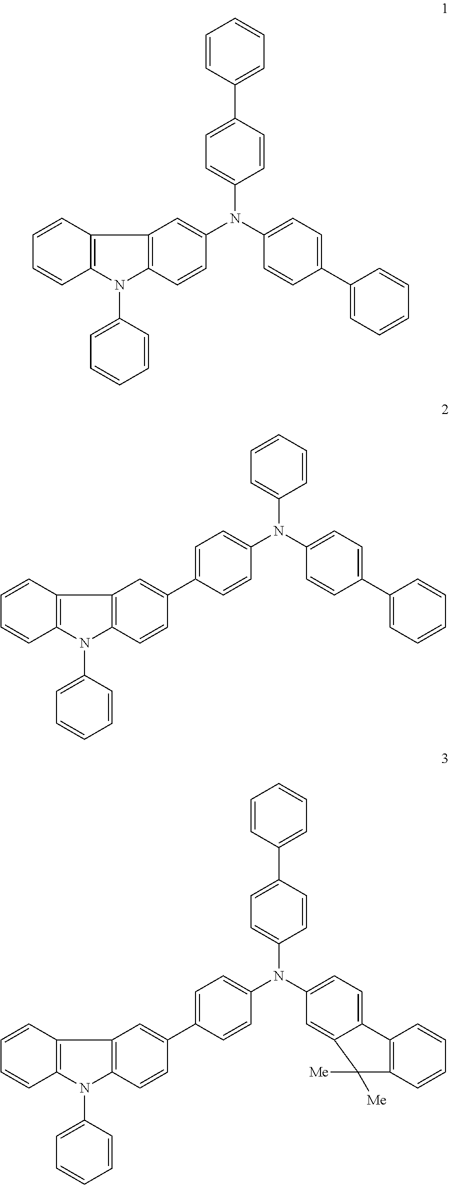 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

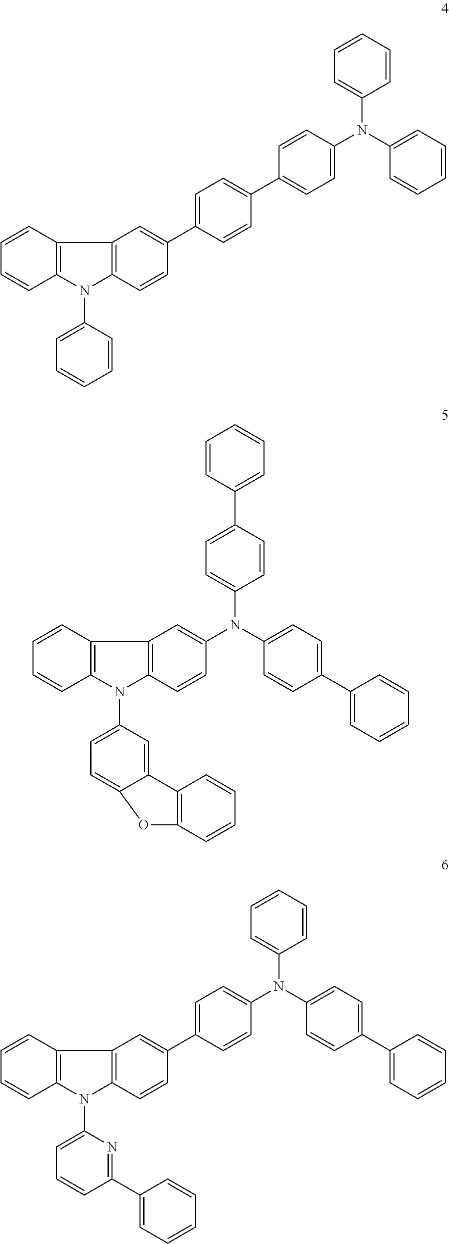 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

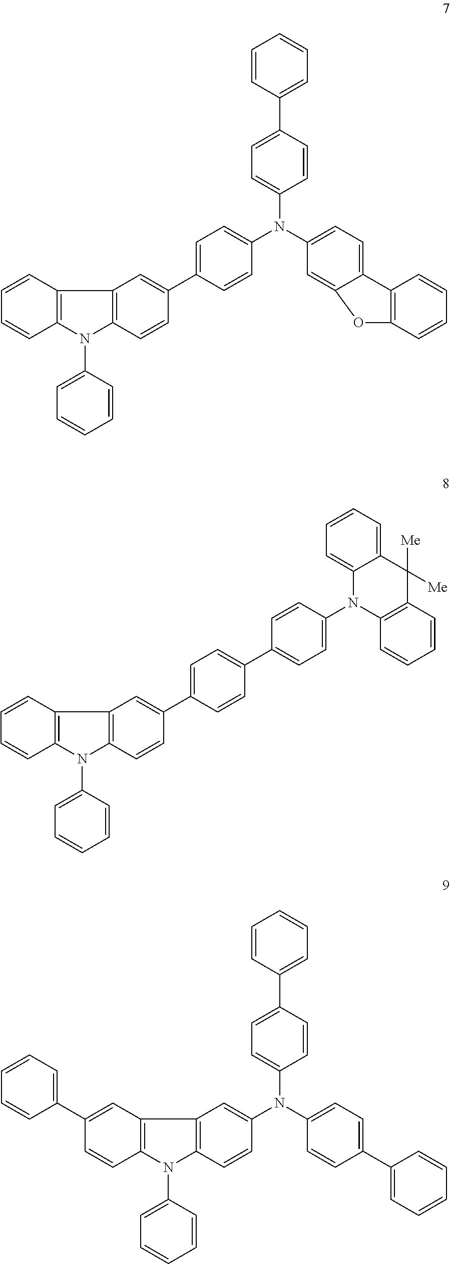 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

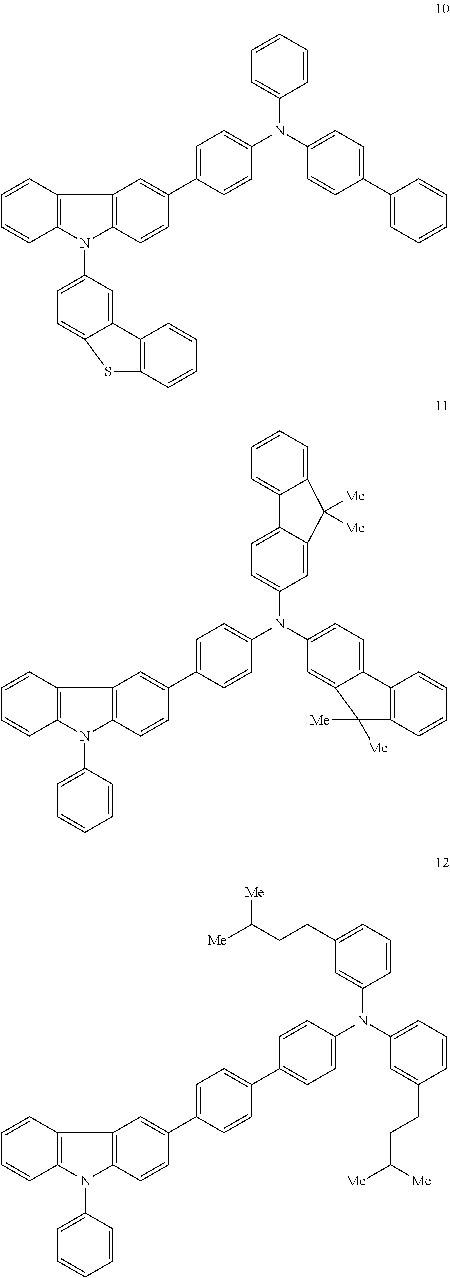 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

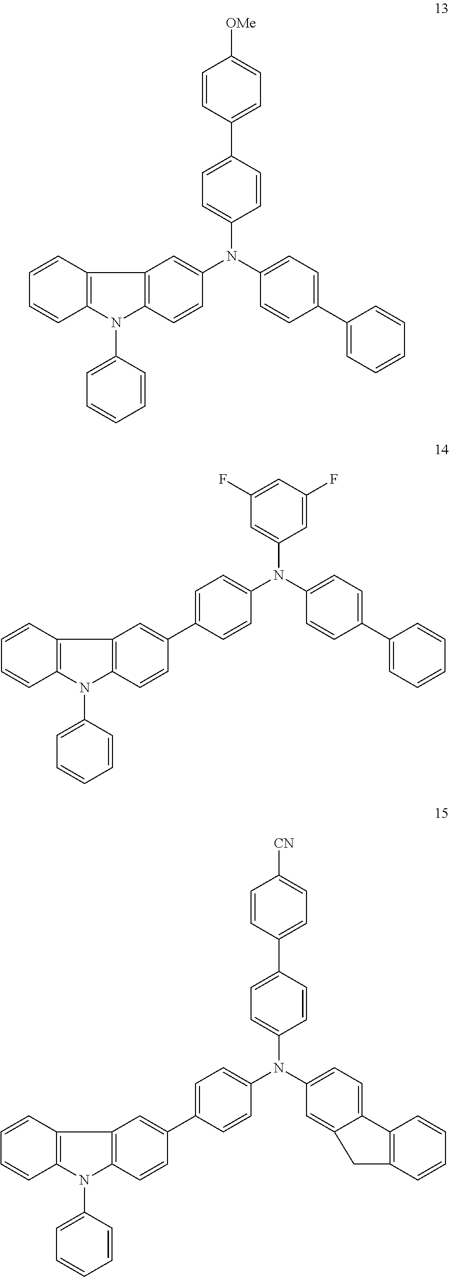 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

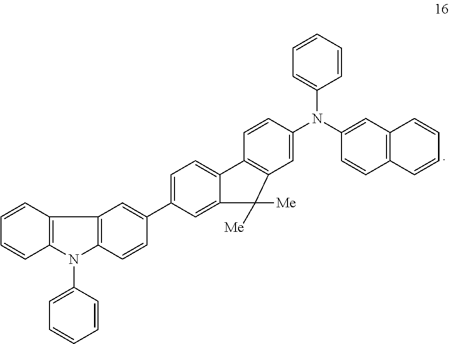 [SMILES: CC1(C)c2cc(-c3ccc4c(c3)c3ccccc3n4-c3ccccc3)ccc2-c2ccc(N(c3ccccc3)c3ccc4ccccc4c3)cc21]

15. An organic EL device as claimed in claim 10, wherein the third layer includes one of the following Compounds 31 to 54:

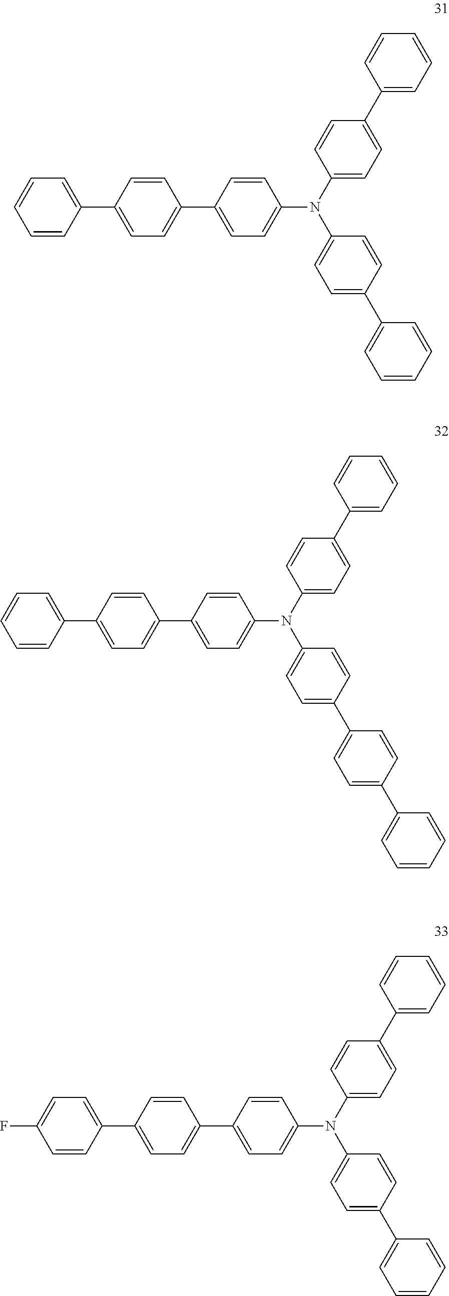 [SMILES: c1ccc(-c2ccc(-c3ccc(N(c4ccc(-c5ccccc5)cc4)c4ccc(-c5ccccc5)cc4)cc3)cc2)cc1 ; c1ccc(-c2ccc(-c3ccc(N(c4ccc(-c5ccccc5)cc4)c4ccc(-c5ccc(-c6ccccc6)cc5)cc4)cc3)cc2)cc1 ; Fc1ccc(-c2ccc(-c3ccc(N(c4ccc(-c5ccccc5)cc4)c4ccc(-c5ccccc5)cc4)cc3)cc2)cc1]

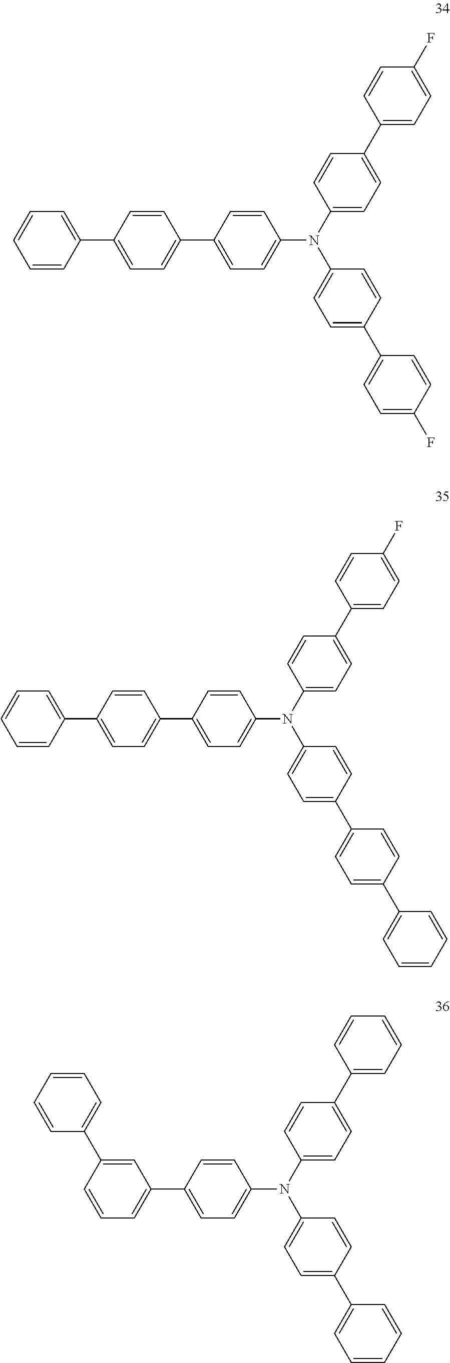 [SMILES: Fc1ccc(-c2ccc(N(c3ccc(-c4ccc(F)cc4)cc3)c3ccc(-c4ccc(-c5ccccc5)cc4)cc3)cc2)cc1 ; Fc1ccc(-c2ccc(N(c3ccc(-c4ccc(-c5ccccc5)cc4)cc3)c3ccc(-c4ccc(-c5ccccc5)cc4)cc3)cc2)cc1 ; c1ccc(-c2ccc(N(c3ccc(-c4ccccc4)cc3)c3ccc(-c4cccc(-c5ccccc5)c4)cc3)cc2)cc1]

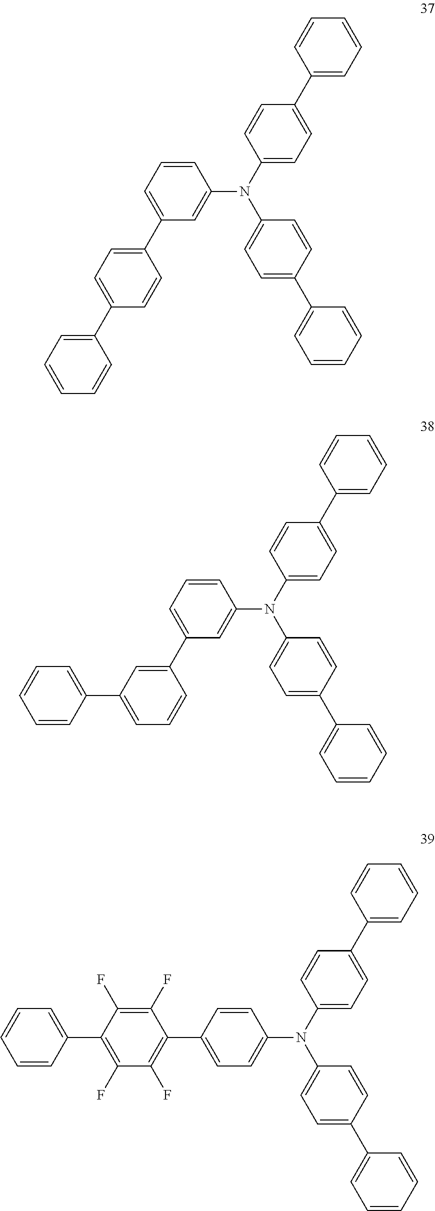 [SMILES: c1ccc(-c2ccc(-c3cccc(N(c4ccc(-c5ccccc5)cc4)c4ccc(-c5ccccc5)cc4)c3)cc2)cc1 ; c1ccc(-c2ccc(N(c3ccc(-c4ccccc4)cc3)c3cccc(-c4cccc(-c5ccccc5)c4)c3)cc2)cc1 ; Fc1c(F)c(-c2ccc(N(c3ccc(-c4ccccc4)cc3)c3ccc(-c4ccccc4)cc3)cc2)c(F)c(F)c1-c1ccccc1]

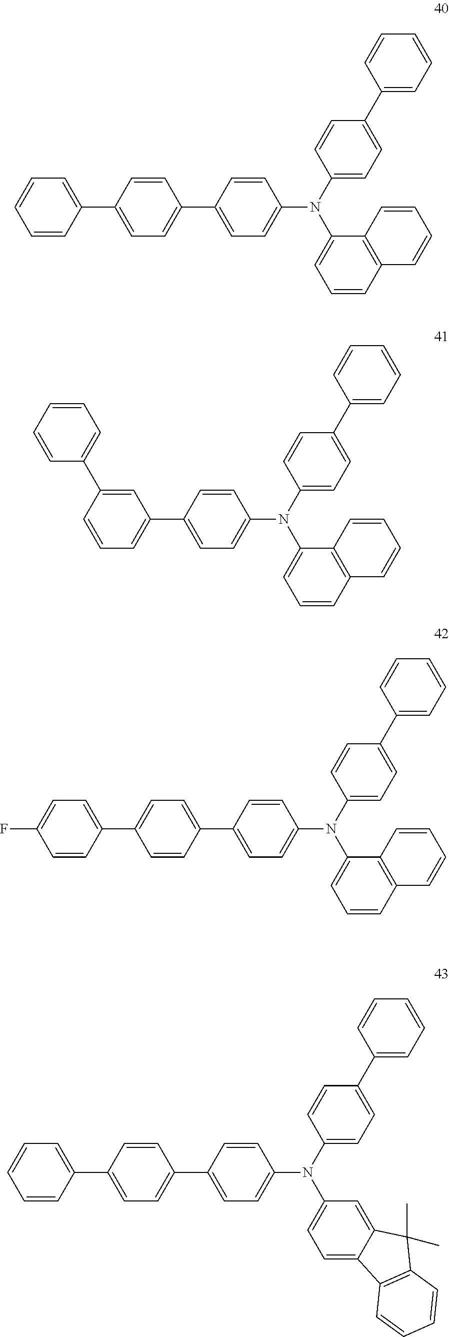 [SMILES: c1ccc(-c2ccc(-c3ccc(N(c4ccc(-c5ccccc5)cc4)c4cccc5ccccc45)cc3)cc2)cc1 ; c1ccc(-c2ccc(N(c3ccc(-c4cccc(-c5ccccc5)c4)cc3)c3cccc4ccccc34)cc2)cc1 ; Fc1ccc(-c2ccc(-c3ccc(N(c4ccc(-c5ccccc5)cc4)c4cccc5ccccc45)cc3)cc2)cc1 ; CC1(C)c2ccccc2-c2ccc(N(c3ccc(-c4ccccc4)cc3)c3ccc(-c4ccc(-c5ccccc5)cc4)cc3)cc21]

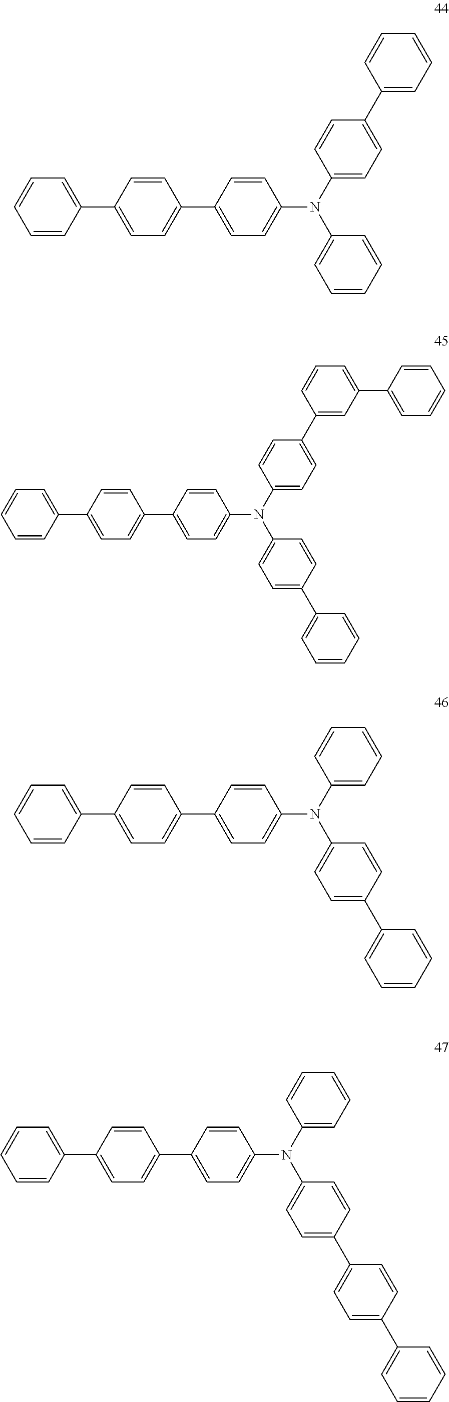 [SMILES: c1ccc(-c2ccc(-c3ccc(N(c4ccccc4)c4ccc(-c5ccccc5)cc4)cc3)cc2)cc1 ; c1ccc(-c2ccc(-c3ccc(N(c4ccc(-c5ccccc5)cc4)c4ccc(-c5cccc(-c6ccccc6)c5)cc4)cc3)cc2)cc1 ; c1ccc(-c2ccc(-c3ccc(N(c4ccccc4)c4ccc(-c5ccccc5)cc4)cc3)cc2)cc1 ; c1ccc(-c2ccc(-c3ccc(N(c4ccccc4)c4ccc(-c5ccc(-c6ccccc6)cc5)cc4)cc3)cc2)cc1]

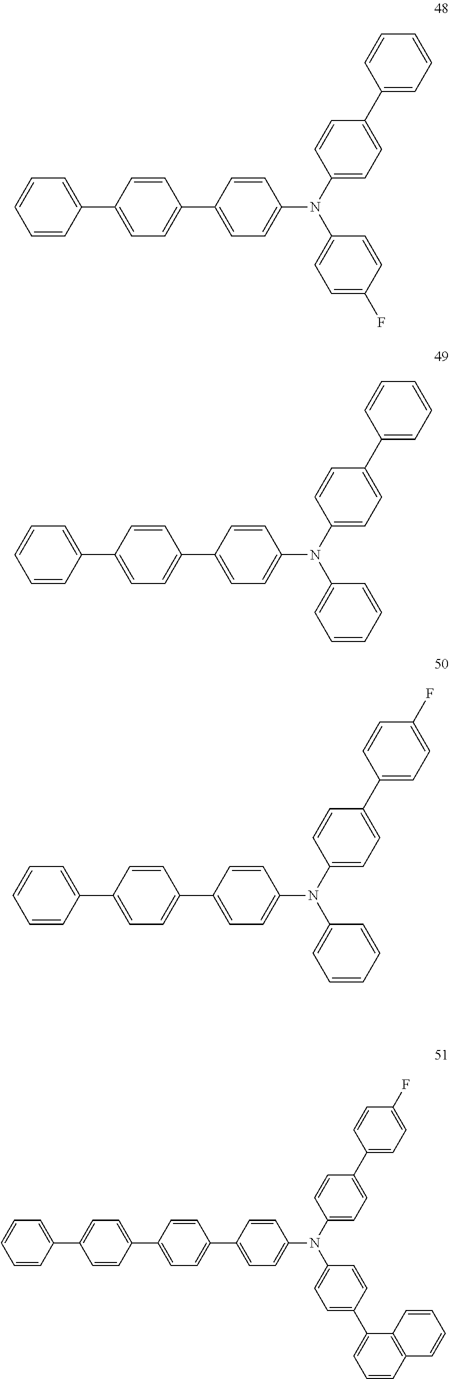 [SMILES: Fc1ccc(N(c2ccc(-c3ccccc3)cc2)c2ccc(-c3ccc(-c4ccccc4)cc3)cc2)cc1 ; c1ccc(-c2ccc(-c3ccc(N(c4ccccc4)c4ccc(-c5ccccc5)cc4)cc3)cc2)cc1 ; Fc1ccc(-c2ccc(N(c3ccccc3)c3ccc(-c4ccc(-c5ccccc5)cc4)cc3)cc2)cc1 ; Fc1ccc(-c2ccc(N(c3ccc(-c4ccc(-c5ccc(-c6ccccc6)cc5)cc4)cc3)c3ccc(-c4cccc5ccccc45)cc3)cc2)cc1]

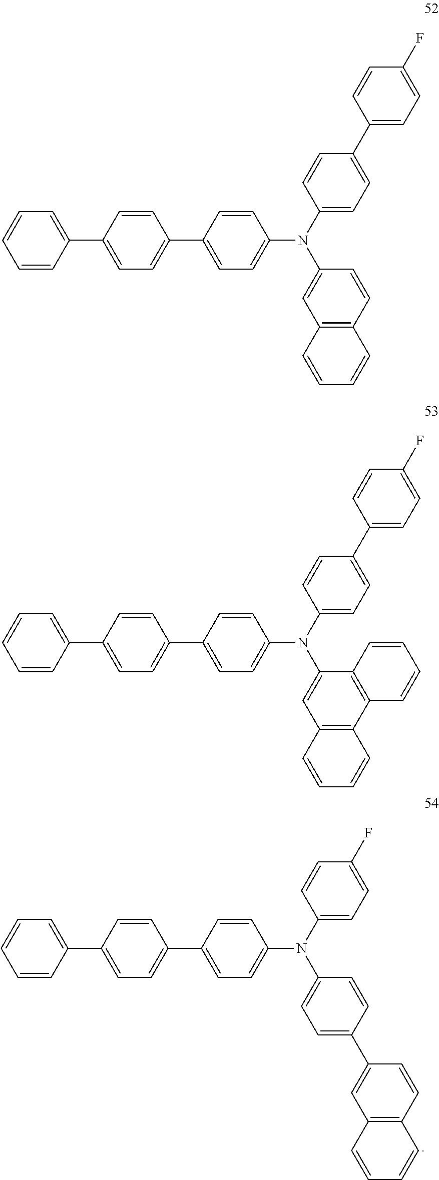 [SMILES: Fc1ccc(-c2ccc(N(c3ccc(-c4ccc(-c5ccccc5)cc4)cc3)c3ccc4ccccc4c3)cc2)cc1 ; Fc1ccc(-c2ccc(N(c3ccc(-c4ccc(-c5ccccc5)cc4)cc3)c3cc4ccccc4c4ccccc34)cc2)cc1 ; Fc1ccc(N(c2ccc(-c3ccc(-c4ccccc4)cc3)cc2)c2ccc(-c3ccc4ccccc4c3)cc2)cc1]

16. The organic EL device as claimed in claim 10, wherein the emission layer includes one of the following Compounds 55 to 66: 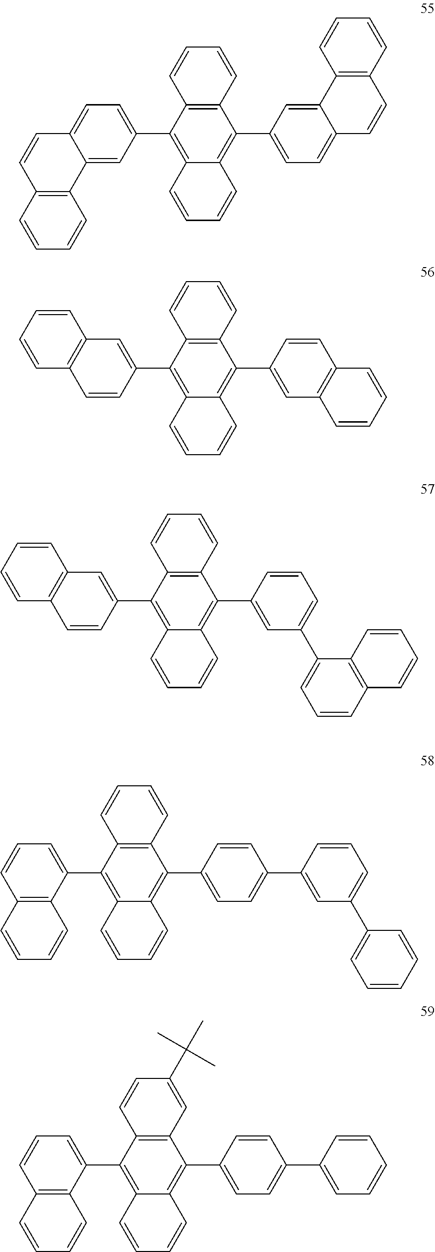 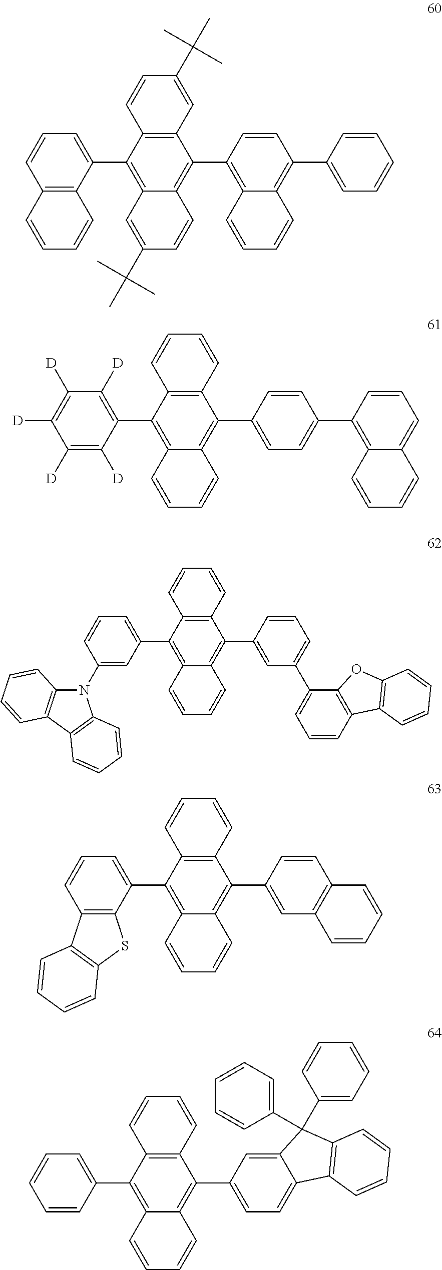 [chemical structure]
